(19) United States
(12) Patent Application Publication
(10) Pub. No.: US 2021/0200098 A1
(43) Pub. Date: Jul. 1, 2021

(54) PATTERN FORMING METHOD AND RESIST LAMINATE FOR ORGANIC SOLVENT DEVELOPMENT

(71) Applicant: FUJIFILM Corporation, Tokyo (JP)

(72) Inventors: Wataru NIHASHI, Shizuoka (JP); Michihiro SHIRAKAWA, Shizuoka (JP)

(73) Assignee: FUJIFILM Corporation, Tokyo (JP)

(21) Appl. No.: 17/200,912

(22) Filed: Mar. 15, 2021

Related U.S. Application Data
(63) Continuation of application No. PCT/JP2019/034460, filed on Sep. 2, 2019.

(30) Foreign Application Priority Data
Sep. 27, 2018 (JP) 2018-182231

(51) Int. Cl. G03F 7/32; G03F 7/004; G03F 7/039

(52) U.S. Cl. CPC G03F 7/325; H01L 21/0274; G03F 7/039; G03F 7/0041

(57) ABSTRACT

A pattern forming method includes: preparing a laminate having a substrate, an inorganic base layer, and a resist layer; exposing the resist layer; and developing the laminate using a developer including an organic solvent to form a negative tone pattern, in which a surface energy γA of the resist layer and a surface energy γB of the inorganic base layer after irradiation of the laminate with ultraviolet rays having a wavelength of 13.5 nm from the resist layer side with an integrated light quantity of 40 mJ/cm², followed by heating of the laminate at 110° C. for 60 seconds are 60 mJ/m² or more and 55 mJ/m² or more, respectively, and a difference γ_{AB} in surface energies that is defined by Formula (A) is 5.0 mJ/m² or less: γ_{AB}=γ_{A}−γ_{B} (Formula (A)).

### CROSS-REFERENCE TO RELATED APPLICATIONS

This application is a continuation application of International Application No. PCT/JP2019/034460, filed Sep. 2, 2019, the disclosure of which is incorporated herein by reference in its entirety. Further, this application claims priority from Japanese Patent Application No. 2018-182231, filed Sep. 27, 2018, the disclosure of which is incorporated herein by reference in its entirety.

### BACKGROUND OF THE INVENTION

### 1. Field of the Invention

The disclosure relates to a pattern forming method and a resist laminate for organic solvent development.

### 2. Description of the Related Art

In processes for manufacturing semiconductor devices such as an integrated circuit (IC) and a large scale integrated circuit (LSI) in the related art, microfabrication by lithography using a resist composition has been performed. In recent years, formation of an ultrafine pattern in a submicron region or a quarter-micron region has been demanded in accordance with realization of a high degree of integration for integrated circuits. In accordance with this, a tendency that the exposure wavelength becomes shorter, for example, from a g-ray to an i-ray, and further to excimer laser light such as KrF can be seen, and further, development of lithography using electron beams, X-rays, or extreme ultraviolet rays (EUV), in addition to the excimer laser light, is also now in progress.

Moreover, as a composition in the related art, those described in JP2014-134592A, JP2014-157242A, and JP2013-167669A are known.

JP2014-134592A describes a composition for forming a titanium-containing resist underlayer film, the composition including:

a silicon-containing compound obtained by subjecting one or more silicon compounds represented by Formulae (A-I) to hydrolysis, condensation, or the both as a component (A):

R^{1A}ₐ₁R^{2A}ₐ₂R^{3A}ₐ₃Si(OR^{0A})₍₄₋ₐ₁₋ₐ₂₋ₐ₃₎ (A-I)

(In the formula, R^{0A} is a hydrocarbon group having 1 to 6 carbon atoms, and R^{1A}, R^{2A}, and R^{3A} are each a hydrogen atom or a monovalent organic group having 1 to 30 carbon atoms. Further, a1, a2, and a3 are each 0 or 1, and satisfy 1≤a1+a2+a3≤3.); and

a titanium-containing compound obtained by subjecting one or more hydrolyzable titanium compounds represented by Formula (B-I) to hydrolysis, condensation, or the both as a component (B).

Ti(OR^{0B})4 (B-I)

(In the formula, R^{0B} is an organic group having 1 to 10 carbon atoms.)

JP2014-157242A describes a composition for forming a resist underlayer film, the composition including:

a silicon-containing compound obtained by subjecting one or more silicon compounds represented by Formula (A-1) to hydrolysis, condensation, or the both as a component (A):

R^{1A}ₐ₁R^{2A}ₐ₂R^{3A}ₐ₃Si(OR^{0A})₍₄₋ₐ₁₋ₐ₂₋ₐ₃₎ (A-1)

(In the formula, R^{OA} is a hydrocarbon group having 1 to 6 carbon atoms, any one or more of R^{1A}, R^{2A}, and R^{3A} are an organic having a nitrogen atom, a sulfur atom, a phosphorus atom, or an iodine atom, and the others are each a hydrogen atom or a monovalent organic group having 1 to 30 carbon atoms. Further, a1, a2, and a3 are each 0 or 1, and satisfy 1≤a1+a2+a3≤3.); and

JP2013-167669A describes a silicon-containing surface modifier containing any one or more of a constitutional unit represented by Formula (A) and a partial structure represented by Formula (C).

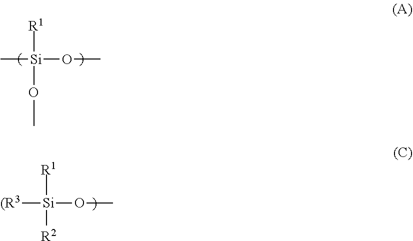

(In the formula, R¹ is an organic group having a hydroxyl group or carboxylic acid group, which is substituted with an acid-unstable group. R² and R³ are each independently the same as R¹, or are a hydrogen atom, or a monovalent organic group having 1 to 30 carbon atoms.)

### SUMMARY OF THE INVENTION

An object to be achieved by an embodiment of the present invention is to provide a pattern forming method which makes it possible to obtain a pattern having excellent etching resistance and enables excellent resolution.

Another object to be achieved by another embodiment of the present invention is to provide a resist laminate for organic solvent development, which makes it possible to obtain a pattern having excellent etching resistance and enables excellent resolution.

Units for achieving the objects include the following aspects.

<1> A pattern forming method, comprising:

preparing a laminate having a substrate, an inorganic base layer on the substrate, and a resist layer provided on the inorganic base layer in such a manner that the resist layer contacts the inorganic base layer;

exposing the resist layer; and

developing the laminate using a developer comprising an organic solvent to form a negative tone pattern,

in which a surface energy γA of the resist layer after irradiation of the laminate with ultraviolet rays having a wavelength of 13.5 nm from the resist layer side with an integrated light quantity of 40 mJ/cm², followed by heating of the laminate at 110° C. for 60 seconds is 60 mJ/m² or more,

in which a surface energy γB of the inorganic base layer after irradiation of the laminate with ultraviolet rays having a wavelength of 13.5 nm from the resist layer side with an integrated light quantity of 40 mJ/cm², followed by heating of the laminate at 110° C. for 60 seconds is 55 mJ/m² or more, and

a difference γ_{AB} in surface energies that is defined by Formula (A) is 5.0 mJ/m² or less:

γ_{AB}=γ_{A}−γ_{B} Formula (A).

<2> The pattern forming method as described in <1>,

in which the surface energy γA is 62 mJ/m² or more.

<3> The pattern forming method as described in <1> or <2>,

in which the surface energy γB is 60 mJ/m² or more.

<4> The pattern forming method as described in any one of <1> to <3>,

in which the exposing is performed with ultraviolet rays having a wavelength of 5 nm to 20 nm.

<5> The pattern forming method as described in any one of <1> to <4>,

in which the inorganic base layer is a layer comprising a silicon atom.

<6> The pattern forming method as described in any one of <1> to <5>,

in which the resist layer prior to the exposure comprises:

a resin having a constitutional unit having two or more phenolic hydroxyl groups and a constitutional unit having a polar group protected by an acid-decomposable group; and

a photoacid generator.

<7> The pattern forming method as described in <6>,

in which the constitutional unit having two or more phenolic hydroxyl groups is a constitutional unit represented by Formula (I-1).

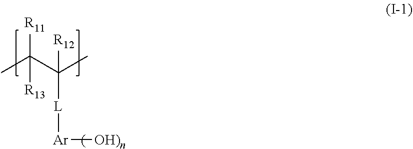

In Formula (I-1), R₁₁ and R₁₂ each independently represent a hydrogen atom or an alkyl group, R₁₃ represents a hydrogen atom or an alkyl group, or represents a single bond or an alkylene group, and is bonded to L or Ar to form a ring, where L represents a single bond or a divalent linking group and Ar represents an aromatic ring, and n represents an integer of 2 or more.

<8> The pattern forming method as described in any one of <1> to <7>,

in which a value of a pattern height/a pattern width in at least a part of an obtained pattern is 1.5 to 1.8.

<9> A resist laminate for organic solvent development, the resist laminate comprising:

a substrate;

an inorganic base layer on the substrate; and

a resist layer provided on the inorganic base layer in such a manner that the resist layer contacts the inorganic base layer,

in which a surface energy γA of the resist layer after irradiation of the laminate with ultraviolet rays having a wavelength of 13.5 nm from the resist layer side with an integrated light quantity of 40 mJ/cm², followed by heating of the laminate at 110° C. for 60 seconds is 60 mJ/m² or more,

a surface energy γB of the base layer after irradiation of the laminate with ultraviolet rays having a wavelength of 13.5 nm from the resist layer side with an integrated light quantity of 40 mJ/cm², followed by heating of the laminate at 110° C. for 60 seconds is 50 mJ/m² or more, and

a difference γ_{AB} in surface energies that is defined by Formula (A) is 5.0 mJ/m² or less:

γ_{AB}=γ_{A}−γ_{B} Formula (A).

<10> The resist laminate for organic solvent development as described in <9>,

in which the surface energy γA is 62 mJ/m² or more.

<11> The resist laminate for organic solvent development as described in <9> or <10>,

in which the surface energy γB is 60 mJ/m² or more.

<12> The resist laminate for organic solvent development as described in any one of <9> to <11>,

in which the inorganic base layer is a layer comprising a silicon atom.

<13> The resist laminate for organic solvent development as described in any one of <9> to <12>,

in which the resist layer comprises:

a resin having a constitutional unit having two or more phenolic hydroxyl groups and a constitutional unit having a polar group protected by an acid-decomposable group; and

a photoacid generator.

<14> The resist laminate for organic solvent development as described in <13>,

in which the constitutional unit having two or more phenolic hydroxyl groups is a constitutional unit represented by Formula (I-1).

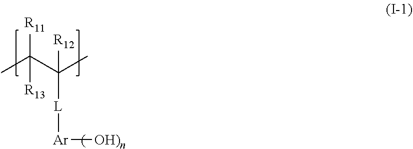

In Formula (I-1), R₁₁ and R₁₂ each independently represent a hydrogen atom or an alkyl group, R₁₃ represents a hydrogen atom or an alkyl group, or represents a single bond or an alkylene group, and is bonded to L or Ar to form a ring, where L represents a single bond or a divalent linking group and Ar represents an aromatic ring, and n represents an integer of 2 or more.

According to an embodiment of the present invention, it is possible to provide a pattern forming method which makes it possible to obtain a pattern having excellent etching resistance and enables excellent resolution.

According to another embodiment of the present invention, it is possible to provide a resist laminate for organic solvent development, which makes it possible to obtain a pattern having excellent etching resistance and enables excellent resolution.

### DESCRIPTION OF THE PREFERRED EMBODIMENTS

Hereinafter, the disclosure will be described in detail.

Description of configuration requirements described below may be made on the basis of representative embodiments of the present invention in some cases, but the present invention is not limited to such embodiments.

In citations for a group (atomic group) in the present specification, in a case where the group is cited without specifying whether it is substituted or unsubstituted, the group includes both a group having no substituent and a group having a substituent. For example, an “alkyl group” includes not only an alkyl group having no substituent (unsubstituted alkyl group), but also an alkyl group having a substituent (substituted alkyl group). In addition, an “organic group” in the present specification refers to a group including at least one carbon atom.

“Actinic rays” or “radiation” in the present specification means, for example, a bright line spectrum of a mercury lamp, far ultraviolet rays typified by an excimer laser, extreme ultraviolet rays (EUV light), X-rays, electron beams (EB), or the like. “Light” in the present specification means actinic rays or radiation unless otherwise specified.

Unless otherwise specified, “exposure” in the present specification encompasses not only exposure by a bright line spectrum of a mercury lamp, far ultraviolet rays typified by an excimer laser, extreme ultraviolet rays, X-rays, EUV light, or the like, but also exposure by particle rays such as electron beams and ion beams.

In the present specification, a numerical range expressed using “to” is used in a meaning of a range that includes the preceding and succeeding numerical values of “to” as the lower limit value and the upper limit value, respectively.

In the present specification, (meth)acrylate represents acrylate and methacrylate, and (meth)acryl represents acryl and methacryl.

In the present specification, the weight-average molecular weight (Mw), the number-average molecular weight (Mn), and the dispersity (also referred to as a molecular weight distribution) (Mw/Mn) of a resin component are each defined as a value converted in terms of polystyrene by means of gel permeation chromatography (GPC) measurement (solvent: tetrahydrofuran, flow amount (amount of a sample injected): 10 μL, columns: TSK gel Multipore HXL-M manufactured by Tosoh Corporation, column temperature: 40° C., flow rate: 1.0 mL/min, detector: differential refractive index detector) using a GPC apparatus (HLC-8120 GPC manufactured by Tosoh Corporation).

In the present specification, in a case where a plurality of substances corresponding to each component are present in a composition, the amount of each component in the composition is the total amount of the plurality of the corresponding substances which are present in the composition unless otherwise specified.

In the present specification, a “step” not only includes an independent step but also includes even a step which is not clearly distinguished from other steps as long as an intended purpose of the step is accomplished.

In the present specification, a “total solid content” refers to the total mass of components excluding a solvent from the total composition of a composition. In addition, a “solid content” is a component excluding the solvent as mentioned above, and may be either a solid or a liquid at 25° C., for example.

In the present specification, “% by mass” and “% by weight” have the same definition, and “part by mass” and “part by weight” also have the same definition.

In addition, in the present specification, a combination of two or more preferred aspects is a more preferable aspect.

(Pattern Forming Method)

The pattern forming method according to an embodiment of the disclosure includes a step of preparing a laminate having a substrate, an inorganic base layer on the substrate, and a resist layer provided on the inorganic base layer so that the resist layer is in contact with the inorganic base layer; a step of exposing the resist layer; and a step of developing the laminate with a developer including an organic solvent to form a negative tone pattern, in which a surface energy γA of the resist layer after irradiating the laminate with ultraviolet rays having a wavelength of 13.5 nm from the resist layer side with an integrated light quantity of 40 mJ/cm² and heating the laminate at 110° C. for 60 seconds is 60 mJ/m² or more, a surface energy γB of the inorganic base layer after irradiating the laminate with ultraviolet rays having a wavelength of 13.5 nm from the resist layer side with an integrated light quantity of 40 mJ/cm² and heating the laminate at 110° C. for 60 seconds is 55 mJ/m² or more, and a difference γ_{AB} in surface energy which is defined by Formula (A) is 5.0 mJ/m² or less.

γ_{AB}=γ_{A}−γ_{B} Formula (A).

The present inventors have conducted intensive studies, and as a result, they have found that a pattern forming method which makes it possible to obtain a pattern having excellent etching resistance and enables excellent resolution can be obtained.

Detailed mechanism by which the effects are obtained is unclear, but it is presumed that a difference between the surface energy of the inorganic base layer and the surface energy of the resist layer after exposure is set to 5.0 mJ/m² or less to improve the adhesiveness between the layers, the surface energy of the resist layer is further increased to the high value (hydrophilicity) shown above to suppress the penetration of an organic solvent developer during development, and thus, a pattern having excellent resolution and a high aspect ratio can be formed and the etching resistance of a pattern thus obtained pattern is also excellent.

Hereinafter, details of the pattern forming method according to the embodiment of the disclosure will be described.

<Preparing Step>

The pattern forming method according to the embodiment of the disclosure includes a step of preparing a laminate having a substrate, an inorganic base layer on the substrate, and a resist layer provided on the inorganic base layer so that the resist layer is in contact with the inorganic base layer.

The laminate may be manufactured in the preparing step, or a product which has been manufactured may be prepared.

<<Laminate>>

The laminate used in the disclosure has a substrate, an inorganic base layer on the substrate, and a resist layer provided on the inorganic base layer so that the resist layer is in contact with the inorganic base layer.

Furthermore, in the laminate used in the disclosure, a surface energy₇A of the resist layer after irradiating the laminate with ultraviolet rays having a wavelength of 13.5 nm from the resist layer side with an integrated light quantity of 40 mJ/cm² and heating the laminate at 110° C. for 60 seconds is 60 mJ/m² or more; in the laminate, a surface energy γB of the inorganic base layer after irradiating the laminate with ultraviolet rays having a wavelength of 13.5 nm from the resist layer side with an integrated light quantity of 40 mJ/cm² and heating the laminate at 110° C. for 60 seconds is 55 mJ/m² or more; and a difference γ_{AB} in surface energy which is defined by Formula (A) is 5.0 mJ/m² or less.

γ_{AB}=γ_{A}−γ_{B} Formula (A).

The surface energy γ_{A} of the resist layer after irradiating the laminate with ultraviolet rays having a wavelength of 13.5 nm from the resist layer side with an integrated light quantity of 40 mJ/cm² and heating the laminate at 110° C. for 60 seconds is 60 mJ/m² or more, and from the viewpoints of etching resistance and resolution, the surface energy γ_{A} is preferably 61 mJ/m² or more, more preferably 62 mJ/m² or more, still more preferably from 62 mJ/m² to 80 mJ/m², and particularly preferably from 62 mJ/m² to 70 mJ/m².

Furthermore, the surface energy γB of the inorganic base layer after irradiating the laminate with ultraviolet rays having a wavelength of 13.5 nm from the resist layer side at an integrated light quantity of 40 mJ/cm² and heating the laminate at 110° C. for 60 seconds is 55 mJ/m² or more, and from the viewpoints of etching resistance and resolution, the surface energy γ_{B} is preferably 58 mJ/m² or more, more preferably 60 mJ/m² or more, still more preferably from 61 mJ/m² to 80 mJ/m², and particularly preferably from 61 mJ/m² to 70 mJ/m².

Moreover, the difference γ_{AB} in the surface energy which is defined by Formula (A) is 5.0 mJ/m² or less, and from the viewpoint of etching resistance and resolvability, the difference γ_{AB} in the surface energy is preferably 4.0 mJ/m² or less, more preferably 3.0 mJ/m² or less, still more preferably 2.0 mJ/m² or less, and particularly preferably from −2.0 mJ/m² to 2.0 mJ/m².

The method for measuring the surface energies γ_{A} and γ_{B} in the disclosure shall be carried out by the following method. Further, the surface energy in the disclosure has the same definition as the surface free energy.

First, the laminate is irradiated with ultraviolet rays having a wavelength of 13.5 nm from the resist layer side at an integrated light quantity of 40 mJ/cm². After the irradiation, the laminate thus irradiated is heated at 110° C. for 60 seconds.

Next, the contact angle of pure water with respect to the surface of a sample cut out from the laminate after heating and the contact angle of diiodomethane with respect to the surface are each measured at 25° C. Measurement of these contact angles are performed by using, for example, a solid-liquid interface analyzer “Drop Master 500” manufactured by Kyowa Interface Science Co., Ltd. Based on these contact angles, the surface energies γ_{A} and γ_{B} are derived by an Owens-Wendt method described below.

—Owens-Wendt Method—

First, it is assumed that the surface energy gamma γᵢ of any substance i consists of a non-polar dispersion force item gamma γ^{d}ᵢ and a polar hydrogen bonding item gamma γ^{h}ᵢ.

γᵢ=γ^{d}ᵢ+γ^{h}ᵢ

Furthermore, it is assumed that the following equation is satisfied at an interface between a substance a and a substance b by an extended Fowkes model.

γ_{ab}=γₐ+γ_{b}−2(γ^{d}ₐγ_{d}^{b})^{0.5}−2(γ^{h}ₐγₕ^{b})^{0.5}

In a case of a liquid L and a solid S, upon combination of the equation with a Young's equation, the following equation involving a contact angle θ between the liquid L and the solid S is obtained.

γ_{L} cos θ=−γ_{L}+2(γ^{d}_{S}γ^{d}_{L})^{0.5}+2(γ^{h}_{S}γ^{h}_{L})^{0.5}

From this, the following equation is derived.

γ_{L}(1+cos θ)=2(γ^{d}_{S}γ^{d}_{L})^{0.5}+2(γ^{h}_{S}γ^{h}_{L})^{0.5}

The surface energies of the resist layer and the inorganic base layer are each calculated by measuring θ with liquids (water and diiodomethane) having known item values of the surface energies and solving simultaneous equations therewith.

Moreover, the items of each surface energy of water and diiodomethane are as follows.

Dispersion force item γ^{d} of water: 21.8 mJ/m²

Hydrogen bonding item γ^{h} of water: 51.0 mJ/m²

Surface energy γ of water: 72.8 mJ/m²

Value of (γ^{d})^{0.5} of water: 4.7 (mJ/m²)^{0.5}

Value of (γ^{h})^{0.5} of water: 7.1 (mJ/m²)^{0.5}

Dispersion force item γ^{d} of diiodomethane: 49.5 mJ/m²

Hydrogen bonding item γ^{h} of diiodomethane: 1.3 mJ/m²

Surface energy γ of diiodomethane: 50.8 mJ/m²

Value of (γ^{d})^{0.5} of diiodomethane: 7.0 (mJ/m²)^{0.5}

Value of (γ^{h})^{0.5} of diiodomethane: 1.1 (mJ/m²)^{0.5}

—Substrate—

The laminate used in the disclosure has an inorganic base layer and a resist layer on a substrate.

The substrate is not particularly limited, and a substrate which is generally used in a step of manufacturing a semiconductor such as an integrated circuit (IC), and a process for manufacturing a circuit board for a liquid crystal, a thermal head, or the like, other lithographic processes of photofabrication, and the like can be used.

Specific examples of the substrate include inorganic substrates whose materials are Si, amorphous silicon (α-Si), p-Si, SiO₂, SiN, SiON, W, TiN, Al, or the like.

Furthermore, preferred examples of the substrate include a substrate (examples: silicon and silicon dioxide coating) used for manufacturing an integrated circuit (IC) element.

In addition, the substrate may have known members or known layers such as an electrode, a wiring, and various base films (an antireflection film and the like).

—Inorganic Base Layer—

The laminate used in the disclosure has an inorganic base layer provided in contact with the resist layer.

The inorganic base layer is a layer including an inorganic compound, and the content of the inorganic compound is preferably 10% by mass or more, and more preferably 70% by mass or more with respect to the total mass of the inorganic base layer.

From the viewpoint of etching resistance, the inorganic base layer is preferably a layer including a metal atom, more preferably a layer including at least one metal atom selected from the group consisting of boron, silicon, aluminum, gallium, yttrium, germanium, titanium, zirconium, hafnium, bismuth, tin, vanadium, niobium, and tantalum, still more preferably a layer including at least one metal atom selected from the group consisting of silicon and titanium, and particularly preferably a layer including a silicon atom.

Preferred examples of the inorganic compound used for forming the inorganic base layer include a metal compound.

Suitable examples of the metal compound include an alkoxy metal compound, a metal halide, a metal hydroxide, and a metal oxide.

Among those, in a case of performing hydrolysis and condensation form the inorganic base layer, at least one compound selected from the group consisting of an alkoxy metal compound and a metal halide is preferable.

In the hydrolysis and condensation, only one kind of hydrolyzable and condensable metal compound such as an alkoxy metal compound or a metal halide may be hydrolyzed and condensed, or two or more kinds of hydrolyzable and condensable metal compounds may be hydrolyzed and condensed.

Examples of the alkoxysilane compound used in the disclosure include trimethoxysilane, triethoxysilane, tripropoxysilane, triisopropoxysilane, methyltrimethoxysilane, methyltriethoxysilane, methyltripropoxysilane, and methyltriisopropoxysilane, ethyltrimethoxysilane, ethyltriethoxysilane, ethyltripropoxysilane, ethyltriisopropoxysilane, vinyltrimethoxysilane, vinyltriethoxysilane, vinyltripropoxysilane, vinyltriisopropoxysilane, propyltrimethoxysilane, propyltriethoxysilane, propyltripropoxysilane, propyltriisopropoxysilane, isopropyltrimethoxysilane, isopropyltriethoxysilane, isopropyltripropoxysilane, isopropyltriisopropoxysilane, butyltrimethoxysilane, butyltriethoxysilane, butyltripropoxysilane, butyltriisopropoxysilane, sec-butyltrimethoxysilane, sec-butyltriethoxysilane, sec-butyltripropoxysilane, sec-butyltriisopropoxysilane, t-butyltrimethoxysilane, t-butyltriethoxysilane, t-butyltripropoxysilane, t-butyltriisopropoxysilane, cyclopropyltrimethoxysilane, cyclopropyltriethoxysilane, cyclopropyltripropoxysilane, cyclopropyltriisopropoxysilane, cyclobutyltrimethoxysilane, cyclobutyltriethoxysilane, cyclobutyltripropoxysilane, cyclobutyltriisopropoxysilane, cyclopentyltriethoxysilane, cyclopentyltriethoxysilane, cyclopentyltripopoxysilane, cyclopentyltripropoxysilane, cyclohexyltrimethoxysilane, cyclohexyltriethoxysilane, cyclohexyltripropoxysilane, cyclohexyltriisopropoxysilane, cyclohexenyltrimethoxysilane, cyclohexenyltriethoxysilane, cyclohexenyltripropoxysilane, cyclohexenyltriisopropoxysilane, cyclohexenylethyltrimethoxysilane, cyclohexenylethyltriethoxysilane, cyclohexenylethyltripropoxysilane, cyclohexenylethyltriisopropoxysilane, cyclooctyltrimethoxysilane, cyclooctyltriethoxysilane, cyclooctyltripropoxysilane, cyclooctyltriisopropoxysilane, cyclopentadienylpropyltrimethoxysilane, cyclopentadienylpropyltriethoxysilane, cyclopentadienylpropyltripropoxysilane, cyclopentadienylpropyltriisopropoxysilane, bicycloheptenyltrimethoxysilane, bicycloheptenyltriethoxysilane, bicycloheptenyltripropoxysilane, bicycloheptenyltriisopropoxysilane, bicycloheptyltrimethoxysilane, bicycloheptyltriethoxysilane, bicycloheptyltripropoxysilane, bicycloheptyltriisopropoxysilane, adamantyltrimethoxysilane, adamantyltriethoxysilane, adamantyltripropoxysilane, adamantyltripropoxysilane, phenyltrimethoxysilane, phenyltriethoxysilane, phenyltripropoxysilane, phenyltriisopropoxysilane, benzyltrimethoxysilane, benzyltriethoxysilane, benzyltripropoxysilane, benzyltriisopropoxysilane, tolyltrimethoxysilane, tolyltriethoxysilane, tolyltriisopropoxysilane, tolyltriisopropoxysilane, anisyltrimethoxysilane, anisyltriethoxysilane, anisyltripropoxysilane, anisyltriisopropoxysilane, phenethyltrimethoxysilane, phenetyltriethoxysilane, phenetyltripropoxysilane, phenetytriisopropoxysilane, naphthyltrimethoxysilane, naphthyltriethoxysilane, naphthyltripropoxysilane, naphthyltriisopropoxysilane, dimethyldimethoxysilane, dimethyldiethoxysilane, methylethyldimethoxysilane, methylethyldiethoxysilane, dimethyldipropoxysilane, dimethyldiisopropoxysilane, diethyldimethoxysilane, diethyldiethoxysilane, diethyldipropoxysilane, diethyldiisopropoxysilane, dipropyldimethoxysilane, dipropyldiethoxysilane, dipropyldipropoxysilane, dipropyldiisopropoxysilane, diisopropyldimethoxysilane, diisopropyldiethoxysilane, diisopropyldipropoxysilane, diisopropyldiisopropoxysilane, dibutyldimethoxysilane, dibutyldiethoxysilane, dibutyldipropoxysilane, dibutyldiisopropoxysilane, di-sec-butyldimethoxysilane, di-sec-butyldiethoxysilane, di-sec-butyldipropoxysilane, di-sec-butyldiisopropoxysilane, di-t-butyldimethoxysilane, di-t-butyldiethoxysilane, di-t-butyldipropoxysilane, di-t-butyldiisopropoxysilane, dicyclopropyldimethoxysilane, dicyclopropyldiethoxysilane, dicyclopropyldipropoxysilane, dicyclopropyldiisopropoxysilane, dicyclobutyldimethoxysilane, dicyclobutyldiethoxysilane, dicyclobutyldipropoxysilane, dicyclobutyldiisopropoxysilane, dicyclopentyldimethoxysilane, dicyclopentyldiethoxysilane, dicyclopentyldipropoxysilane, dicyclopentyldiisopropoxysilane, dicyclohexyldimethoxysilane, dicyclohexyldiethoxysilane, dicyclohexyldipropoxysilane, dicyclohexyldiisopropoxysilane, dicyclohexenyldimethoxysilane, dicyclohexenyldiethoxysilane, dicyclohexenyldipropoxysilane, dicyclohexenyldiisopropoxysilane, dicyclohexenylethyldimethoxysilane, dicyclohexenylethyldiethoxysilane, dicyclohexenylethyldipropoxysilane, dicyclohexenylethyldiisopropoxysilane, dicyclooctyldimethoxysilane, dicyclooctyldiethoxysilane, dicyclooctyldipropoxysilane, dicyclooctyldiisopropoxysilane, dicyclopentadienylpropyldimethoxysilane, dicyclopentadienylpropyldiethoxysilane, dicyclopentadienylpropyldipropoxysilane, dicyclopentadienylpropyldiisopropoxysilane, bis(bicycloheptenyl)dimethoxysilane, bis(bicycloheptenyl)diethoxysilane, bis(bicycloheptenyl)dipropoxysilane, bis(bicycloheptenyl)diisopropoxysilane, bis(bicycloheptyl)dimethoxysilane, bis(bicycloheptyl)diethoxysilane, bis(bicycloheptyl)dipropoxysilane, bis(bicycloheptyl)diisopropoxysilane, diadamantyldimethoxysilane, diadamantyldiethoxysilane, diadamantyldipropoxysilane, diadamantyldiisopropoxysilane, diphenyldimethoxysilane, diphenyldiethoxysilane, methylphenyldimethoxysilane, methylphenyldiethoxysilane, diphenyldipropoxysilane, diphenyldiisopropoxysilane, trimethylmethoxysilane, trimethylethoxysilane, dimethylethylmethoxysilane, dimethylethylethoxysilane, dimethylphenylmethoxysilane, dimethylphenylethoxysilane, dimethylbenzylmethoxysilane, dimethylbenzylethoxysilane, dimethylphenethylmethoxysilane, dimethylphenethylethoxysilane, tetramethoxysilane, tetraethoxysilane, tetrapropoxysilane, tetraisopropoxysilane, tetrabutoxysilane, tetraphenoxysilane, and tetraacetoxysilane.

Furthermore, examples of the titanium compound used in the disclosure include titanium methoxide, titanium ethoxide, titanium propoxide, titanium butoxide, titanium amyloxide, titanium hexyloxide, titanium cyclopentoxide, titanium cyclohexyloxide, titanium allyloxide, titanium phenoxide, titanium methoxyethoxide, titanium ethoxyethoxide, titanium dipropoxybisethylacetoacetate, titanium dibutoxybisethylacetoacetate, titanium dipropoxybis-2,4-pentanedionate, and titanium dibutoxybis-2,4-pentanedionate.

A method for forming an inorganic base layer is not particularly limited, but the inorganic base layer can be formed by a known method such as a sputtering method, a vapor deposition method, and a coating method.

Among those, the coating method is preferable, and a spin coating method is more preferable.

Examples of an aqueous solvent which may be included in a coating liquid for forming an inorganic base layer, which is used for forming an inorganic base layer, include water and a water-soluble organic solvent.

Examples of the water-soluble organic solvent include methanol, ethanol, 1-propanol, 2-propanol, 1-butanol, 2-butanol, 2-methyl-1-propanol, acetone, tetrahydrofuran, acetonitrile, propylene glycol monomethyl ether, ethylene glycol monomethyl ether, propylene glycol monoethyl ether, ethylene glycol monoethyl ether, propylene glycol monopropyl ether, ethylene glycol monopropyl ether, propylene glycol dimethyl ether, diethylene glycol dimethyl ether, propylene glycol monomethyl ether acetate, propylene glycol monoethyl ether acetate, and propylene glycol monopropyl ether acetate.

Furthermore, an auxiliary solvent may be added, in addition to the water-soluble organic solvent.

Examples of the auxiliary solvent include toluene, hexane, ethyl acetate, cyclohexanone, methyl amyl ketone, propylene glycol dimethyl ether, diethylene glycol dimethyl ether, propylene glycol monomethyl ether acetate, propylene glycol monoethyl ether acetate, ethyl pyruvate, butyl acetate, methyl 3-methoxypropionate, ethyl 3-ethoxypropionate, t-butyl acetate, t-butyl propionate, propylene glycol mono-t-butyl ether acetate, γ-butyrolactone, methyl isobutyl ketone, and cyclopentyl methyl ether.

The solid content of the coating liquid for forming an inorganic base layer is not particularly limited, but is preferably 0.1% by mass to 20% by mass.

In addition, the solid content can be adjusted so that it can be easily applied at the time of application.

Moreover, the inorganic base layer may include other known components.

Examples of other components include a photoacid generator, a thermal crosslinking accelerator, an organic acid, a stabilizer, and a surfactant.

Examples thereof include those described in JP2013-167669A.

The thickness of the inorganic base film is not particularly limited, the inorganic base film may be formed with any thickness as desired, but the thickness is preferably from 1 nm to 500 nm, more preferably from 1 nm to 300 nm, and particularly preferably from 1 nm to 200 nm.

—Resist Layer—

The laminate used in the disclosure has a resist layer provided in contact with the inorganic base layer.

The resist layer is preferably a resist layer for developing an organic solvent.

Furthermore, the resist layer is preferably a chemically amplified resist layer from the viewpoint of resolution and sensitivity.

In addition, the resist layer is preferably a negative tone resist layer. For example, it is also possible to select a positive tone or negative tone resist layer, depending on the polarity of a developer such as an organic solvent used for development.

Moreover, it is preferable that the resist layer includes a resin having a constitutional unit having two or more phenolic hydroxyl groups and a constitutional unit having a polar group protected by an acid-decomposable group (hereinafter also referred to as a resin (A)), and a photoacid generator, from the viewpoint of etching resistance and resolution.

[Resin (A)]

From the viewpoint of etching resistance and resolution, it is preferable that the resist layer includes a resin having a constitutional unit having two or more phenolic hydroxyl groups and a constitutional unit having a polar group protected by an acid-decomposable group (resin (A)) as a base resin, and it is more preferable that the resist layer includes a resin having a constitutional unit (a) having two or more phenolic hydroxyl groups, represented by Formula (I-1), and a constitutional unit (b) having a group in which a protecting group including a monocycle is eliminated by an action of an acid to generate a polar group (hereinafter referred to as “a polar group protected by an acid-decomposable group”).

[[Constitutional Unit (a)]]

The constitutional unit (a) having two or more phenolic hydroxyl groups is preferably a constitutional unit represented by Formula (I-1) from the viewpoint of etching resistance and resolution.

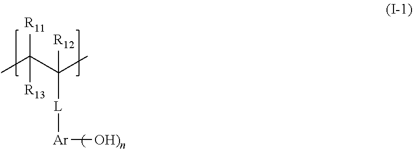

In Formula (I-1), R₁₁ and R₁₂ each independently represent a hydrogen atom or an alkyl group, R₁₃ represents a hydrogen atom or an alkyl group, or represents a single bond or an alkylene group, and is bonded to L or Ar to form a ring, where L represents a single bond or a divalent linking group and Ar represents an aromatic ring, and n represents an integer of 2 or more.

Examples of the alkyl group represented by each of R₁₁, R₁₂, and R₁₃ in Formula (I-1) include a methyl group, an ethyl group, a propyl group, an isopropyl group, an n-butyl group, a sec-butyl group, a hexyl group, a 2-ethylhexyl group, an octyl group, a dodecyl group, and other alkyl groups having 20 or less carbon atoms. In one aspect, the alkyl group represented by each of R₁₁, R₁₂, and R₁₃ is preferably an alkyl group having 8 or less carbon atoms, and more preferably an alkyl group having 3 or less carbon atoms.

Incidentally, the alkyl group represented by each of R₁₁, R₁₂, and R₁₃ may have a substituent. Preferred examples of the substituent include a cycloalkyl group, an aryl group, an amino group, an amido group, a ureido group, a urethane group, a hydroxyl group, a carboxyl group, a halogen atom, an alkoxy group, a thioether group, an acyl group, an acyloxy group, an alkoxycarbonyl group, a cyano group, and a nitro group, and the substituent preferably has 8 or less carbon atoms.

Examples of the divalent linking group represented by L include an ester bond, —CONR₆₄ (R₆₄ represents a hydrogen atom or an alkyl group)-, an alkylene group, or a combination of two or more selected from any of these groups.

Preferred examples of the alkyl group of R₆₄ in —CONR₆₄— (R₆₄ represents a hydrogen atom or an alkyl group) include an alkyl group having 20 or less carbon atoms, such as a methyl group, an ethyl group, a propyl group, an isopropyl group, an n-butyl group, a sec-butyl group, a hexyl group, a 2-ethylhexyl group, an octyl group, and a dodecyl group, each of which may have a substituent, and more preferred examples of the alkyl group include an alkyl group having 8 or less carbon atoms. Further, in one embodiment, —CONR₆₄— is preferably —CONH—.

Examples of the alkylene group represented by L include those having 1 to 8 carbon atoms, such as a methylene group, an ethylene group, a propylene group, a butylene group, a hexylene group, and an octylene group. The alkylene group may have a substituent.

Furthermore, L is preferably a single bond, an ester bond, or —CONH—, more preferably the single bond or the ester bond, and particularly preferably the single bond.

Examples of the aromatic ring represented by Ar include an aromatic hydrocarbon ring having 6 to 18 carbon atoms, such as a benzene ring, a naphthalene ring, an anthracene ring, a fluorene ring, and a phenanthrene ring, or an aromatic ring heterocycle including a heterocycle, such as a thiophene ring, a furan ring, a pyrrole ring, a benzothiophene ring, a benzofuran ring, a benzopyrrole ring, a triazine ring, an imidazole ring, a benzimidazole ring, a triazole ring, a thiadiazole ring, and a thiazole ring. Among these, the benzene ring or the naphthalene ring is preferable, and the benzene ring is more preferable, from the viewpoint of resolution.

Such an aromatic ring may have a substituent. Preferred examples of the substituent include the specific examples of the alkyl group represented by each of R₁₁, R₁₂, and R₁₃ as mentioned above; alkoxy groups such as a methoxy group, an ethoxy group, a hydroxyethoxy group, a propoxy group, a hydroxypropoxy group, and a butoxy group; and aryl groups such as a phenyl group.

n represents an integer of 2 or more, preferably represents an integer from 2 to 5, and is more preferably 2 or 3.

The resin (A) may contain two or more kinds of the constitutional units (a).

Specific examples of the constitutional unit (a) will be shown below, but the present invention is not limited thereto. In the formula, R represents a hydrogen atom or a methyl group, and a represents 2 or 3.

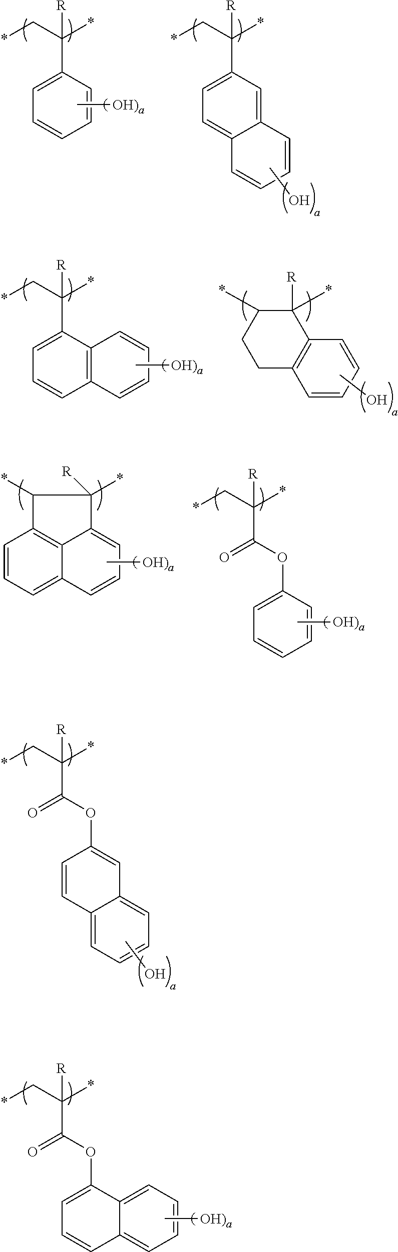

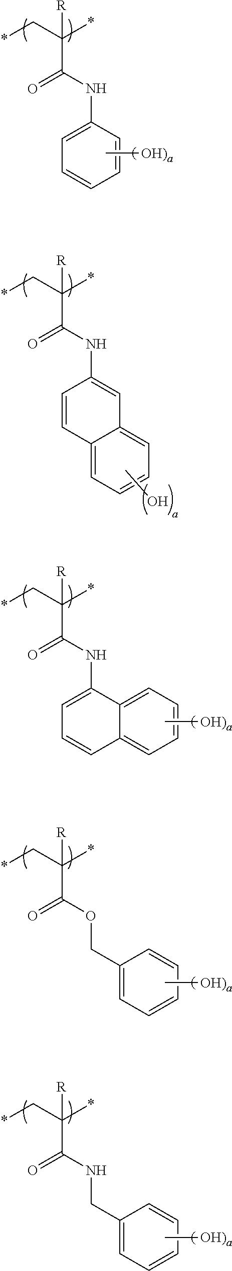

The content of the constitutional unit (a) (the total content in a case where two or more kinds thereof are contained) is preferably 5% by mole to 60% by mole, more preferably 10% by mole to 50% by mole, and still more preferably 20% by mole to 40% by mole with respect to the total content of the constitutional units of the resin (A), from the viewpoint of achieving both the reactivity of the resin (A) and an ability to suppress the diffusion of an acid generated.

In addition, in the disclosure, in a case where the content of the “constitutional unit” is provided in terms of the molar ratio, the “constitutional unit” has the same definition as the “monomer unit”. Further, in the disclosure, the “monomer unit” may be modified after the polymerization by a polymer reaction or the like. The same applies to the following.

[[Constitutional Unit (b)]]

The constitutional unit (b) is a constitutional unit having a polar group protected by an acid-decomposable group, and is preferably a constitutional unit having an acid-decomposable group in which a protecting group including a monocycle is eliminated by an action of an acid to generate a polar group.

As compared with a protecting group including a polycyclic structure or a protecting group including a chain group, the protecting group including a monocycle can achieve both of a high deprotection reactivity in the acid-decomposable group and low diffusivity of an acid generated.

Here, the monocycle included in the protecting group of the constitutional unit (b) is an aliphatic ring and may include an unsaturated bond. Further, the monocycle is preferably a monocyclic hydrocarbon group consisting of only carbon atoms and hydrogen atoms.

From the viewpoint of hydrophilicity, it is preferable that the number of carbon atoms constituting the monocycle is small.

The number of carbon atoms constituting the monocycle is preferably 5 to 10, more preferably 5 to 8, and still more preferably 5 to 7.

The monocycle may have a substituent, and the substituent may include an atom other than the carbon atom and the hydrogen atom. Examples of the substituent which may be contained include an alkyl group (having 1 to 4 carbon atoms), a halogen atom, a hydroxyl group, an alkoxy group (having 1 to 4 carbon atoms), a carboxyl group, an alkoxycarbonyl group (having 2 to 6 carbon atoms), a cyan group, an amino group, a sulfonamido group, and an alkylamido group.

In the constitutional unit (b), examples of the polar group generated by elimination of the protecting group including a monocyclic hydrocarbon group by an action of an acid include a carboxyl group (aliphatic carboxyl group), an aromatic carboxyl group, a phenolic hydroxyl group, and a hydroxyl group (aliphatic hydroxyl group). Among these, the polar group is preferably the carboxyl group.

Here, it is preferable that the polar group is a carboxyl group from the viewpoint of achieving both of a high reactivity in the resin (A) and an ability to suppress the diffusion of an acid generated. For example, in a case where the polar group is the carboxyl group, in particular, the Tg after exposure is high and the suppression of diffusion of an acid is excellent, as compared with a case where the polar group is the phenolic hydroxyl group or the hydroxyl group. In addition, in a case of combination with a protecting group, the acid strength of the polar group is higher, and thus, the deprotection reactivity is excellent.

The constitutional unit (b) is preferably, for example, a constitutional unit represented by Formula (pA).

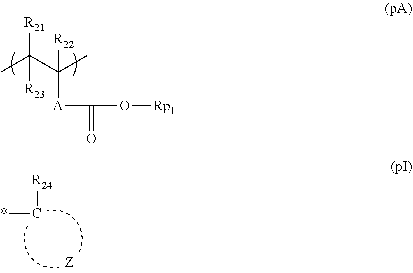

In Formula (pA),

R₂₁, R₂₂, and R₂₃ each independently represent a hydrogen atom or an alkyl group.

A represents a single bond or a divalent linking group.

Rp₁ represents a group represented by Formula (pI).

In Formula (pI),

R₂₄ represents a methyl group, an ethyl group, an n-propyl group, an isopropyl group, an n-butyl group, an isobutyl group, a sec-butyl group, or a tert-butyl group. Further, R₂₄ is preferably the methyl group.

Z represents an atomic group which is required to form a monocyclic cycloalkyl group together with the carbon atom in the formula.

* represents a linking moiety with the rest of the constitutional unit represented by Formula (pA).

Specific examples of the alkyl group represented by each of R₂₁, R₂₂, and R₂₃ in Formula (pA) include the same ones of the specific examples exemplified as the alkyl group represented by each of R₁₁, R₁₂, and R₁₃ in Formula (I-1) as mentioned above, and preferred specific examples thereof are also the same.

The alkyl group represented by each of R₂₁, R₂₂, and R₂₃ may have a substituent. Preferred specific examples of the substituent include specific examples include the same ones of the specific examples exemplified as the substituent which may be contained in the alkyl group represented by each of R₁₁, R₁₂, and R₁₃ in Formula (I-1) as mentioned above.

Examples of the divalent linking group represented by A include an arylene group and a —COO-Rt- group. In the formula, Rt represents an alkylene group or a cycloalkylene group.

Incidentally, A is preferably a single bond.

As mentioned above, Z represents an atomic group which is required to form a cycloalkyl group together with the carbon atom in the formula. From the viewpoint of hydrophilicity, the number of carbon atoms of the cycloalkyl group formed by Z together with the carbon atom in the formula is preferably 5 to 10, more preferably 5 to 8, and still more preferably 5 to 7.

The constitutional unit (b) may be a constitutional unit represented by Formula (pB).

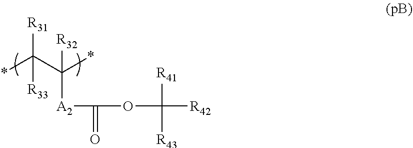

In Formula (pB),

R₃₁, R₃₂, and R₃₃ each independently represent a hydrogen atom or an alkyl group.

A₂ represents a single bond or a divalent linking group.

R₄₁, R₄₂, and R₄₃ each independently represent a linear or branched alkyl group, or a monocyclic or polycyclic cycloalkyl group. It should be noted that at least one of R₄₁, R₄₂, or R₄₃ represents a monocyclic cycloalkyl group.

Specific examples of the alkyl group represented by each of R₃₁, R₃₂, and R₃₃ in Formula (pB) include the same ones of the specific examples of the alkyl group represented by each of R₁₁, R₁₂, and R₁₃ on Formula (I-1), and preferred specific examples are also the same.

The alkyl group represented by each of R₃₁, R₃₂, and R₃₃ may have a substituent. Preferred specific examples of the substituent include specific examples include the same ones of the specific examples exemplified as the substituent which may be contained in the alkyl group represented by each of R₁₁, R₁₂, and R₁₃ in Formula (I-1) as mentioned above.

Examples of the divalent linking group represented by A₂ include the specific examples exemplified as the divalent linking group represented by A in Formula (pA) as mentioned above.

Furthermore, A₂ is preferably a single bond.

As the linear or branched alkyl group represented by each of R₄₁, R₄₂, and R₄₃, for example, an alkyl group having 1 to 4 carbon atoms, such as a methyl group, an ethyl group, an n-propyl group, an isopropyl group, an n-butyl group, an isobutyl group, and a t-butyl group, is preferable.

The monocyclic cycloalkyl group represented by each of R₄₁, R₄₂, and R₄₃ is preferably a cycloalkyl group having 5 to 10 carbon atoms, more preferably a cycloalkyl group having 5 to 8 carbon atoms, and still more preferably a cycloalkyl group having 5 to 7 carbon atoms.

As the polycyclic cycloalkyl group represented by each of R₄₁, R₄₂, and R₄₃, a polycyclic cycloalkyl group such as a norbornyl group, a tetracyclodecanyl group, a tetracyclododecanyl group, and an adamantyl group is preferable.

The resin (A) may contain two or more kinds of constitutional units (b).

Specific examples of the constitutional unit (b) are shown below, but the disclosure is not limited thereto. In the formula, R represents a hydrogen atom or a methyl group, and Rx's each independently represent an alkyl group having 1 to 4 carbon atoms.

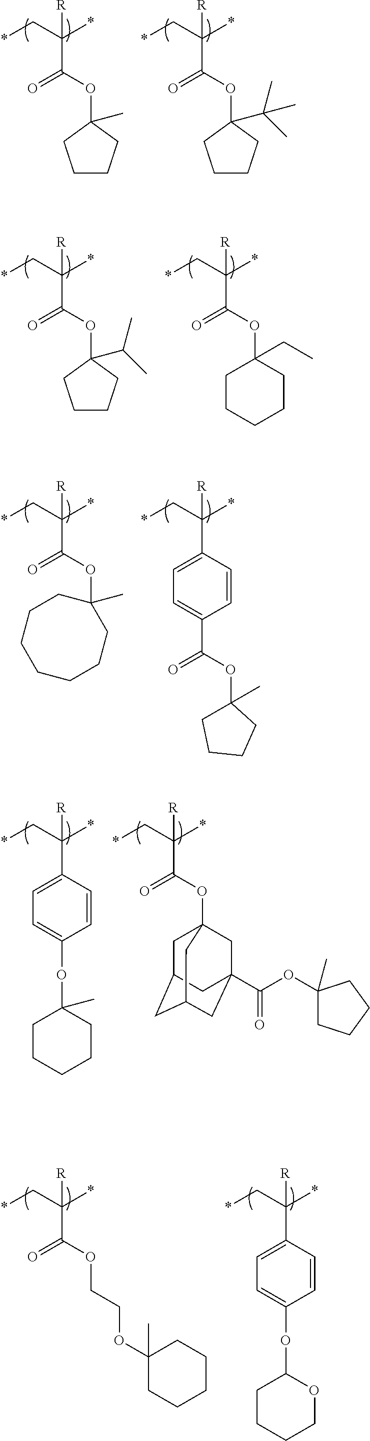

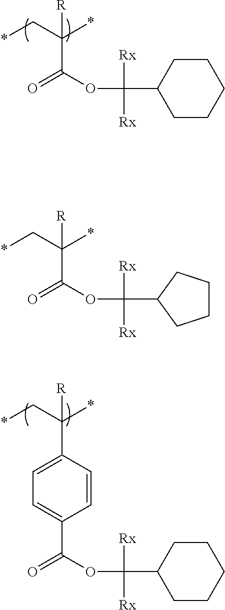

The content of the constitutional unit (b) (the total content in a case where two or more kinds thereof are contained) is preferably 20% by mole to 90% by mole, more preferably 25% by mole to 80% by mole, and still more preferably 30% by mole to 70% by mole with respect to all the constitutional units in the resin (A).

The resin (A) may further contain the constitutional unit (b) different from the constitutional unit having an acid-decomposable group in which a protecting group including a monocycle is eliminated by an action of an acid to generate a polar group as mentioned above.

A constitutional unit having a group that decomposes by an action of an acid to generate a carboxyl group is a constitutional unit having a group substituted with a group in which a hydrogen atom of the carboxyl group is eliminated through decomposition by an action of an acid.

Examples of the group which is eliminated by an acid include —C(R₃₆)(R₃₇)(R₃₈), —C(R₃₆)(R₃₇)(OR₃₉), and —C(R₀₁)(R₀₂)(OR₃₉).

In the formulae, R₃₆ to R₃₉ each independently an alkyl group, a polycyclic cycloalkyl group, an aryl group, an aralkyl group, or an alkenyl group. R₃₆ and R₃₇ may be bonded to each other to form a ring.

R₀₁ and R₀₂ each independently represent a hydrogen atom, an alkyl group, a polycyclic cycloalkyl group, an aryl group, an aralkyl group, or an alkenyl group.

As the constitutional unit having a group which decomposes by an action of an acid to generate a carboxyl group, a constitutional unit represented by Formula (AI) is preferable.

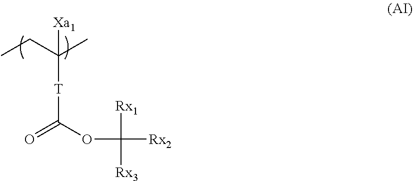

In Formula (AI),

Xa₁ represents a hydrogen atom, or an alkyl group which may have a substituent.

T represents a single bond or a divalent linking group.

Rx₁ to Rx₃ each independently represent an (linear or branched) alkyl group or a polycyclic cycloalkyl group. It should be noted that in a case where all of Rx₁ to Rx₃ are (linear or branched) alkyl groups, it is preferable that at least two of Rx₁, . . . , or Rx₃ are methyl groups.

Two of Rx₁ to Rx₃ may be bonded to each other to form a polycyclic cycloalkyl group.

Examples of the alkyl group which may have a substituent, represented by Xa₁, include a methyl group or a group represented by —CH₂-Rx₁₁. Examples of Rx₁₁ include a halogen atom (a fluorine atom and the like), a hydroxyl group, or a monovalent organic group, for example, an alkyl group having 5 or less carbon atoms and an acyl group having 5 or less carbon atoms, and Rx₁₁ is preferably an alkyl group having 3 or less carbon atoms, and more preferably a methyl group. Xa₁ is preferably the hydrogen atom, a methyl group, a trifluoromethyl group, or a hydroxymethyl group.

Examples of the divalent linking group of T include an alkylene group, an arylene group, a —COO-Rt- group, and an —O-Rt- group. Rt represents an alkylene group or a cycloalkylene group.

T is preferably the single bond, the arylene group or the —COO-Rt- group, and more preferably the single bond or the arylene group. As the arylene group, an arylene group having 6 to 10 carbon atoms is preferable, and a phenylene group is more preferable. Rt is preferably an alkylene group having 1 to 5 carbon atoms, and more preferably a —CH₂— group, a —(CH₂)₂— group, or a —(CH₂)₃— group.

As the alkyl group of each of Rx₁ to Rx₃, an alkyl group having 1 to 4 carbon atoms, such as a methyl group, an ethyl group, an n-propyl group, an isopropyl group, an n-butyl group, an isobutyl group, and a t-butyl group, is preferable.

Examples of the polycyclic cycloalkyl group of each of Rx₁ to Rx₃ include polycyclic cycloalkyl groups such as a norbornyl group, a tetracyclodecanyl group, a tetracyclododecanyl group, and an adamantyl group.

As the polycyclic cycloalkyl group formed by the bonding of two of Rx₁ to Rx₃, a polycyclic cycloalkyl group such as a norbornyl group, a tetracyclodecanyl group, a tetracyclododecanyl group, or an adamantyl group is preferable.

In the polycyclic cycloalkyl group formed by the bonding of two of Rx₁ to Rx₃, for example, one of the methylene groups constituting the ring may be substituted with a heteroatom such as an oxygen atom, or a group having a heteroatom, such as a carbonyl group.

Each of the groups may have a substituent, and examples of the substituent include an alkyl group (having 1 to 4 carbon atoms), a halogen atom, a hydroxyl group, an alkoxy group (having 1 to 4 carbon atoms), a carboxyl group, and an alkoxycarbonyl group (having 2 to 6 carbon atoms), and these groups preferably have 8 or less carbon atoms.

The constitutional unit represented by Formula (AI) is preferably an acid-decomposable tertiary alkyl (meth)acrylic ester-based constitutional unit (Xa₁ represents a hydrogen atom or a methyl group, and T represents a single bond). The constitutional unit represented by Formula (AI) is more preferably the constitutional unit in which Rx₁ to Rx₃ each independently represent a linear or branched alkyl group, and still more preferably the constitutional unit in which Rx₁ to Rx₃ each independently represent the linear alkyl group.

Specific examples of the constitutional unit having a group which decomposes by an action of an acid to generate a carboxyl group are shown below, but the disclosure is not limited thereto.

In the specific examples, Rx and Xa₁ each represent a hydrogen atom, CH₃, CF₃, or CH₂OH. Rxa and Rxb each represent an alkyl group having 1 to 4 carbon atoms. Z represents a substituent including a polar group, and in a case where there are a plurality of Z's, Z's are each independent. p represents 0 or a positive integer. Examples of the substituent including a polar group represented by Z include a linear or branched alkyl group or cycloalkyl group, which has a hydroxyl group, a cyano group, an amino group, an alkylamido group, or a sulfonamido group, and the substituent is preferably an alkyl group having a hydroxyl group. As the branched alkyl group, an isopropyl group is particularly preferable.

Furthermore, as a specific example of the constitutional unit having a group that decomposes by an action of an acid to generate a carboxyl group, the specific examples described in paragraphs 0227 to 0233 of JP2014-232309A can be incorporated herein, and the contents of the publication are incorporated herein by reference.

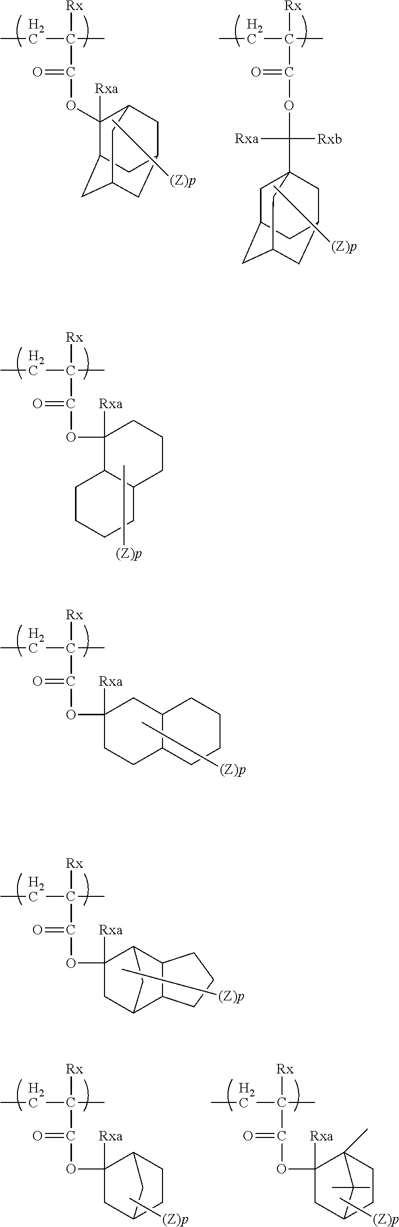

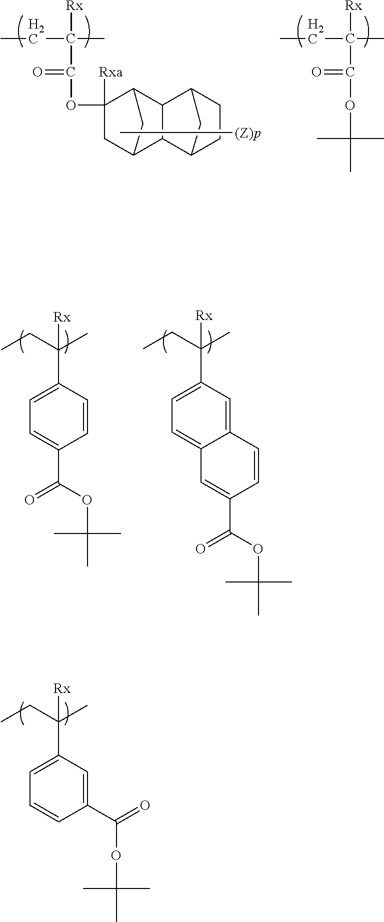

In a case where the resin (A) contains a constitutional unit having a group that decomposes by an action of an acid to generate a carboxyl group, the content of the constitutional unit is preferably 20% by mole to 90% by mole, more preferably 25% by mole to 80% by mole, and still more preferably 30% by mole to 70% by mole with respect to all the constitutional units in the resin (A).

[[Constitutional Unit Having at Least One Selected from Group Consisting of Lactone Structure, Sultone Structure, and Carbonate Structure]]

The resin (A) preferably has a constitutional unit having at least one selected from the group consisting of a lactone structure, a sultone structure, and a carbonate structure.

As the lactone structure or the sultone structure, any one having a lactone structure or a sultone structure can be used, but the lactone structure or the sultone structure is preferably a 5- to 7-membered ring lactone structure or a 5- to 7-membered ring sultone structure, and more preferably a 5- to 7-membered ring lactone structure to which another ring structure is fused so as to form a bicyclo structure or a spiro structure, or a 5- to 7-membered ring sultone structure to which another ring structure is fused so as to form a bicyclo structure or a spiro structure. The resin (A) still more preferably has a constitutional unit having a lactone structure represented by any of Formulae LC1-1 to LC1-21 or a sultone structure represented by any of General Formulae SL1-1 to SL1-3. In addition, the lactone structure or the sultone structure may be bonded directly to the main chain. The structure is preferably LC1-1, LC1-4, LC1-5, LC1-8, LC1-16, LC1-21, or SL1-1.

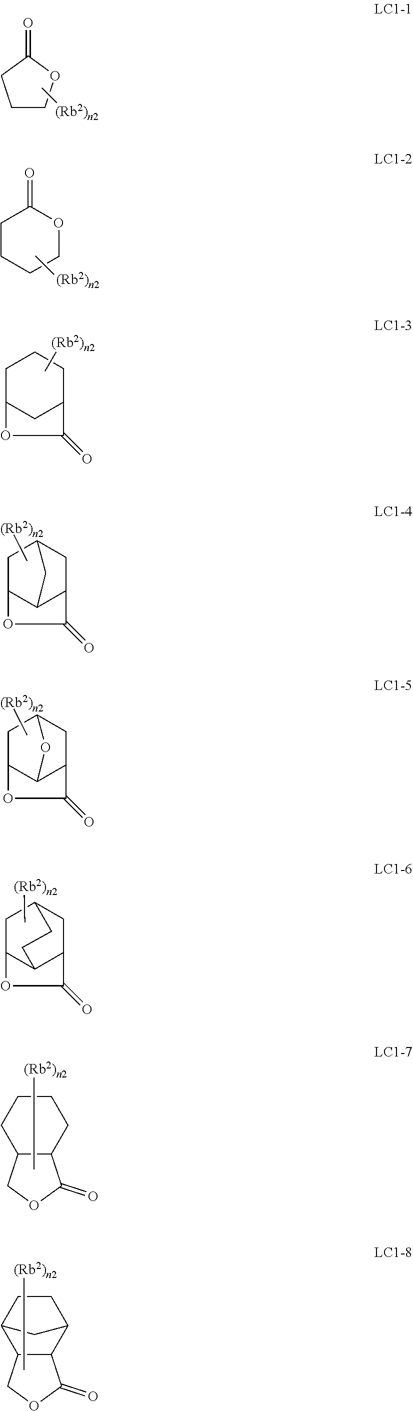

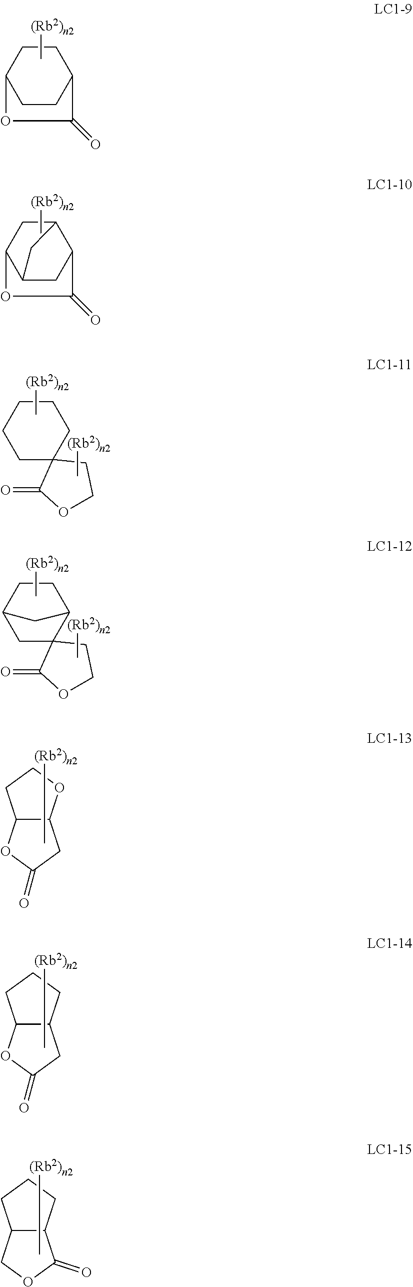

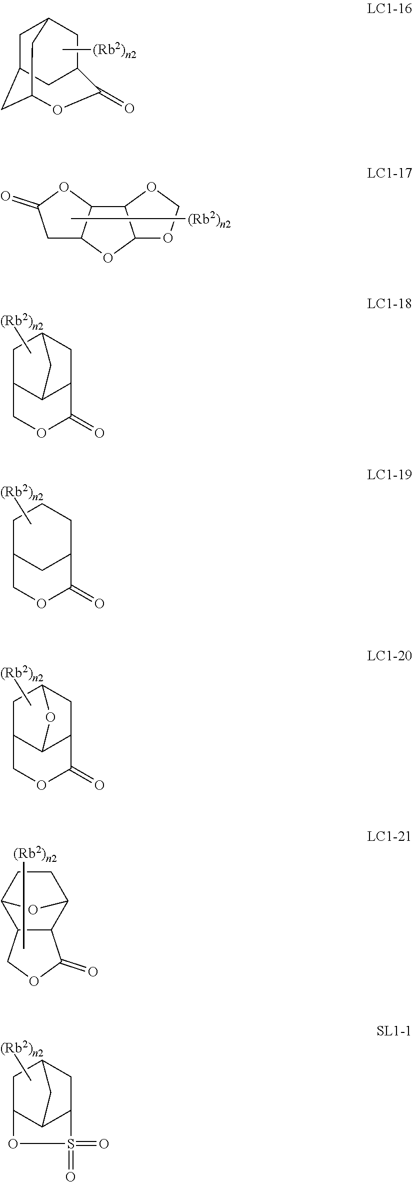

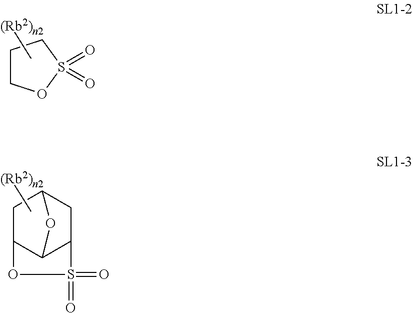

The lactone structural moiety or the sultone structural moiety may or may not have a substituent (Rb²). Preferred examples of the substituent (Rb²) include an alkyl group having 1 to 8 carbon atoms, a cycloalkyl group having 4 to 7 carbon atoms, an alkoxy group having 1 to 8 carbon atoms, an alkoxycarbonyl group having 2 to 8 carbon atoms, a carboxyl group, a halogen atom other than a fluorine atom, a hydroxyl group, a cyano group, and an acid-decomposable group. The substituent (Rb₂) is more preferably an alkyl group having 1 to 4 carbon atoms, the cyano group, or the acid-decomposable group. n2 represents an integer of 0 to 4. In a case where n2 is 2 or more, the substituents (Rb²) which are present in a plural number may be the same as or different from each other. Further, the substituents (Rb²) which are present in a plural number may be bonded to each other to form a ring.

The constitutional unit having a lactone structure or a sultone structure is preferably a constitutional unit represented by Formula III from the viewpoint of a tolerance of depth of focus and pattern linearity.

In addition, the resin having the constitutional unit having an acid-decomposable group preferably includes a constitutional unit represented by Formula III from the viewpoint of the tolerance of depth of focus and the pattern linearity.

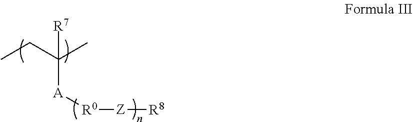

In Formula III,

A represents an ester bond (a group represented by —COO—) or an amide bond (a group represented by —CONH—).

n is the number of repetitions of the structure represented by —R⁰—Z—, represents an integer of 0 to 5, and is preferably 0 or 1, and more preferably 0. In a case where n is 0, —R⁰—Z— is not present, A and R⁸ are bound through a single bond.

R⁰ represents an alkylene group, a cycloalkylene group, or a combination thereof. In a case where R⁰'s are present in a plural number, R⁰'s each independently represent an alkylene group, a cycloalkylene group, or a combination thereof.

Z represents a single bond, an ether bond, an ester bond, an amide bond, a urethane bond, or a urea bond. In a case where Z's are present in a plural number, Z's each independently represent a single bond, an ether bond, an ester bond, an amide bond, a urethane bond, or a urea bond.

R⁸ represents a monovalent organic group having a lactone structure or a sultone structure.

R⁷ represents a hydrogen atom, a halogen atom other than a fluorine atom, or a monovalent organic group (preferably a methyl group).

The alkylene group or the cycloalkylene group of Ro may have a substituent.

Z is preferably the ether bond or the ester bond, and more preferably the ester bond.

Specific examples of a monomer corresponding to the constitutional unit represented by Formula III and specific example of a monomer corresponding to the constitutional unit represented by Formula A-1, each of which will described later, are shown below, but the disclosure is not limited to those specific examples. The following specific examples correspond to cases where R₇ in Formula III and R_{A}¹ in Formula A-1 are each a methyl group, but R₇ and R_{A}¹ can each be optionally substituted with a hydrogen atom, a halogen atom other than a fluorine atom, or a monovalent organic group.

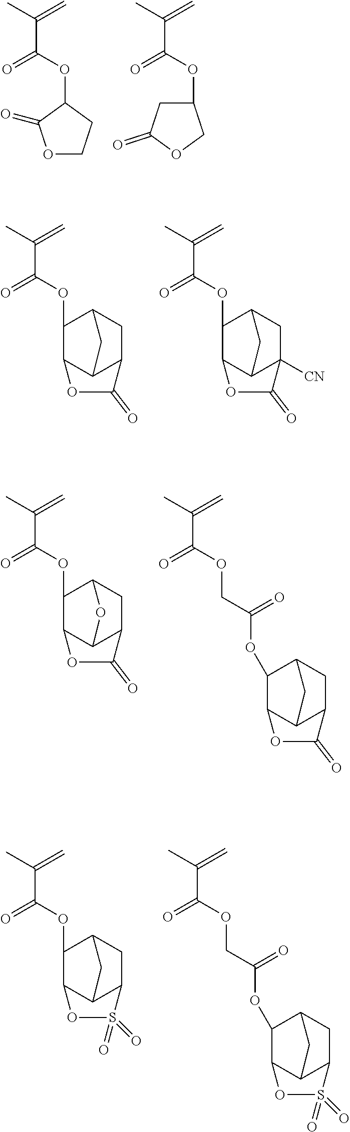

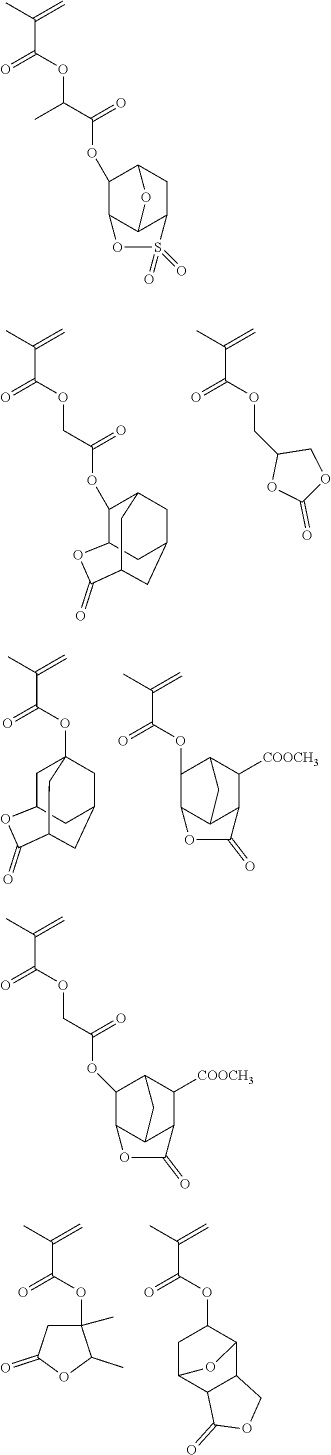

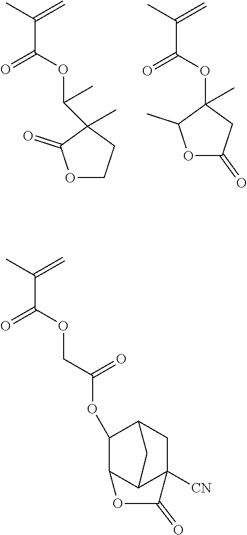

In addition to the monomers, monomers shown below are also suitably used as a raw material for the resin (A).

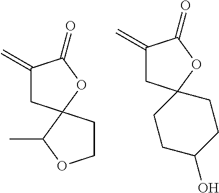

The resin (A) may have a constitutional unit having a carbonate structure. The carbonate structure is preferably a cyclic carbonic ester structure.

The constitutional unit having a cyclic carbonate structure is preferably a constitutional unit represented by Formula A-1.

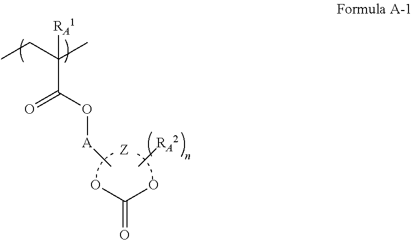

In Formula A-1, R_{A}¹ represents a hydrogen atom, a halogen atom other than a fluorine atom, or a monovalent organic group (preferably a methyl group), n represents an integer of 0 or more, and R_{A}² represents a substituent. In a case where n is 2 or more, R_{A}²'s each independently represent a substituent, A represents a single bond or a divalent linking group, and Z represents an atomic group which forms a monocyclic structure or a polycyclic structure together with a group represented by —O—C(═O)—O—in the formula.

The resin (A) preferably includes the constitutional unit described in paragraphs 0370 to 0414 of the specification of US2016/0070167A as a constitutional unit having at least one selected from the group consisting of a lactone structure, a sultone structure, and a carbonate structure.

The resin (A) may have only one kind or a combination of two or more kinds of constitutional units including at least one selected from the group consisting of a lactone structure, a sultone structure, and a carbonate structure.

The content of the constitutional unit having at least one selected from the group consisting of a lactone structure, a sultone structure, and a carbonate structure, included in the resin (A) (the total content of the constitutional units in a case where a plurality of constitutional units having at least one selected from the group consisting of a lactone structure, a sultone structure, and a carbonate structure are present) is preferably 5% by mole to 70% by mole, more preferably 10% by mole to 65% by mole, and still more preferably 20% by mole to 60% by mole with respect to all the constitutional units in the resin (A).

The resin (A) can further have a constitutional unit having a polar group, particularly a constitutional unit having an alicyclic hydrocarbon structure substituted with a polar group.

As a result, the adhesiveness to a substrate and the affinity for a developer are improved. The alicyclic hydrocarbon structure in the alicyclic hydrocarbon structure substituted with a polar group is preferably an adamantyl group, a diamantyl group, or a norbornane group. As the polar group, a hydroxyl group or a cyano group is preferable.

Specific examples of the constitutional unit having a polar group are shown below, but the disclosure is not limited thereto.

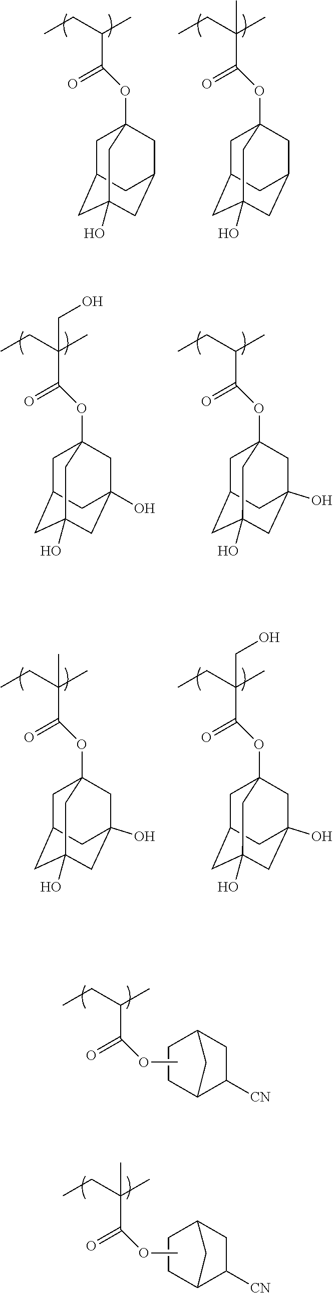

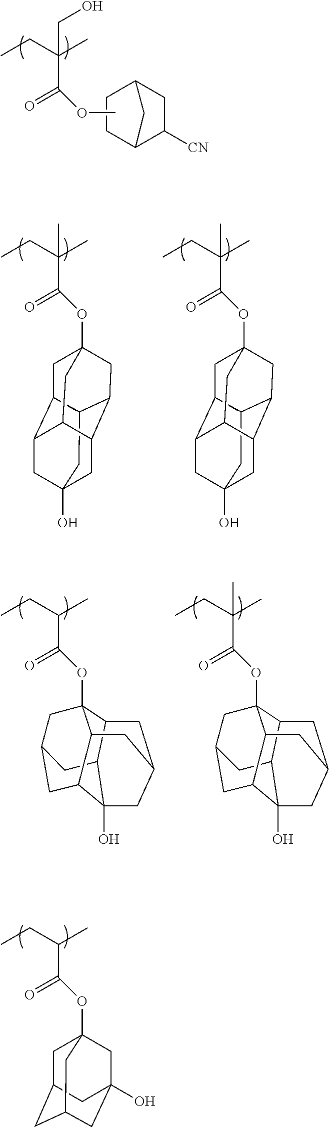

In a case where the resin (A) has a constitutional unit having a polar group, a content thereof is preferably 1% by mole to 30% by mole, more preferably 5% by mole to 25% by mole, and still more preferably 5% by mole to 20% by mole with respect to all the constitutional units in the resin (A).

Furthermore, a constitutional unit having a group that generates an acid upon irradiation with light (photoacid generating group) can also be included as a constitutional unit other than those above. In this case, it can be considered that the constitutional unit having this photoacid generating group corresponds to the photoacid generator.

Examples of such a constitutional unit include a constitutional unit represented by Formula (4).

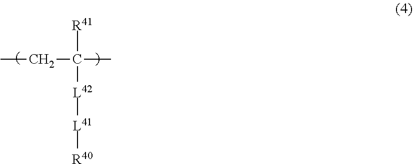

R⁴¹ represents a hydrogen atom or a methyl group. L⁴¹ represents a single bond or a divalent linking group. L⁴² represents a divalent linking group. R⁴⁰ represents a structural moiety that decomposes upon irradiation with actinic rays or radiation to generate an acid in a side chain.

Specific examples of the constitutional unit represented by Formula (4) will be shown below, but the present invention is not limited thereto.

In addition, examples of the constitutional unit represented by Formula (4) include the constitutional units described in paragraphs 0094 to 0105 of JP2014-041327A.

In a case where the resin (A) contains a constitutional unit having a photoacid generating group, the content of the constitutional unit having a photoacid generating group is preferably 1% by mole to 40% by mole, more preferably 1% to 35% by mole, and still more preferably 1% by mole to 30% by mole with respect to all the constitutional units in the resin (A).

The resin (A) can be synthesized in accordance to an ordinary method (for example, radical polymerization). Examples of the general synthesis method include a batch polymerization method in which polymerization is performed by dissolving monomer species and an initiator in a solvent and heating the solution, and a dropwise addition polymerization method in which a solution of monomer species and an initiator is added dropwise to a heating solvent for 1 to 10 hours, with the dropwise addition polymerization method being preferable.

Examples of the reaction solvent include ethers such as tetrahydrofuran, 1,4-dioxane, and diisopropyl ether; ketones such as methyl ethyl ketone and methyl isobutyl ketone; ester solvents such as ethyl acetate; amide solvents such as dimethyl formamide and dimethyl acetamide; and a solvent that dissolves the components of the resist layer, such as propylene glycol monomethyl ether acetate, propylene glycol monomethyl ether, and cyclohexanone, which will be described later. The polymerization is preferably carried out using the same solvent as the solvent used in the composition for forming a resist layer. As a result, it is possible to suppress the generation of particles during storage.

The polymerization reaction is preferably performed in an inert gas atmosphere such as nitrogen and argon. As the polymerization initiator, a commercially available radical initiator (an azo-based initiator, a peroxide, or the like) can be used to initiate the polymerization. As the radical initiator, an azo-based initiator is preferable, and an azo-based initiator having an ester group, a cyano group, or a carboxyl group is preferable. Preferred examples of the initiator include azobisisobutyronitrile, azobisdimethylvaleronitrile, and dimethyl 2,2′-azobis(2-methyl propionate). The polymerization initiator is added, or added in portionwise, as desired, and after completion of the reaction, the mixture is put into a solvent and a desired polymer is recovered by a method such as powder or solid recovery. The concentration of the reaction is preferably 5% by mass to 50% by mass, and more preferably 10% by mass to 30% by mass. The reaction temperature is preferably 10° C. to 150° C., more preferably 30° C. to 120° C., and still more preferably 60° C. to 100° C.

For purification, a typical method such as a liquid-liquid extraction method in which residual monomers and oligomer components are removed by combining water washing with an appropriate solvent, a purification method in a solution state such as ultrafiltration in which substances having a specific molecular weight or less are removed by extraction, a reprecipitation method in which residual monomers are removed by adding a resin solution dropwise over a poor solvent to solidify the resin in the poor solvent, and a purification method in a solid state in which a resin slurry separated by filtration is washed with a poor solvent can be applied.

The weight-average molecular weight of the resin (A) is preferably 1,000 to 200,000, more preferably 3,000 to 20,000, and still more preferably 5,000 to 15,000 as a value in terms of polystyrene by a GPC method. By setting the weight-average molecular weight to 1,000 to 200,000, it is possible to prevent deterioration of heat resistance or dry etching resistance, and it is also possible to prevent deterioration of developability or deterioration in film forming properties caused by an increase in a viscosity.

Another particularly preferred form of the weight-average molecular weight of the resin (A) is 3,000 to 9,500 in terms of polystyrene by the GPC method. By setting the weight-average molecular weight to 3,000 to 9,500, it is possible to suppress, in particular, a resist residue (hereinafter also referred to as a “scum”) and thus, to form a better pattern.

The dispersity (molecular weight distribution) of the resin (A) is preferably 1 to 5, more preferably 1 to 3, still more preferably 1.2 to 3.0, and particularly preferably 1.2 to 2.0. The smaller the dispersity, the better the resolution and the resist shape, the smoother the side wall of the resist pattern, and the better the roughness.

In the resist layer, the content of the resin (A) is preferably 50% by mass to 99.9% by mass, and more preferably 60% by mass to 99.0% by mass with respect to the total mass of the resist layer.

Furthermore, only one kind or a combination of two or more kinds of the resins (A) may be used.

[Photoacid Generator (B)]

The resist layer contains a compound that generates an acid upon irradiation with actinic rays or radiation (hereinafter also referred to as a “photoacid generator” (PAG) or a “photoacid generator (B)”).

The photoacid generator may be in a form of a low-molecular-weight compound or a form incorporated into a part of a polymer. Further, a combination of the form of a low-molecular-weight compound and the form incorporated into a part of a polymer may also be used.

In a case where the photoacid generator is in the form of a low-molecular-weight compound, the molecular weight is preferably 3,000 or less, more preferably 2,000 or less, and still more preferably 1,000 or less.

In a case where the photoacid generator is incorporated into a part of a polymer, it may be incorporated into a part of the resin (A) or in a resin different from the resin (A).

The number of fluorine atoms contained in the photoacid generator is appropriately adjusted for the purpose of adjusting the cross-sectional shape of a pattern. By adjusting the number of the fluorine atoms, it is possible to control the uneven distribution on the surface of the photoacid generator in the resist film. The more fluorine atoms contained in the acid generator, the more unevenly they are distributed on the surface.

In the disclosure, the photoacid generator is preferably in the form of a low-molecular-weight compound.

The photoacid generator is not particularly limited as long as it is a known one, but it is preferably a compound that generates at least any one of organic acids such as sulfonic acid, bis(alkylsulfonyl)imide, and tris(alkylsulfonyl)methide upon irradiation with light, and preferably electron beams or extreme ultraviolet rays.

More preferred examples of the photoacid generator include a compound represented by Formula (ZI), Formula (ZII), or Formula (ZIII).

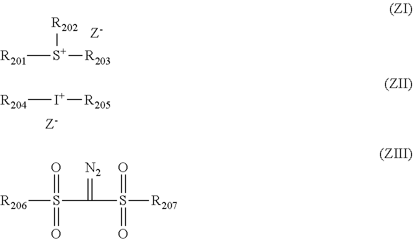

In Formula (ZI),

R₂₀₁, R₂₀₂, and R₂₀₃ each independently represent an organic group.

The organic group as each of R₂₀₁, R₂₀₂, and R₂₀₃ preferably has 1 to 30 carbon atoms, and more preferably has 1 to 20 carbon atoms.

In addition, two of R₂₀₁ to R₂₀₃ may be bonded to each other to form a ring structure, and the ring may include an oxygen atom, a sulfur atom, an ester bond, an amide bond, or a carbonyl group. Examples of the group formed by the bonding of two of R₂₀₁ to R₂₀₃ include an alkylene group (for example, a butylene group and a pentylene group).

Z⁻ represents a non-nucleophilic anion (anion having an extremely low ability to cause a nucleophilic reaction).

Examples of the non-nucleophilic anion include a sulfonate anion (an aliphatic sulfonate anion, an aromatic sulfonate anion, a camphor sulfonate anion, and the like), a carboxylate anion (an aliphatic carboxylate anion, an aromatic carboxylate anion, an aralkyl carboxylate anion, and the like), a sulfonylimide anion, a bis(alkylsulfonyl)imide anion, and a tris(alkylsulfonyl)methide anion.

The aliphatic moiety in the aliphatic sulfonate anion and the aliphatic carboxylate anion may be an alkyl group or a cycloalkyl group, and preferred examples thereof include a linear or branched alkyl group having 1 to 30 carbon atoms and a cycloalkyl group having 3 to 30 carbon atoms.

The aromatic group in the aromatic sulfonate anion and the aromatic carboxylate anion is preferably an aryl group having 6 to 14 carbon atoms, and examples thereof include a phenyl group, a tolyl group, and a naphthyl group.

The alkyl group, the cycloalkyl group, and the aryl group exemplified above may have a substituent. Specific examples of the substituent include a nitro group, a halogen atom such as fluorine atom, a carboxyl group, a hydroxyl group, an amino group, a cyano group, an alkoxy group (preferably having 1 to 15 carbon atoms), a cycloalkyl group (preferably having 3 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), an alkoxycarbonyloxy group (preferably having 2 to 7 carbon atoms), an alkylthio group (preferably having 1 to 15 carbon atoms), an alkylsulfonyl group (preferably having 1 to 15 carbon atoms), an alkyliminosulfonyl group (preferably having 1 to 15 carbon atoms), an aryloxysulfonyl group (preferably having 6 to 20 carbon atoms), an alkylaryloxysulfonyl group (preferably having 7 to 20 carbon atoms), a cycloalkylaryloxysulfonyl group (preferably having 10 to 20 carbon atoms), an alkyloxyalkyloxy group (preferably having 5 to 20 carbon atoms), and a cycloalkylalkyloxyalkyloxy group (preferably having 8 to 20 carbon atoms). With regard to the aryl group and the ring structure contained in each group, an alkyl group (preferably having a carbon number of 1 to 15) can be exemplified as the substituent.

Preferred examples of the aralkyl group in the aralkylcarboxylate anion include an aralkyl group having 7 to 12 carbon atoms, and examples thereof include a benzyl group, a phenethyl group, a naphthylmethyl group, a naphthylethyl group, and a naphthylbutyl group.

Examples of the sulfonylimide anion include a saccharin anion.

The alkyl group in the bis(alkylsulfonyl)imide anion and the tris(alkylsulfonyl)methide anion is preferably an alkyl group having 1 to 5 carbon atoms. Examples of the substituent of such an alkyl group include a halogen atom, an alkyl group substituted with the halogen atom, an alkoxy group, an alkylthio group, an alkyloxysulfonyl group, an aryloxysulfonyl group, and a cycloalkylaryloxysulfonyl group, and the substituent is preferably a fluorine atom or an alkyl group substituted with the fluorine atom.

Furthermore, the alkyl group in the bis(alkylsulfonyl)imide anion may be bonded to each other to form a ring structure. As a result, the acid strength increases.

Examples of the other non-nucleophilic anions include fluorinated phosphorus (for example, PF₆⁻), fluorinated boron (for example, BF₄⁻), and fluorinated antimony (for example, SbF₆⁻).

As the non-nucleophilic anion, an aliphatic sulfonate anion in which at least α-position of sulfonic acid is substituted with a fluorine atom, an aromatic sulfonate anion substituted with a fluorine atom or a group having a fluorine atom, a bis(alkylsulfonyl)imide anion in which an alkyl group is substituted with a fluorine atom, or a tris(alkylsulfonyl)methide anion in which an alkyl group is substituted with a fluorine atom is preferable. As the non-nucleophilic anion, a perfluoroaliphatic sulfonate anion (more preferably having 4 to 8 carbon atoms) or a benzene sulfonate anion having a fluorine atom is more preferable, and a nonafluorobutane sulfonate anion, a perfluorooctane sulfonate anion, a pentafluorobenzene sulfonate anion, or a 3,5-bis(trifluoromethyl) benzenesulfonate anion is still more preferable.

From the viewpoint of the acid strength, it is preferable that a pKa of an acid generated is −1 or less since the sensitivity is improved.

Furthermore, as the non-nucleophilic anion, an anion represented by Formula (AN1) is also mentioned as a preferred aspect.

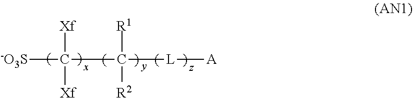

In the formula,

Xf's each independently represent a fluorine atom or an alkyl group substituted with at least one fluorine atom.

R¹ and R² each independently represent a hydrogen atom, a fluorine atom, or an alkyl group, and in a case where R¹'s and R²'s are each present in a plural number, they may each be the same as or different from each other.

L represents a divalent linking group, and in a case where L's are present in a plural number, L's may be the same as or different from each other.

A represents a cyclic organic group.

x represents an integer of 1 to 20, y represents an integer of 0 to 10, and z represents an integer of 0 to 10.

Formula (AN1) will be described in more detail.

The alkyl group with regard to the alkyl group substituted with the fluorine atom of Xf preferably has 1 to 10 carbon atoms, and more preferably has 1 to 4 carbon atoms. In addition, the alkyl group substituted with at least one fluorine atom is preferably a perfluoroalkyl group.

As Xf, a fluorine atom or a perfluoroalkyl group having 1 to 4 carbon atoms is preferable. Specific examples of Xf include a fluorine atom, CF₃, C₂F₅, C₃F₇, C₄F₉, CH₂CF₃, CH₂CH₂CF₃, CH₂C₂F₅, CH₂CH₂C₂F₅, CH₂C₃F₇, CH₂CH₂C₃F₇, CH₂C₄F₉, and CH₂CH₂C₄F₉. Among these, the fluorine atom or CF₃ is preferable. In particular, it is preferable that both Xf's are fluorine atoms.

The alkyl group of each of R¹ and R² may have a substituent (preferably a fluorine atom), and preferably has 1 to 4 carbon atoms. The alkyl group is more preferably a perfluoroalkyl group having 1 to 4 carbon atoms. Specific examples of the alkyl group having a substituent, of each of R¹ and R², include CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉, and CH₂CH₂C₄F₉, and among these, CF₃ is preferable.

R¹ and R² are each preferably a fluorine atom or CF₃.

x is preferably 1 to 10, and more preferably 1 to 5.

y is preferably 0 to 4, and more preferably 0.

z is preferably 0 to 5, and more preferably 0 to 3.

The divalent linking group of L is not particularly limited, examples thereof include —COO—, —OCO—, —CO—, —O—, —S—, —SO—, —SO₂—, an alkylene group, a cycloalkylene group, an alkenylene group, and a linking group in which a plurality of these groups are linked, and the divalent linking group is preferably a linking group having a total number of carbon atoms of 12 or less. Among those, —COO—, —OCO—, —CO—, or —O— is preferable, and —COO— or —OCO— is more preferable.

The cyclic organic group of A is not particularly limited as long as it has a cyclic structure, and examples thereof include an alicyclic group, an aryl group, and a heterocyclic group (also including a group having aromaticity as well as a group not having aromaticity).

The alicyclic group may be either a monocycle or a polycycle, and a monocyclic cycloalkyl group such as a cyclopentyl group, a cyclohexyl group, and a cyclooctyl group, or a polycyclic cycloalkyl group such as a norbornyl group, a tricyclodecanyl group, a tetracyclodecanyl group, a tetracyclododecanyl group, and an adamantyl group is preferable. Among these, an alicyclic group having a bulky structure having 7 or more carbon atoms, such as a norbornyl group, a tricyclodecanyl group, a tetracyclodecanyl group, a tetracyclododecanyl group, and an adamantyl group, can be used in the post-exposure baking step is preferable from the viewpoint that it can suppress the in-membrane diffusion and improve a mask error enhancement factor (MEEF).

Examples of the aryl group include a benzene ring, a naphthalene ring, a phenanthrene ring, and an anthracene ring.

Examples of the heterocyclic group include those derived from a furan ring, a thiophene ring, a benzofuran ring, a benzothiophene ring, a dibenzofuran ring, a dibenzothiophene ring, or a pyridine ring. Among these, those derived from the furan ring, the thiophene ring, or the pyridine ring are preferable.

Furthermore, examples of the cyclic organic group also include a lactone structure, and specifically a lactone structure represented by any of Formulae (LC1-1) to (LC1-17).

The cyclic organic group may have a substituent, and examples of the substituent include an alkyl group (which may be in any of linear, branched, and cyclic forms, and preferably has 1 to 12 carbon atoms), a cycloalkyl group (which may be any of a monocycle, a polycycle, and a spiro ring, and preferably has 3 to 20 carbon atoms), an aryl group (preferably having 6 to 14 carbon atoms), a hydroxyl group, an alkoxy group, an ester group, an amido group, a urethane group, a ureido group, a thioether group, a sulfonamido group, and a sulfonic ester group. Incidentally, the carbon constituting the cyclic organic group (carbon contributing to ring formation) may be carbonyl carbon.

Examples of the organic group of each of R₂₀₁, R₂₀₂, and R₂₀₃ include an aryl group, an alkyl group, and a cycloalkyl group.

It is preferable that at least one of R₂₀₁, R₂₀₂, or R₂₀₃ is an aryl group, and it is more preferable that all of R₂₀₁, R₂₀₂, and R₂₀₃ represent an aryl group. As the aryl group, not only a phenyl group, a naphthyl group, or the like but also a heteroaryl group such as an indole residue and a pyrrole residue is also available. Preferred examples of the alkyl group and the cycloalkyl group of each of R₂₀₁ to R₂₀₃ include a linear or branched alkyl group having 1 to 10 carbon atoms and a cycloalkyl group having 3 to 10 carbon atoms. More preferred examples of the alkyl group include a methyl group, an ethyl group, an n-propyl group, an i-propyl group, and an n-butyl group. Still more preferred examples of the cycloalkyl group include a cyclopropyl group, a cyclobutyl group, a cyclopentyl group, a cyclohexyl group, and a cycloheptyl group. Such groups may further have a substituent. Examples of the substituent include, but are not limited to, a nitro group, a halogen atom such as fluorine atom, a carboxyl group, a hydroxyl group, an amino group, a cyano group, an alkoxy group (preferably having 1 to 15 carbon atoms), a cycloalkyl group (preferably having 3 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), and an alkoxycarbonyloxy group (preferably having 2 to 7 carbon atoms).

Preferred examples of the anion represented by Formula (AN1) include the following ones. In the following examples, A represents a cyclic organic group.

SO₃—CF₂—CH₂—OCO-A, SO₃—CF₂—CHF—CH₂—OCO-A, SO₃—CF₂—COO-A, SO₃—CF₂—CF₂—CH₂-A, SO₃—CF₂—CH(CF₃)—OCO-A

In Formulae (ZII) and (ZIII), R₂₀₄ to R₂₀₇ each independently represent an aryl group, an alkyl group, or a cycloalkyl group.

As the aryl group, the alkyl group, and the cycloalkyl group of each of R₂₀₄ to R₂₀₇ have the same definition as the aryl group described in the aryl group, the alkyl group, and the cycloalkyl group, respectively, of each of R₂₀₁ to R₂₀₃ in the above-mentioned compound (ZI).

The aryl group, the alkyl group, and the cycloalkyl group of each of R₂₀₄ to R₂₀₇ may have a substituent. Examples of the substituent include those which may be contained in the aryl group, the alkyl group, and the cycloalkyl group of each of R₂₀₁ to R₂₀₃ in the above-mentioned compound (ZI).

Z⁻ represents a non-nucleophilic anion, and examples thereof include the same ones as the non−nucleophilic anion of Z⁻ in Formula (ZI).

In the disclosure, from the viewpoint of suppressing an acid generated by exposure from diffusing to an unexposed area and thus improving the resolution, the photoacid generator is preferably a compound that generates an acid in a size with a volume of 130 Å³ (10 Å=1 nm) or more (more preferably a sulfonic acid), more preferably a compound that generates an acid in a size with a volume of 190 Å³ or more (more preferably a sulfonic acid), still more preferably a compound that generates an acid in a size with a volume of 270 Å³ or more (more preferably sulfonic acid), and particularly preferably a compound that generates an acid in a size with a volume of 400 Å³ or more (more preferably sulfonic acid), upon irradiation with electron beams or extreme ultraviolet rays. It should be noted that from the viewpoint of the sensitivity or the solubility in the coating solvent, the volume is preferably 2,000 Å³ or less, and more preferably 1,500 Å³ or less. The value of the volume was determined using “WinMOPAC” manufactured by Fujitsu Limited. That is, first, the chemical structure of an acid according to each example is input, next, using this structure as an initial structure, the most stable steric conformation of each acid is determined by molecular force field calculation using an MM3 method, and then, molecular orbital calculation using a PM3 method is performed with respect to the most stable steric conformation, whereby an “accessible volume” of each acid can be calculated.

With regard to the photoacid generator, reference can be made to paragraphs 0368 to 0377 of JP2014-041328A and paragraphs 0240 to 0262 of JP2013-228681A (corresponding to paragraph 0339 of the specification of US2015/0004533A), the contents of which are incorporated herein by reference. In addition, specific preferred examples of the photoacid generator include, but are not limited to, the following compounds.

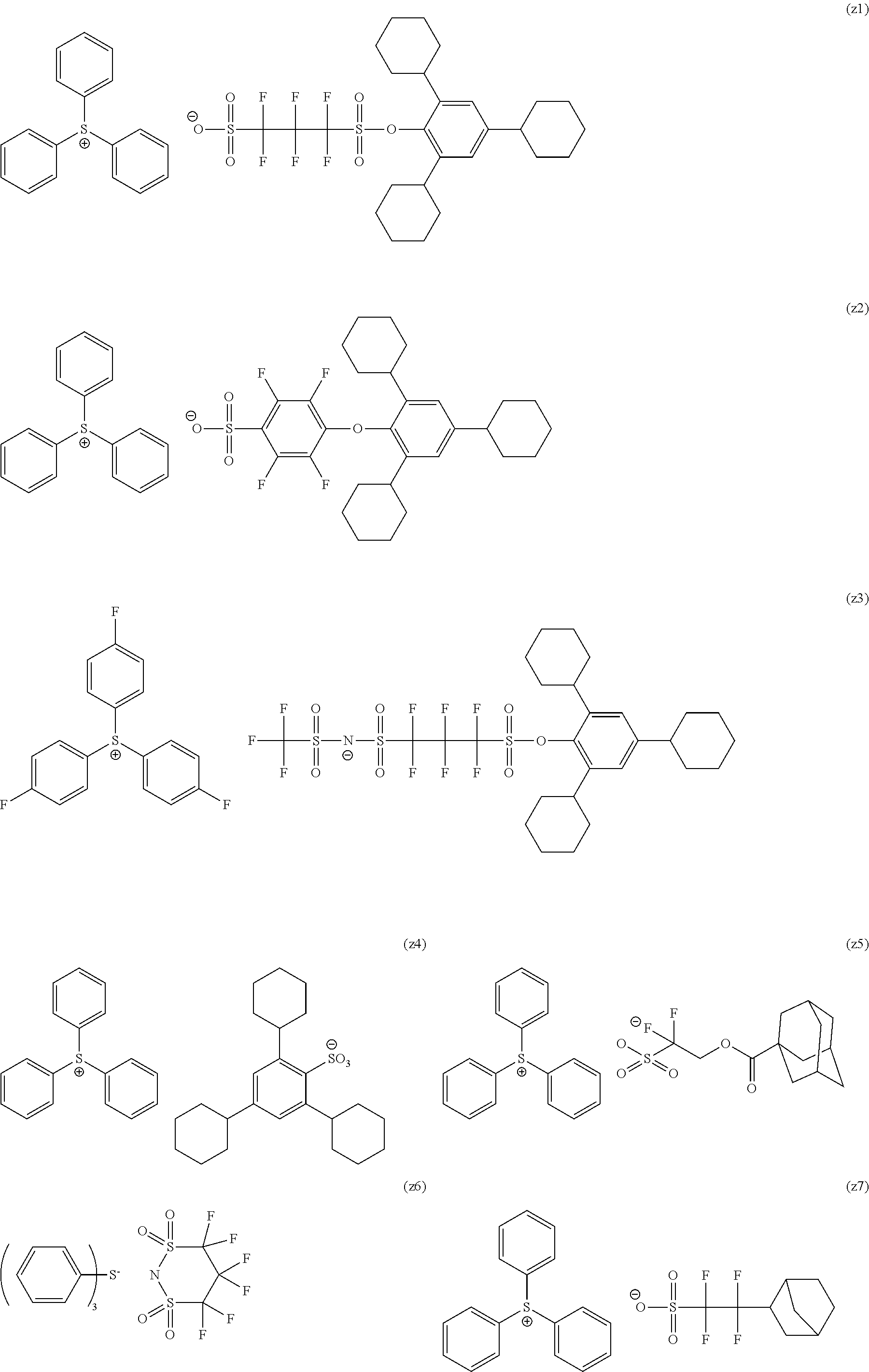

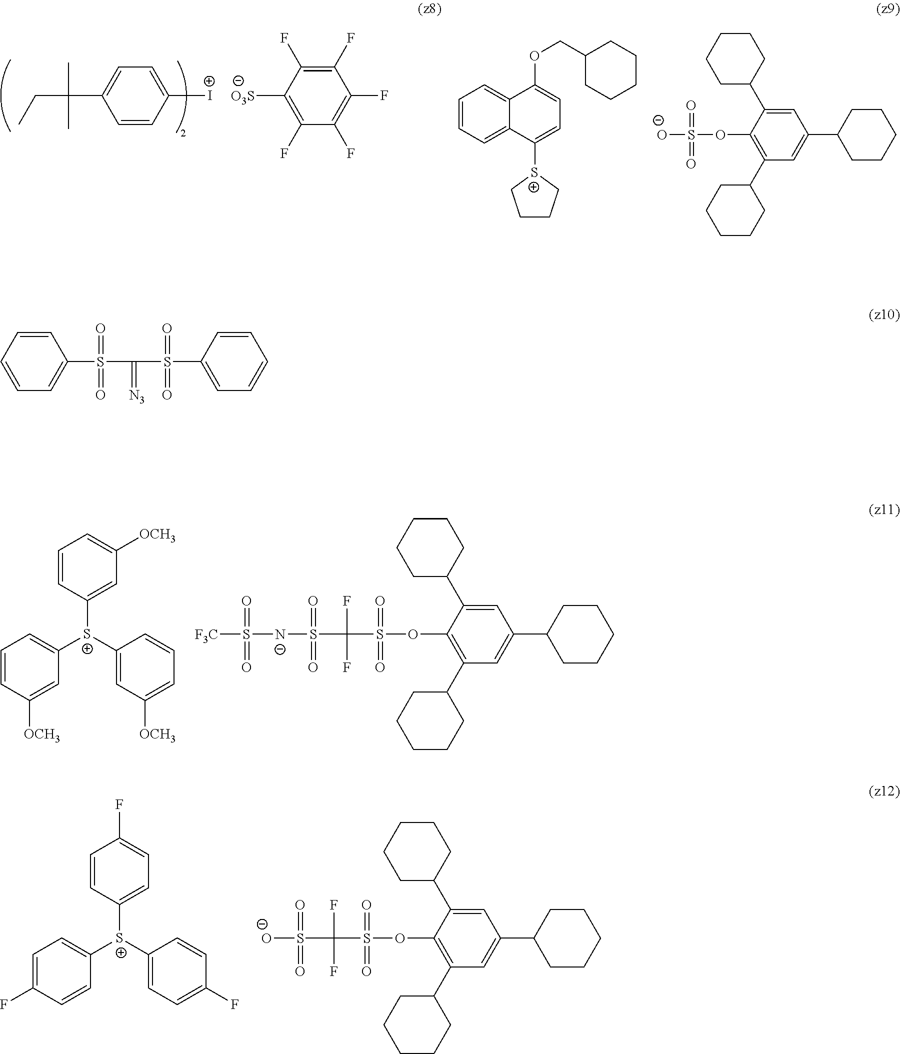

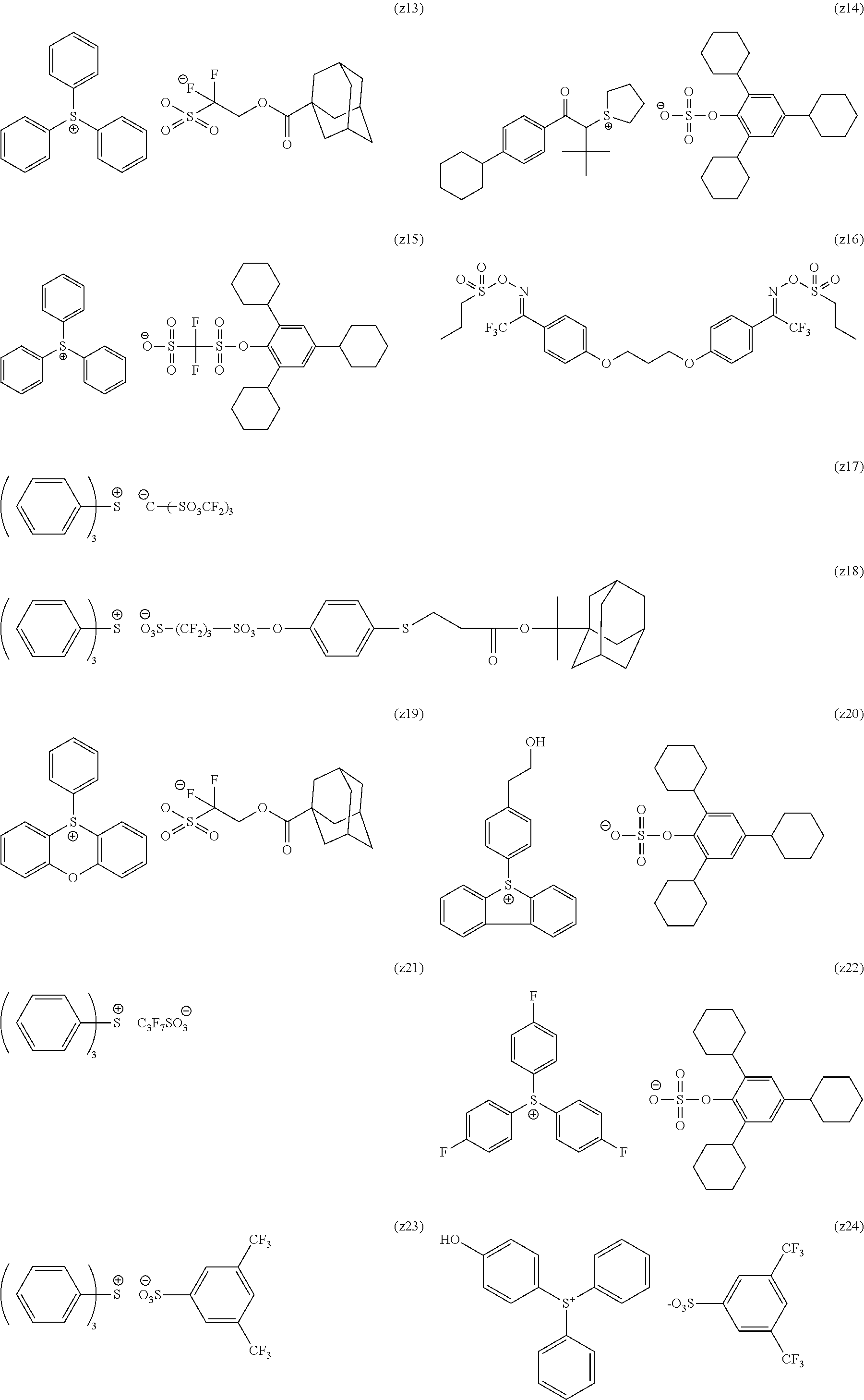

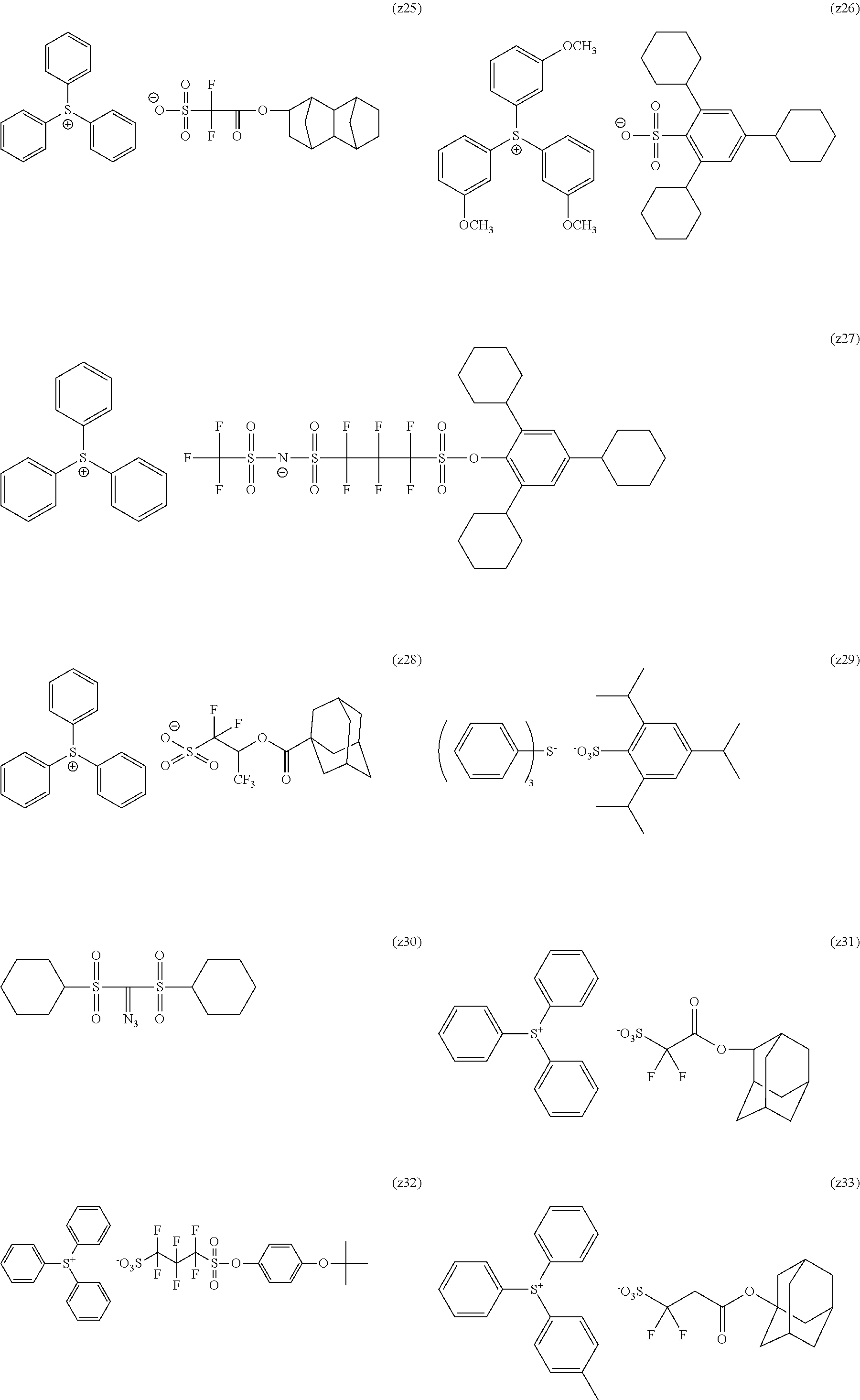

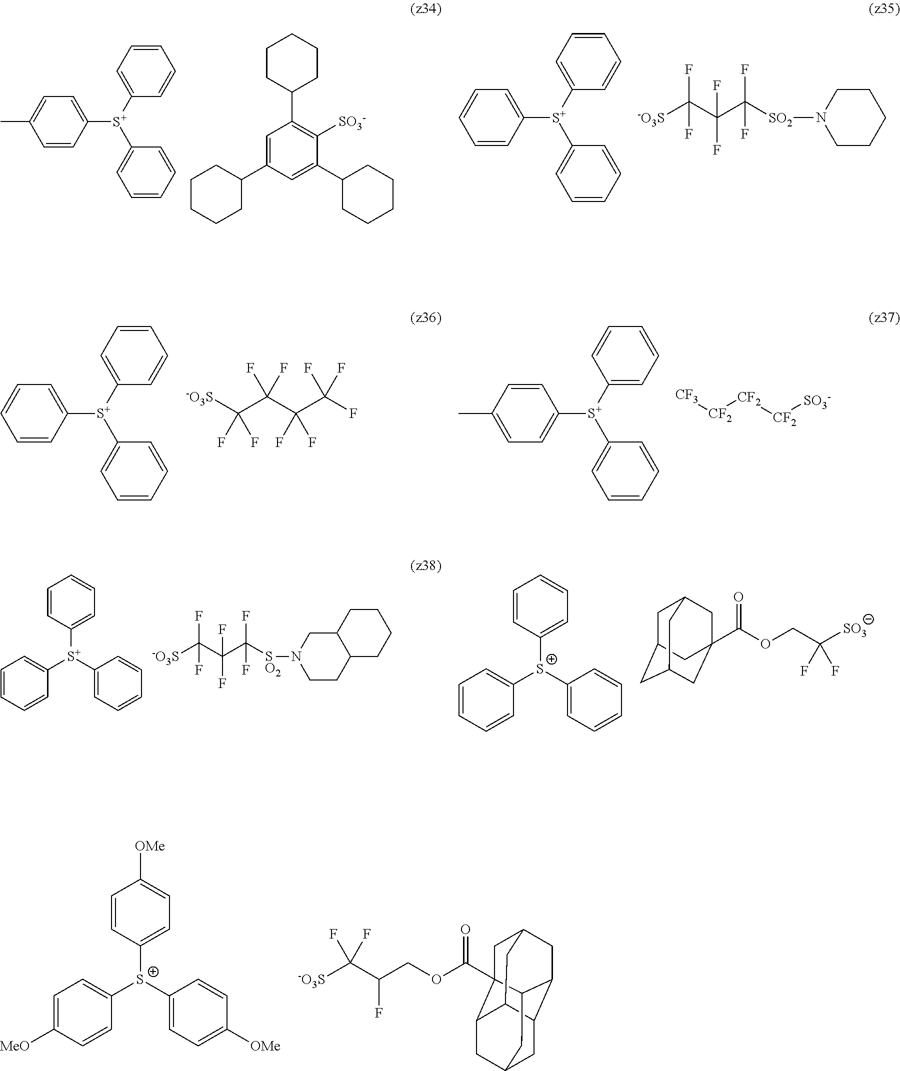

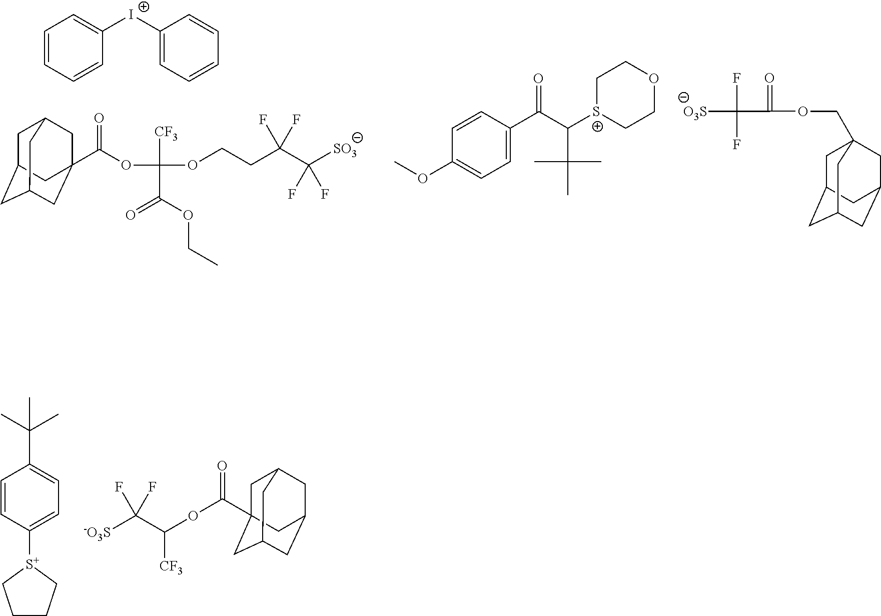

The photoacid generator may be used singly or in combination of two or more kinds thereof.

The content of the photoacid generator is preferably 0.1% by mass to 50% by mass, more preferably 5% by mass to 50% by mass, and still more preferably 8% by mass to 40% by mass with respect to the total mass of the resist layer. In particular, in order to achieve both high sensitivity and high resolution upon exposure to electron beams or extreme ultraviolet rays, the content of the photoacid generator is preferably high, particularly preferably 10% by mass to 40% by mass, and most preferably 10% by mass to 35% by mass.

[Basic Compound]

The resist layer preferably contains a basic compound in order to reduce a change in performance over time from exposure to heating.

Preferred examples of the basic compound (DA) include compounds having structures represented by Formulae (A) to (E).

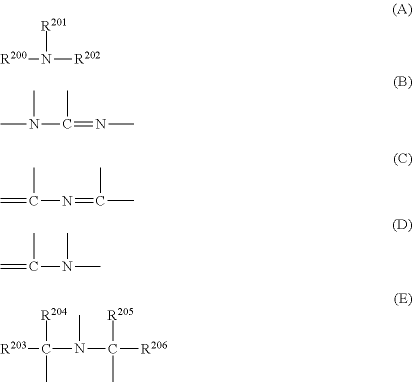

In Formulae (A) and (E), R²⁰⁰, R²⁰¹, and R²⁰² may be the same as or different from each other, and each represent a hydrogen atom, an alkyl group (preferably having 1 to 20 carbon atoms), a cycloalkyl group (preferably having 3 to 20 carbon atoms), or an aryl group (preferably having 6 to 20 carbon atoms), where R²⁰¹ and R²⁰² may be bonded to each other to form a ring.

With regard to the alkyl group, the alkyl group having a substituent is preferably an aminoalkyl group having 1 to 20 carbon atoms, a hydroxyalkyl group having 1 to 20 carbon atoms, or a cyanoalkyl group having 1 to 20 carbon atoms.

R²⁰³, R²⁰⁴, R²⁰⁵, and R²⁰⁶ may be the same as or different from each other, and represent an alkyl group having 1 to 20 carbon atoms.

The alkyl groups in Formula (A) and Formula (E) are more preferably unsubstituted.

Preferred examples of the compound include guanidine, aminopyrrolidine, pyrazole, pyrazoline, piperazine, aminomorpholine, aminoalkylmorpholine, and piperidine, and more preferred examples of the compound include a compound having an imidazole structure, a diazabicyclo structure, an onium hydroxide structure, an onium carboxylate structure, a trialkylamine structure, an aniline structure, or a pyridine structure, an alkylamine derivative having a hydroxyl group and/or an ether bond, and an aniline derivative having a hydroxyl group and/or an ether bond.

Preferred examples of the basic compound further include an amine compound having a phenoxy group and an ammonium salt compound having a phenoxy group.

As the amine compound, a primary, secondary, or tertiary amine compound can be used, and an amine compound in which at least one alkyl group is bonded to a nitrogen atom is preferable. The amine compound is more preferably the tertiary amine compound. In the amine compound, a cycloalkyl group (preferably having 3 to 20 carbon atoms) or an aryl group (preferably having 6 to 12 carbon atoms), in addition to the alkyl group, may be bonded to the nitrogen atom in a case where at least one alkyl group (preferably having 1 to 20 carbon atoms) is bonded to the nitrogen atom.

Furthermore, it is preferable that the amine compound has an oxygen atom in the alkyl chain to form an oxyalkylene group. The number of the oxyalkylene groups is 1 or more, preferably 3 to 9, and more preferably 4 to 6 in the molecule. Among the oxyalkylene groups, an oxyethylene group (—CH₂CH₂O—) or an oxypropylene group (—CH(CH₃)CH₂O— or —CH₂CH₂CH₂O—) is preferable, and the oxyethylene group is more preferable.

As the ammonium salt compound, a primary, secondary, tertiary, or quaternary ammonium salt compound can be used, and an ammonium salt compound in which at least one alkyl group is bonded to a nitrogen atom is preferable. In the ammonium salt compound, a cycloalkyl group (preferably having 3 to 20 carbon atoms) or an aryl group (preferably having 6 to 12 carbon atoms), in addition to the alkyl group, may be bonded to the nitrogen atom in a case where at least one alkyl group (preferably having 1 to 20 carbon atoms) is bonded to the nitrogen atom.

It is preferable that the ammonium salt compound has an oxygen atom in the alkyl chain to form an oxyalkylene group. The number of the oxyalkylene groups is 1 or more, preferably 3 to 9, and more preferably 4 to 6 in the molecule. Among the oxyalkylene groups, an oxyethylene group (—CH₂CH₂O—) or an oxypropylene group (—CH(CH₃)CH₂O— or —CH₂CH₂CH₂O—) is preferable, and the oxyethylene group is more preferable.

Examples of the anion of the ammonium salt compound include a halogen atom, a sulfonate, a borate, and a phosphate, and among these, the halogen atom or the sulfonate is preferable. As the halogen atom, a chloride, a bromide, or an iodide is preferable. As the sulfonate, an organic sulfonate having 1 to 20 carbon atoms is preferable.

The amine compound having a phenoxy group can be obtained by heating a primary or secondary amine having a phenoxy group and a haloalkyl ether to perform a reaction, then adding an aqueous solution of a strong base such as sodium hydroxide, potassium hydroxide, and tetraalkylammonium thereto, and performing extraction with an organic solvent such as ethyl acetate and chloroform. Alternatively, the amine compound having a phenoxy group can be obtained by heating a primary or secondary amine and a haloalkyl ether having a phenoxy group at a terminal to perform a reaction, then adding an aqueous solution of a strong base such as sodium hydroxide, potassium hydroxide, and tetraalkylammonium thereto to obtain a mixed liquid, and then performing extraction with an organic solvent such as ethyl acetate and chloroform.

With regard to specific example of the above-mentioned basic compound, reference can be made to, for example, the specific example described in paragraphs 0237 to 0294 of WO2015/178375A, the contents of which are incorporated herein by reference.

The resist layer may further include a compound (hereinafter also referred to as a “compound (PA)”) which has a proton-accepting functional group and generates a compound that decomposes upon irradiation with actinic rays or radiation to exhibit deterioration in proton-accepting properties, no proton-accepting properties, or a change from the proton-accepting properties to acidic properties as the basic compound.

The proton-accepting functional group refers to a functional group having a group or an electron which is capable of electrostatically interacting with a proton, and for example, means a functional group with a macrocyclic structure, such as a cyclic polyether, or a functional group having a nitrogen atom having an unshared electron pair not contributing to π-conjugation. The nitrogen atom having an unshared electron pair not contributing to π-conjugation is, for example, a nitrogen atom having a partial structure represented by Formula.

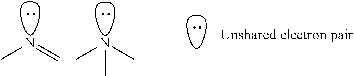

Examples of the partial structure of the proton-accepting functional group include a crown ether, azacrown ether, primary to tertiary amines, pyridine, imidazole, and pyrazine structures.

The compound (PA) decomposes upon irradiation with light to generate a compound exhibiting deterioration in proton-accepting properties, no proton-accepting properties, or a change from the proton-accepting properties to acidic properties. Here, exhibiting deterioration in proton-accepting properties, no proton-accepting properties, or a change from the proton-accepting properties to acidic properties means a change of proton-accepting properties due to the proton being added to the proton-accepting functional group, and specifically a decrease in the equilibrium constant at chemical equilibrium in a case where a proton adduct is generated from the compound (PA) having the proton-accepting functional group and the proton.

Specific examples of the compound (PA) include the following compounds. Further, with regard to specific examples of the compound (PA), reference can be made to those described in paragraphs 0421 to 0428 of JP2014-041328A or paragraphs 0108 to 0116 of JP2014-134686A, the contents of which are incorporated herein by reference.

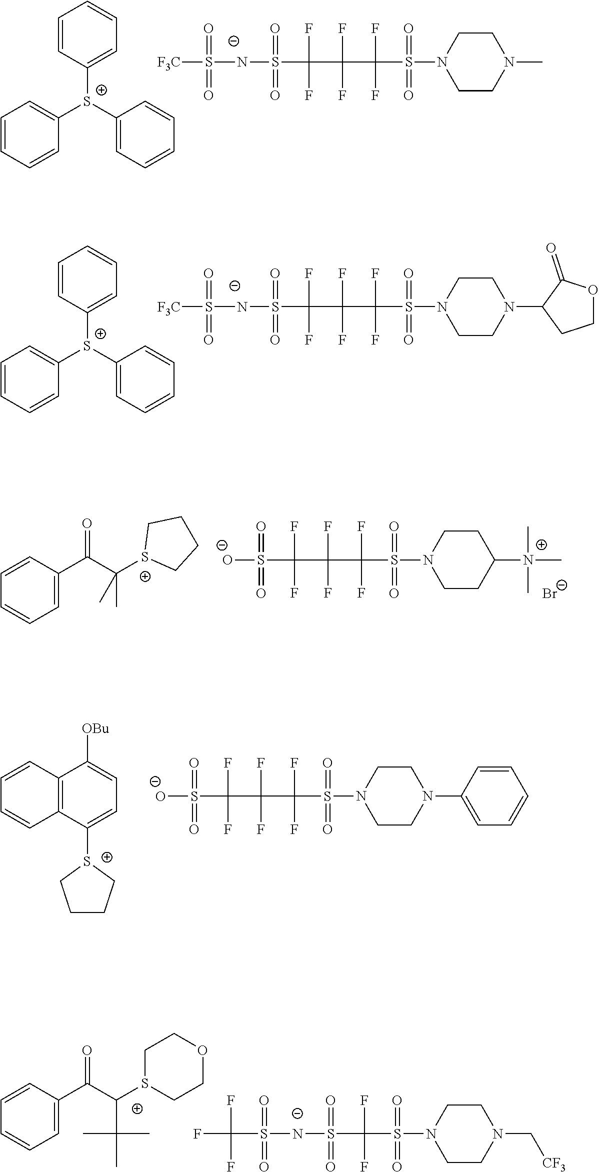

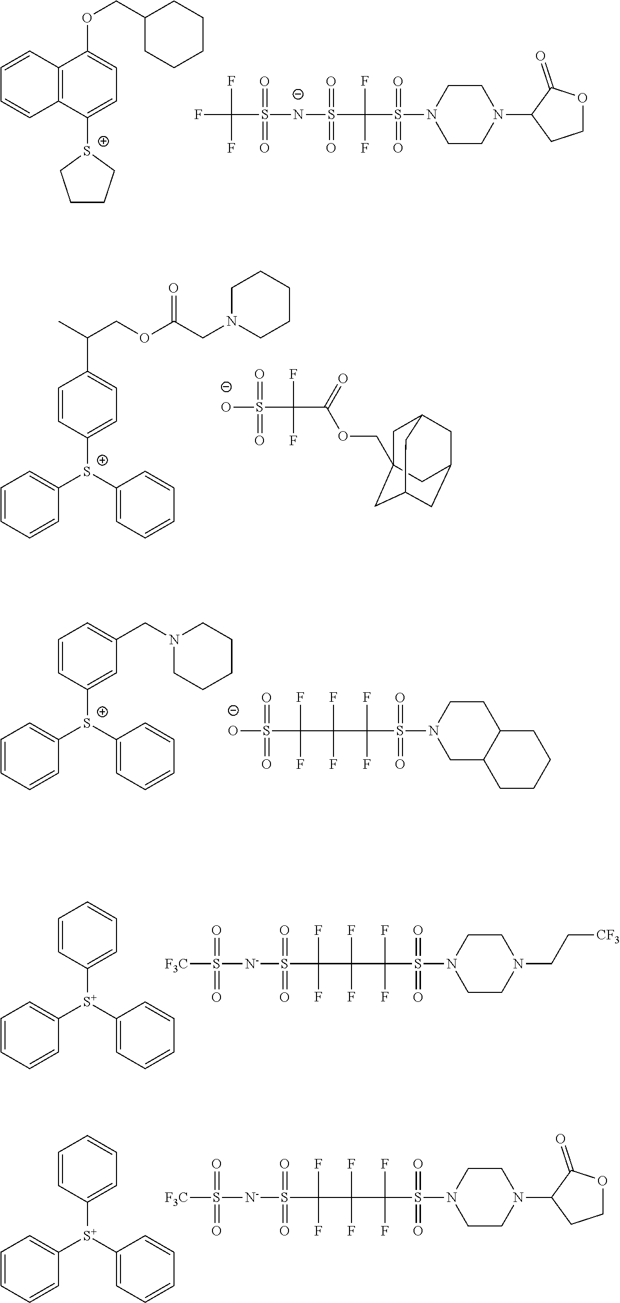

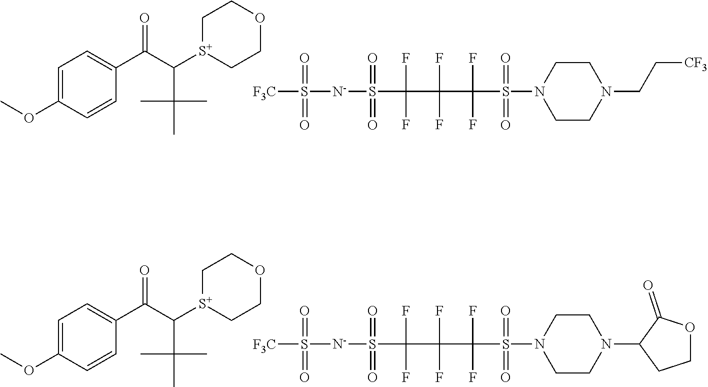 [SMILES: COc1ccc(C(=O)C([S+]2CCOCC2)C(C)(C)C)cc1 ; O=S(=O)([N-]S(=O)(=O)C(F)(F)C(F)(F)C(F)(F)S(=O)(=O)N1CCN(CCC(F)(F)F)CC1)C(F)(F)F ; COc1ccc(C(=O)C([S+]2CCOCC2)C(C)(C)C)cc1 ; O=C1OCCC1N1CCN(S(=O)(=O)C(F)(F)C(F)(F)C(F)(F)S(=O)(=O)[N-]S(=O)(=O)C(F)(F)F)CC1]

These basic compounds may be used singly or in combination of two or more kinds thereof.

The content of the basic compound is preferably 0.001% by mass to 10% by mass, and more preferably 0.01% by mass to 5% by mass with respect to the total mass of the resist layer.

The proportion of the acid generator to the basic compound is preferably the acid generator/the basic compound (molar ratio)=2.5 to 300. That is, from the viewpoint of sensitivity and resolution, the molar ratio is preferably 2.5 or more, and from the viewpoint of suppressing a decrease in resolution due to the thickening of the resist pattern over time until an post-exposure baking treatment, the molar ratio is preferably 300 or less. In addition, the acid generator/the basic compound (molar ratio) is more preferably 5.0 to 200, and still more preferably 7.0 to 150.

As the basic compound, for example, the compounds (amine compounds, amido group-containing compounds, urea compounds, nitrogen-containing heterocyclic compounds, and the like) described in paragraphs 0140 to 0144 of JP2013-011833A can also be used.

[Hydrophobic Resin]

The resist layer may further contain a hydrophobic resin different from the resin (A).

It is preferable that the hydrophobic resin is designed to be unevenly distributed on a surface of a resist film, but unlike the surfactant, the hydrophobic resin does not necessarily have a hydrophilic group in a molecule thereof and does not necessarily contribute to homogeneous mixing of polar/non-polar materials.

Examples of an effect of adding the hydrophobic resin include control of the static/dynamic contact angle of the resist film surface with respect to water, and suppression of outgas.

From the viewpoint of uneven distribution on a film surface layer, the hydrophobic resin preferably has any one or more, and more preferably has two or more, of a “fluorine atom”, a “silicon atom”, or a “CH3 partial structure contained in a side chain moiety of the resin”. Further, the hydrophobic resin preferably contains a hydrocarbon group having 5 or more carbon atoms. These groups may be contained in the main chain of the resin or may be substituted in a side chain.

In a case where the hydrophobic resin includes a fluorine atom or a silicon atom, or the both, the fluorine atom and the silicon atom described above in the hydrophobic resin may be included in the main chain of a resin or may be included in a side chain.

In a case where the hydrophobic resin includes a fluorine atom, it is preferably a resin which has an alkyl group having a fluorine atom, a cycloalkyl group having a fluorine atom, or an aryl group having a fluorine atom as a partial structure having a fluorine atom.

The alkyl group having a fluorine atom (preferably having 1 to 10 carbon atoms, and more preferably having 1 to 4 carbon atoms) is a linear or branched alkyl group in which at least one hydrogen atom is substituted with a fluorine atom, and may further have a substituent other than a fluorine atom.

The cycloalkyl group having a fluorine atom is a monocyclic or polycyclic cycloalkyl group in which at least one hydrogen atom is substituted with a fluorine atom, and may further have a substituent other than a fluorine atom.

Examples of the aryl group having a fluorine atom include an aryl group such as a phenyl group and a naphthyl group, in which at least one hydrogen atom is substituted with a fluorine atom, and the aryl group may further have a substituent other than a fluorine atom.

Examples of the constitutional unit having a fluorine atom or a silicon atom include those exemplified in paragraph 0519 of US2012/0251948A1.

Furthermore, as described above, it is also preferable that the hydrophobic resin includes a CH₃ partial structure in a side chain moiety.

Here, the CH₃ partial structure contained in the side chain moiety in the hydrophobic resin includes a CH₃ partial structure contained in an ethyl group, a propyl group, or the like.

On the other hand, a methyl group bonded directly to the main chain of the hydrophobic resin (for example, an α-methyl group in the constitutional unit having a methacrylic acid structure) makes only a small contribution of uneven distribution to the surface of the hydrophobic resin due to the effect of the main chain, and thus, this shall not included in the CH₃ partial structure in the present invention.

With regard to the hydrophobic resin, reference can be made to the description in paragraphs 0348 to 0415 of JP2014-010245A, the contents of which are incorporated herein by reference.

In addition, those described in JP2011-248019A, JP2010-175859A, and JP2012-032544A can also be preferably used as the hydrophobic resin.

The hydrophobic resin may be contained singly or in combination of two or more kinds thereof.

The content of the hydrophobic resin is preferably 0.01% by mass to 20% by mass, more preferably 0.01% by mass to 10% by mass, still more preferably 0.05% by mass to 8% by mass, and particularly preferably 0.5% by mass to 5% by mass with respect to the total mass of the resist layer.

[Surfactant]

The resist layer may further include a surfactant. By incorporating the surfactant into the composition, it is possible to provide a pattern having adhesiveness and less development defects with good sensitivity and resolution in a case where an exposure light source having a wavelength of 250 nm or less, and particularly 220 nm or less is used.

As the surfactant, a fluorine-based surfactant, a silicon-based surfactant, or both is particularly preferably used.

Examples of the fluorine-based and/or silicon-based surfactants include the surfactants described in paragraph 0276 of the specification of US2008/0248425A. In addition, EFTOP EF301 and EF303 (manufactured by Shin-Akita Chemical Co., Ltd.); FLUORAD FC430, 431, and 4430 (manufactured by Sumitomo 3M Inc.); MEGAFACE F171, F173, F176, F189, F113, F110, F177, F120, and R08 (manufactured by DIC Corp.); SURFLON S-382, SC101, 102, 103, 104, 105, and 106 (manufactured by Asahi Glass Co., Ltd.), TROYSOL S-366 (manufactured by Troy Chemical Corp.); ARON GF-300 and GF-150 (manufactured by Toagosei Chemical Industry Co., Ltd.); SURFLON S-393 (manufactured by Seimi Chemical Co., Ltd.); EFTOP EF121, EF122A, EF122B, RF122C, EF125M, EF135M, EF351, EF352, EF801, EF802, and EF601 (manufactured by JEMCO Inc.); PF636, PF656, PF6320, and PF6520 (manufactured by OMNOVA Solutions Inc.); or FTX-204G, 208G, 218G, 230G, 204D, 208D, 212D, 218D, and 222D (manufactured by NEOS Co., Ltd.) may be used. In addition, a polysiloxane polymer KP-341 (manufactured by Shin-Etsu Chemical Co., Ltd.) can be used as the silicon-based surfactant.

Moreover, in addition to the known surfactants as shown above, a surfactant may be synthesized using a fluoroaliphatic compound manufactured using a telomerization method (also referred to as a telomer method) or an oligomerization method (also referred to as an oligomer method). Specifically, a polymer including a fluoroaliphatic group derived from fluoroaliphatic compound may be used as the surfactant. This fluoroaliphatic compound can be synthesized, for example, by the method described in JP2002-090991A.

In addition, a surfactant other than the fluorine-based surfactant and/or the silicon-based surfactant described in paragraph 0280 of the specification of US2008/0248425A may be used.

These surfactants may be used singly or in combination of two or more kinds thereof.

The content of the surfactant is preferably 0.0001% by mass to 2% by mass, and more preferably 0.0005% by mass to 1% by mass with respect to the total mass of the resist layer.

[Other Additives]

The resist layer may further include other additives other than those described above.

As other additives, known additives can be used. Examples thereof include a dissolution inhibiting compound, a dye, a plasticizer, a photosensitizer, a light absorber, and/or a compound promoting a solubility in a developer (for example, a phenol compound having a molecular weight of 1,000 or less or an alicyclic or aliphatic compound including a carboxyl group).

The resist layer may further include a dissolution inhibiting compound. Here, the “dissolution inhibiting compound” is a compound having a molecular weight of 3,000 or less, having a solubility in an organic developer that decreases through decomposition by an action of an acid.

[Method of Forming Resist Layer]

The resist layer can be suitably formed by preparing a photosensitive resin composition including the components.

The photosensitive resin composition is used by dissolving the components in a predetermined organic solvent, and preferably the mixed solvent, filtering the solution through a filter, and then applying it onto, for example, the inorganic base layer. The pore size of a filter for use in filtration through the filter is preferably pore size (pore diameter) of 0.1 μm or less, more preferably 0.05 μm or less, and still more preferably 0.03 μm or less. The filter is preferably a polytetrafluoroethylene-made, polyethylene-made, or nylon-made filter. In the filtration through a filter as shown in the specification of JP2002-062667A, circulating filtration may be performed or the filtration may be performed by connecting plural kinds of filters in series or in parallel. In addition, the composition may be filtered in plural times. Furthermore, the composition may be subjected to a deaeration treatment or the like before or after filtration through a filter.

[[Solvent]]

The photosensitive resin composition preferably includes a solvent (also referred to as a “resist solvent”). The solvent may include isomers (compounds having the same number of atoms but different structures). Moreover, only one kind or a plurality of kinds of the isomers may be included. The solvent preferably includes at least one solvent of (M1) propylene glycol monoalkyl ether carboxylate, or (M2) at least one selected from the group consisting of a propylene glycol monoalkyl ether, a lactic ester, an acetic ester, an alkoxypropionic ester, a chain ketone, a cyclic ketone, a lactone, and an alkylene carbonate. Further, the solvent may further include components other than the components (M1) and (M2).

As the component (M1), at least one selected from the group consisting of propylene glycol monomethyl ether acetate, propylene glycol monomethyl ether propionate, and propylene glycol monoethyl ether acetate is preferable, and the propylene glycol monomethyl ether acetate is more preferable.

As the component (M2), the following ones are preferable.

As the propylene glycol monoalkyl ether, propylene glycol monomethyl ether or propylene glycol monoethyl ether is preferable.

As the lactic ester, ethyl lactate, butyl lactate, or propyl lactate is preferable.

As the acetic ester, methyl acetate, ethyl acetate, butyl acetate, isobutyl acetate, propyl acetate, isoamyl acetate, methyl formate, ethyl formate, butyl formate, propyl formate, or 3-methoxybutyl acetate is preferable. Furthermore, butyl butyrate is also preferred.

As the alkoxy propionic ester, methyl 3-methoxypropionate (MMP), or ethyl 3-ethoxypropionate (EEP) is preferable.

As the chain ketone, 1-octanone, 2-octanone, 1-nonanone, 2-nonanone, acetone, 4-heptanone, 1-hexanone, 2-hexanone, diisobutyl ketone, phenyl acetone, methyl ethyl ketone, methyl isobutyl ketone, acetyl acetone, acetonyl acetone, ionone, diacetonyl alcohol, acetyl carbinol, acetophenone, methyl naphthyl ketone, or methyl amyl ketone is preferable.

As the cyclic ketone, methyl cyclohexanone, isophorone, or cyclohexanone is preferable.

As the lactone, γ-butyrolactone is preferable.

As the alkylene carbonate, propylene carbonate is preferable.

As the component (M2), propylene glycol monomethyl ether, ethyl lactate, ethyl 3-ethoxypropionate, methyl amyl ketone, cyclohexanone, butyl acetate, pentyl acetate, g-butyrolactone, or propylene carbonate is more preferable.

In addition to the components, an ester-based solvent having 7 or more carbon atoms (preferably having 7 to 14 carbon atoms, more preferably having 7 to 12 carbon atoms, and still more preferably having 7 to 10 carbon atoms) and having 2 or less heteroatoms is preferably used.

Preferred examples of the ester-based solvents having 7 or more carbon atoms and 2 or less heteroatoms include amyl acetate, 2-methylbutyl acetate, 1-methylbutyl acetate, hexyl acetate, pentyl propionate, hexyl propionate, butyl propionate, isobutyl isobutyrate, heptyl propionate, and butyl butanoate, and isoamyl acetate is particularly preferably used.

As the component (M2), one having a flash point (hereinafter also referred to as fp) of 37° C. or higher is preferably used. As such a component (M2), propylene glycol monomethyl ether (fp: 47° C.), ethyl lactate (fp: 53° C.), ethyl 3-ethoxypropionate (fp: 49° C.), methyl amyl ketone (fp: 42° C.), cyclohexanone (fp: 44° C.), pentyl acetate (fp: 45° C.), methyl 2-hydroxyisobutyrate (fp: 45° C.), γ-butyrolactone (fp: 101° C.), or propylene carbonate (fp: 132° C.) is preferable. Among these, propylene glycol monoethyl ether, ethyl lactate, pentyl acetate, or cyclohexanone is more preferable, and propylene glycol monoethyl ether or ethyl lactate is particularly preferable. In addition, the “flash point” herein means the value described in a reagent catalog of Tokyo Chemical Industry Co., Ltd. or Sigma-Aldrich Co. LLC.

It is preferable that the solvent includes the component (M1). It is more preferable that the solvent substantially consists of only the component (M1) or is a mixed solvent of the component (M1) and other components. In the latter case, it is still more preferable that the solvent includes both the component (M1) and the component (M2).

The mass ratio of the component (M1) to the component (M2) is preferably in the range of 100:0 to 15:85, more preferably in the range of 100:0 to 40:60, and still more preferably in the range of 100:0 to 60:40. That is, it is preferable that the solvent consists of only the component (M1) or include both the component (M1) and the component (M2), and a mass ratio thereof is as follows. That is, in the latter case, the mass ratio of the component (M1) to the component (M2) is preferably 15/85 or more, more preferably 40/60 or more, and still more preferably 60/40 or more. In a case where such a configuration is adopted and used, it is possible to further reduce the number of development defects.

Moreover, in a case where the solvent includes both the component (M1) and the component (M2), the mass ratio of the component (M1) to the component (M2) is, for example, 99/1 or less.

As described above, the solvent may further include components other than the components (M1) and (M2). In this case, the content of the components other than the components (M1) and (M2) is preferably in the range of 5% by mass to 30% by mass with respect to the total mass of the solvent.

From the viewpoint of a coating property, the content of the solvent in the photosensitive resin composition is preferably set such that the concentration of solid contents is 0.5% by mass to 30% by mass, and more preferably set such that the concentration of solid contents is 1% by mass to 20% by mass.

Further, the concentration of solid contents of the photosensitive resin composition can be appropriately adjusted for the purpose of adjusting the thickness of the resist film to be prepared.

The film thickness of the resist film consisting of the photosensitive resin composition according to the disclosure is not particularly limited, but is preferably 200 nm or less, more preferably 90 nm or less, still more preferably from 10 nm to 85 nm, and particularly preferably from 30 nm to 70 nm, from the viewpoint of improving the resolving power. Such a film thickness can be easily obtained by setting the concentration of solid contents in the composition to an appropriate range to provide the composition with a suitable viscosity and improve the coating property or the film forming property.

—Other Layers—

The laminate may have other layers other than those as mentioned above.

As such other layer, a known layer can be provided.

For example, the laminate may have a topcoat layer on the resist layer.

The top coat layer is not particularly limited, and top coat layers known in the related art can be formed by the methods known in the related art, and a top coat layer can be formed in accordance with, for example, the description in paragraphs 0072 to 0082 of JP2014-059543A.

The thickness of the top coat layer is preferably 10 nm to 200 nm, more preferably 20 nm to 100 nm, and particularly preferably 40 nm to 80 nm.

<Exposing Step>

The pattern forming method according to the embodiment of the disclosure includes a step of exposing the resist layer (also referred to as an “exposing step”).

The exposing step can be performed by, for example, the following method.

The resist layer is irradiated with light through a predetermined mask. Further, in the irradiation with electron beams, drawing without using a mask (direct lithography) is common.

The light used for the exposure is not particularly limited, and examples thereof include a KrF excimer laser, an ArF excimer laser, extreme ultraviolet rays (EUV), and electron beams (EB), with the extreme ultraviolet rays or the electron beams being particularly preferable. The exposure may be liquid immersion exposure.

Among those, from the viewpoint of etching resistance and resolution, it is preferable that the exposure in the exposing step is performed with ultraviolet rays having a wavelength of 5 nm to 20 nm.

The exposure dose is preferably 5 mJ/cm² to 200 mJ/cm², and more preferably 10 mJ/cm² to 100 mJ/cm².

<Baking Step>

In the pattern forming method according to the embodiment of the disclosure, it is preferable to perform baking after the exposing step and before the developing step (post-exposure baking (PEB)). Baking accelerates the reaction of the exposed area, resulting in better sensitivity and pattern shape.

The heating temperature is preferably 80° C. to 150° C., more preferably 80° C. to 140° C., and still more preferably 80° C. to 130° C.

The heating time is preferably 30 seconds to 1,000 seconds, more preferably 60 seconds to 800 seconds, and still more preferably 60 seconds to 600 seconds.

Heating may be performed using a unit included in a known exposure/development machine, or may also be performed using a hot plate or the like.

<Developing Step>

The pattern forming method according to the embodiment of the disclosure includes a step of developing the laminate with a developer including an organic solvent to form a negative tone pattern (also referred to as a “developing step”).

The development in the developing step is performed with a developer including an organic solvent.

As the developing method, for example, a method in which a substrate is dipped in a tank filled with a developer including an organic solvent for a certain period of time (a dip method), a method in which development is performed by heaping a developer including an organic solvent up onto the surface of a substrate by surface tension, and then leaving it to stand for a certain period of time (a puddle method), a method in which a developer including an organic solvent is sprayed on the surface of a substrate (a spray method), and a method in which a developer including an organic solvent is continuously jetted onto a substrate spun at a constant rate while scanning a developer jetting nozzle at a constant rate (a dynamic dispense method) can be applied.

Furthermore, after the developing step, a step of stopping the development may be carried out while substituting the solvent with another solvent.

The developing time is not particularly limited as long as the resin in the exposed area or the unexposed area is sufficiently dissolved, and the developing time is preferably 10 seconds to 300 seconds, and more preferably 10 seconds to 120 seconds.

The temperature of the developer including an organic solvent is preferably 0° C. to 50° C., and more preferably 15° C. to 35° C.

Next, the organic solvent included in the developer will be described.

The vapor pressure of the organic solvent (the total vapor pressure in a case of a mixed solvent) is preferably 5 kPa or less, more preferably 3 kPa or less, and particularly preferably 2 kPa or less at 20° C. By adjusting the vapor pressure of the organic solvent to 5 kPa or less, the evaporation of the developer for use in combination on a substrate or in a developing cup is suppressed, the temperature uniformity in the wafer surface is improved, and as a result, the dimensional uniformity within a wafer surface is improved.

As the organic solvent, various organic solvents are widely used, but for example, solvents such as an ester-based solvent, a ketone-based solvent, an alcohol-based solvent, an amide-based solvent, an ether-based solvent, and a hydrocarbon-based solvent can be used.

Among these, the developer is preferably a developer containing at least one organic solvent selected from the group consisting of a ketone-based solvent, an ester-based solvent, an alcohol-based solvent, an amide-based solvent, an ether-based solvent, and a hydrocarbon-based solvent.

—Ketone-Based Solvent—

Examples of the ketone-based solvent include 1-octanone, 2-octanone, 1-nonanone, 2-nonanone, acetone, 2-heptanone (methyl amyl ketone), 4-heptanone, 1-hexanone, 2-hexanone, diisobutyl ketone, cyclohexanone, methylcyclohexanone, phenyl acetone, methyl ethyl ketone, methyl isobutyl ketone, acetyl acetone, acetonyl acetone, ionone, diacetonyl alcohol, acetyl carbinol, acetophenone, methyl naphthyl ketone, isophorone, and propylene carbonate.

—Ester-Based Solvent—

Examples of the ester-based solvent include methyl acetate, butyl acetate, ethyl acetate, isopropyl acetate, pentyl acetate, isopentyl acetate, amyl acetate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, methyl formate, ethyl formate, butyl formate, propyl formate, ethyl lactate, butyl lactate, propyl lactate, butyl butyrate, methyl 2-hydroxyisobutyrate, isoamyl acetate, isobutyl isobutyrate, and butyl propionate.

—Other Solvents—

As the alcohol-based solvent, the amide-based solvent, the ether-based solvent, and the hydrocarbon-based solvent, the solvents disclosed in paragraphs 0715 to 0718 of the specification of US2016/0070167A can be used.

A plurality of the solvents may be mixed or the solvent may be used in admixture with a solvent other than those described above or water. The moisture content in the entire developer is preferably less than 50% by mass, more preferably less than 20% by mass, and still more preferably less than 10% by mass, and it is particularly preferable that water is not substantially contained.

The content of the organic solvent in the developer is preferably from 50% by mass to 100% by mass, more preferably from 80% by mass to 100% by mass, still more preferably from 90% by mass to 100% by mass, and particularly preferably from 95% by mass to 100% by mass with respect to the total amount of the developer.

In a case where extreme ultraviolet rays (EUV) or electron beams (EB) are used in the exposing step, it is preferable to use an ester-based solvent having 6 or more carbon atoms (preferably 6 to 14 carbon atoms, more preferably 6 to 12 carbon atoms, and still more preferably 6 to 10 carbon atoms) and having 2 or less heteroatoms as the organic solvent included in the developer from the viewpoint that the swelling of a resist layer can be suppressed.

The heteroatom of the ester-based solvent is an atom other than a carbon atom and a hydrogen atom, and examples thereof include an oxygen atom, a nitrogen atom, and a sulfur atom. The number of heteroatoms is preferably 2 or less.

Preferred examples of the ester-based solvents having 6 or more carbon atoms and 2 or less heteroatoms include butyl acetate, amyl acetate, isoamyl acetate, 2-methylbutyl acetate, 1-methylbutyl acetate, hexyl acetate, pentyl propionate, hexyl propionate, butyl propionate, isobutyl isobutyrate, heptyl propionate, and butyl butanoate, isoamyl acetate is particularly preferably used.

It is also preferable that the developer contains an antioxidant. As a result, generation of an oxidizing agent over time can be suppressed, and the content of the oxidizing agent can be further reduced. As the antioxidant, a known antioxidant can be used, but in a case where the antioxidant is used in semiconductor applications, an amine-based antioxidant or a phenol-based antioxidant is preferably used.

The content of the antioxidant is not particularly limited, but is preferably 0.0001% by mass to 1% by mass, more preferably 0.0001% by mass to 0.1% by mass, and still more preferably 0.0001% by mass to 0.01% by mass with respect to the total mass of the developer. In a case where the content of the antioxidant is 0.0001% by mass or more, a more excellent antioxidant effect is obtained, and in a case where the content of the antioxidant is 1% by mass or less, there is a tendency that the development residue can be suppressed.

The developer may contain a basic compound, and specific examples of the basic compound include the same ones as the basic compounds which may be contained in the resist layer.

The developer may contain a surfactant. In a case where the developer contains the surfactant, the wettability with respect to the actinic ray-sensitive or radiation-sensitive film is improved, and the development proceeds more effectively.

As the surfactant, the same one as the surfactant which can be contained in the resist layer can be used.

In a case where the developer contains a surfactant, the content of the surfactant is preferably 0.001% to 5% by mass, more preferably 0.005% to 2% by mass, and still more preferably 0.01% to 0.5% by mass with respect to the total mass of the developer.

<Rinsing Step>

The pattern forming method according to the embodiment of the disclosure may include a step of treating the surface of the laminate with a rinsing liquid (also referred to as a “rinsing step”) after the developing step.

In the rinsing step, a wafer which has been subjected to development is subjected to a washing treatment using a rinsing liquid.

A method for the washing treatment method is not particularly limited, but for example, a method in which a rinsing liquid is continuously jetted on a substrate rotated at a constant rate (a rotation jetting method), a method in which a substrate is immersed in a tank filled with a rinsing liquid for a certain period of time (a dip method), a method in which a rinsing liquid is sprayed on a substrate surface (a spray method), or the like can be applied, and among these, it is preferable that the washing treatment is performed using the rotation application method, and the substrate is rotated at a rotation speed of 2,000 rpm to 4,000 rpm after washing, thereby removing the rinsing liquid from the substrate.

The rinsing time is not particularly limited, but is preferably 10 seconds to 300 seconds, more preferably 10 seconds to 180 seconds, and particularly preferably 20 seconds to 120 seconds.

The temperature of the rinsing liquid is preferably 0° C. to 50° C., and more preferably 15° C. to 35° C.

Moreover, the pattern forming method according to the embodiment of the disclosure may also include a step of removing the developer or the rinsing liquid adhering to the pattern with a supercritical fluid after the developing step or the rinsing step.

Furthermore, a heat treatment can be performed to remove the solvent remaining in the pattern after the developing step, the rinsing step, or the step of treating with a supercritical fluid. The heating temperature is not particularly limited as long as a good resist pattern can be obtained, and is preferably 40° C. to 160° C., more preferably 50° C. to 150° C., and particularly preferably 50° C. to 110° C. The heating time is not particularly limited as long as a good resist pattern can be obtained, but is preferably 15 seconds to 300 seconds, and more preferably 15 seconds to 180 seconds.

—Rinsing Liquid—

Pure water can be used as a rinsing liquid used in the rinsing treatment performed after the developing step, and an appropriate amount of a surfactant may be added and used.

As the rinsing liquid, a rinsing liquid including an organic solvent is preferably used, and as the organic solvent, at least one organic solvent selected from the group consisting of a hydrocarbon-based solvent, a ketone-based solvent, an ester-based solvent, an alcohol-based solvent, an amide-based solvent, and an ether-based solvent is preferable.

The organic solvent included in the rinsing liquid is preferably at least one selected from the group consisting of an ester-based solvent, a hydrocarbon-based solvent, an ether-based solvent, and a ketone-based solvent, and more preferably the ester-based solvent.

Specific examples of these organic solvents are the same as those described for the organic solvents contained in the developer described above.

The vapor pressure of the rinsing liquid is preferably from 0.05 kPa to 5 kPa, more preferably from 0.1 kPa to 5 kPa, and most preferably from 0.12 kPa to 3 kPa at 20° C. In a case where the rinsing liquid is a mixed solvent of a plurality of solvents, the vapor pressure as a whole is preferably in the range. By setting the vapor pressure of the rinsing liquid to from 0.05 kPa to 5 kPa, the temperature uniformity in the wafer surface is enhanced, swelling due to the permeation of the rinsing liquid is suppressed, and the dimensional uniformity in the wafer surface is improved.

The rinsing liquid may include only one kind or two or more kinds of organic solvents. Examples of a case where the two or more kinds are included include a mixed solvent of butyl acetate and isoamyl acetate.

The rinsing liquid may contain a surfactant. In a case where the rinsing liquid contains a surfactant, the wettability to the resist film is improved, the rinsing property is improved, and the generation of foreign substances tends to be suppressed.

As the surfactant, the same surfactant as those which may be included in the resist layer can be used.

In a case where the rinsing liquid contains a surfactant, the content of the surfactant is preferably 0.001% by mass to 5% by mass, more preferably 0.005% by mass to 2% by mass, and still more preferably 0.01% by mass to 0.5% by mass with respect to the total mass of the rinsing liquid.

The rinsing liquid may contain an antioxidant. The antioxidant which may be contained in the rinsing liquid is the same one as the antioxidant which may be contained in the developer as mentioned above.

In a case where the rinsing liquid contains an antioxidant, the content of the antioxidant is not particularly limited, but is preferably 0.0001% by mass to 1% by mass, more preferably 0.0001% by mass to 0.1% by mass, and still more preferably 0.0001% by mass to 0.01% by mass with respect to the total mass of the rinsing liquid.

The rinsing step may be included after the developing step, but the rinsing step may not be included from the viewpoint of a throughput (productivity).

With regard to a treating method which does not include the rinsing step, reference can be made to, for example, the descriptions in paragraphs 0014 to 0086 of JP2015-216403A, the contents of which are incorporated herein by reference.

Moreover, methyl isobutyl carbinol (MIBC) or the same liquid (particularly butyl acetate) as the developer is also preferable as the rinsing liquid.

<Impurities of Various Materials>

It is preferable that various materials (for example, a coating liquid for forming an inorganic base layer, a photosensitive resin composition for forming a resist layer, a developer, a rinsing liquid, a composition for forming an antireflection film, and a composition for forming a top coat layer) used in the pattern forming method according to the embodiment of the disclosure include no impurities such as metal components, isomers, and residual monomers. The content of the impurities included in these materials is preferably 1 ppm or less, more preferably 100 ppt or less, and still more preferably 10 ppt or less, and particularly preferably, the impurities are not substantially included (no higher than a detection limit of a measurement device).

Examples of a method for removing impurities such as metals from the various materials include filtration using a filter. As for the filter pore diameter, the pore size is preferably 10 nm or less, more preferably 5 nm or less, and still more preferably 3 nm or less. As for the materials of a filter, a polytetrafluoroethylene-made, polyethylene-made, or nylon-made filter is preferable. As the filter, a filter which has been washed with an organic solvent in advance may be used. In the step of filtration using a filter, plural kinds of filters connected in series or in parallel may be used. In a case of using the plural kinds of filters, a combination of filters with at least one of pore diameters and materials being different from each other may be used. In addition, various materials may be filtered plural times, and the step of filtering plural times may be a circulatory filtration step. As the filter, a filter having a reduced amount of elutes as disclosed in JP2016-201426A is preferable.

In addition to the filtration using a filter, removal of impurities by an adsorbing material may be performed, or a combination of filtration using a filter and an adsorbing material may be used. As the adsorbing material, known adsorbing materials can be used, and for example, inorganic adsorbing materials such as silica gel and zeolite, and organic adsorbing materials such as activated carbon can be used. Examples of the metal adsorbing material include those disclosed in JP2016-206500A.

In addition, as a method for removing the impurities such as metals included in the various materials, metal content selects the less material as a raw material constituting the various materials, performing filtering using a filter of the raw material constituting the various materials, equipment the inner and a method such as performing distillation under conditions suppressing as much where available equal to contamination is lined with TEFLON (registered trademark). Preferred conditions in the filtering using a filter to be performed on the raw material constituting the various materials are the same as the above-described conditions.

In order to prevent impurities from being incorporated, it is preferable that various materials are stored in the container described in the specification of US2015/0227049A, JP2015-123351A, JP2017-013804A, or the like.

<Improvement of Surface Roughness>

A method for improving the surface roughness of a pattern may be applied to a pattern formed by the pattern forming method according to the embodiment of the disclosure. Examples of the method for improving the surface roughness of a pattern include the method of treating a resist pattern with plasma of a hydrogen-containing gas, as disclosed in the specification of US2015/0104957A. In addition, known methods as described in the specification of JP2004-235468A, the specification of US2010/0020297A, and Proc. of SPIE Vol. 8328 83280N-1 “EUV Resist Curing Technique for LWR Reduction and Etch Selectivity Enhancement” may be applied.

In addition, a resist pattern formed by the method can be used as a core material (core) of the spacer process disclosed in, for example, the specification of JP1991-270227A (JP-H03-270227A) and the specification of US2013/0209941A.

<Shape of Pattern Obtained>

The shape of a pattern obtained by the pattern forming method according to the embodiment of the disclosure is not particularly limited and may be any desired shape, but since the pattern forming method according to the embodiment of the disclosure provides excellent adhesiveness between the resist layer and the inorganic base layer, a pattern having a high height can be easily formed.

The value of a pattern height/a pattern width in at least a part of the pattern obtained by the pattern forming method according to the embodiment of the disclosure is preferably 1.2 to 2.0 or more, more preferably 1.4 to 1.9, and still more preferably 1.5 to 1.8, from the viewpoint of the balance between etching resistance and resolution.

<Uses>

By appropriately performing an etching treatment, ion injection, or the like with a use of a pattern obtained by the pattern forming method according to the embodiment of the disclosure as a mask, a semiconductor fine circuit, a mold structure for imprints, a photomask, or the like can be manufactured.

Furthermore, the pattern obtained by the pattern forming method according to the embodiment of the disclosure can also be used for a guide pattern formation in a directed self-assembly (DSA) (see, for example, ACS Nano Vol. 4 No. 8 Pages 4815-4823).

In addition, the pattern formed by the pattern forming method according to the embodiment of the disclosure can be used as, for example, a core material (core) of the spacer process disclosed in JP1991-270227A (JP-H03-270227A) and JP2013-164509A.

In addition, a process of a case where a mold for imprints is manufactured using the pattern forming method according to the embodiment of the disclosure is described in, for example, JP4109085B, JP2008-162101A, and “Fundamentals of Nanoimprint and Technical Development/Application Deployment-Substrate Technique of Nanoimprint and Latest Application Deployment”, edited by Yoshihiko Hirai (Frontier Publishing).

The photomask produced by the pattern forming method according to the embodiment of the disclosure may be either a light-transmitting mask used in an ArF excimer laser or the like, or a light-reflecting mask used in a reflection system lithography using EUV light as a light source.

(Method for Manufacturing Electronic Device)

A method for manufacturing an electronic device according to an embodiment of the disclosure includes the pattern forming method according to the embodiment of the disclosure. The electronic device manufactured by the method for manufacturing an electronic device according to the embodiment of the disclosure is suitably mounted on electric or electronic equipment (for example, home electronics, office automation (OA)-related equipment, media-related equipment, optical equipment, and telecommunication equipment).

(Resist Laminate for Organic Solvent Development)

The resist laminate for organic solvent development according to an embodiment of the disclosure has a substrate, an inorganic base layer on the substrate, and a resist layer provided on the inorganic base layer so that the resist layer is in contact with the inorganic base layer, in which a surface energy γA of the resist layer after irradiating the laminate with ultraviolet rays having a wavelength of 13.5 nm from the resist layer side with an integrated light quantity of 40 mJ/cm² and heating the laminate at 110° C. for 60 seconds is 60 mJ/m² or more, a surface energy γB of the base layer after irradiating the laminate with ultraviolet rays having a wavelength of 13.5 nm from the resist layer side with an integrated light quantity of 40 mJ/cm² and heating the laminate at 110° C. for 60 seconds is 50 mJ/m² or more, and a difference γAB in surface energy which is defined by Formula (A) is 5.0 mJ/m² or less.

γAB=γA−γB Formula (A).

The resist laminate for organic solvent development according to the embodiment of the disclosure is a resist laminate which can be developed with a developer including an organic solvent, and suitable examples of the developer including an organic solvent include the above-mentioned developers.

The resist laminate for organic solvent development according to the embodiment of the disclosure is the same as the above-mentioned laminate in the pattern forming method according to the embodiment of the disclosure, and a preferred aspect thereof is also the same.

### EXAMPLES

Hereinafter, embodiments of the present invention will be described in more detail with reference to Examples. The materials, the amounts of materials used, the proportions, the treatment details, the treatment procedure, and the like shown in the Examples below may be modified as appropriate as long as the modifications do not depart from the spirit of the embodiments of the present invention. Therefore, the scope of the embodiments of the present invention should not be construed as being limited to specific examples shown below. In addition, “part” and “%” are based on mass unless otherwise specified.

<Synthesis of Resin P-1>

30 parts by mass of 3,4-dihydroxystyrene (34DHS), 20 parts by mass of norbornane ester-based methacrylate (N, the following compound) shown below, 10 parts by mass of methacrylic acid (MA), 40 parts by mass of 1-isopropylcyclopentyl methacrylate (ester 3, the following compound), and 2.5 parts by mass of a polymerization initiator V-601 (dimethyl 2,2′-azobis(2-methylpropionate), manufactured by FUJIFILM Wako Pure Chemical Corporation) were dissolved in 367 parts by mass of cyclohexanone. 200 parts by mass of cyclohexanone was put in a reaction vessel, and the mixture was added dropwise to the system at 85° C. over 4 hours under a nitrogen gas atmosphere. The reaction solution was heated and stirred for 2 hours, and then allowed to be cooled to room temperature. The reaction solution was added dropwise to 665 parts by mass of a mixed solution of n-heptane and ethyl acetate (n-heptane/ethyl acetate=9/1 (mass ratio)) to precipitate a polymer, which was then filtered. The filtered solid was washed with 200 parts by mass of a mixed solution of n-heptane and ethyl acetate (n-heptane/ethyl acetate=9/1 (mass ratio)). Thereafter, the washed solid was subjected to vacuum drying to obtain a resin P-1.

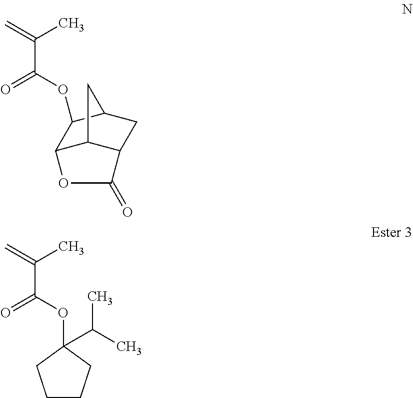 [SMILES: C=C(C)C(=O)OC1C2CC3C(=O)OC1C3C2 ; C=C(C)C(=O)OC1(C(C)C)CCCC1]

<Synthesis of Resins P-2 to P-44>

Resins P-2 to P-44 were each synthesized by the same method as in Synthesis of Resin P-1, except that the monomers used in the synthesis of resin P-1 were changed to the monomers and the contents shown in Table 1 below.

Moreover, the resins P-1 to P-44 each had an Mw in the range of 8,000 to 15,000, and a dispersity (Mw/Mn) in the range of 1.3 to 1.7.

TABLE 1

| | | | | | | Ester | Ester | Ester | Ester |
|---|---|---|---|---|---|---|---|---|---|
| | PHS | 34DHS | N | MA | Ester 1 | 2 | 3 | 4 | 5 |
| P-1 | — | 30 | 20 | 10 | — | — | 40 | — | — |
| P-2 | 30 | — | 20 | 10 | — | 40 | — | — | — |
| P-3 | 50 | — | — | — | 50 | — | — | — | — |
| P-4 | 50 | — | — | — | — | 50 | — | — | — |
| P-5 | 40 | — | — | — | — | — | 60 | — | — |
| P-6 | — | 30 | 10 | 20 | — | 40 | — | — | — |
| P-7 | 30 | 35 | — | — | — | — | — | — | 35 |
| P-8 | — | 50 | — | — | 50 | — | — | — | — |
| P-9 | — | 40 | — | — | — | 60 | — | — | — |
| P-10 | — | 40 | — | — | — | 60 | — | — | — |
| P-11 | — | 30 | — | — | — | — | — | 70 | — |
| P-12 | — | 20 | — | — | — | — | 80 | — | — |
| P-13 | 40 | — | — | — | 60 | — | — | — | — |
| P-14 | 30 | — | — | — | — | 70 | — | — | — |
| P-15 | 30 | — | — | — | — | 70 | — | — | — |
| P-16 | 20 | — | — | — | — | 80 | — | — | — |
| P-17 | 30 | — | 10 | — | 60 | — | — | — | — |
| P-18 | 30 | — | 10 | — | — | 60 | — | — | — |
| P-19 | 30 | — | 10 | — | — | — | — | — | 60 |
| P-20 | — | 30 | 20 | — | — | 50 | — | — | — |
| P-21 | — | 40 | 10 | — | — | 50 | — | — | — |
| P-22 | — | 30 | 10 | — | — | — | 60 | — | — |
| P-23 | — | 30 | 10 | 10 | — | — | 50 | — | — |
| P-24 | — | — | 40 | — | — | — | — | 60 | — |
| P-25 | — | — | 40 | — | — | — | — | — | 60 |
| P-26 | — | — | 40 | — | — | — | — | — | 60 |
| P-27 | 30 | — | — | — | — | — | — | 70 | — |
| P-28 | — | — | 30 | — | — | — | — | — | 70 |
| P-29 | — | — | 40 | — | — | 60 | — | — | — |
| P-30 | — | 50 | — | 10 | — | 40 | — | — | — |
| P-31 | — | — | 40 | — | 60 | — | — | — | — |
| P-32 | — | — | 40 | — | — | 60 | — | — | — |
| P-33 | — | 20 | — | — | — | 80 | — | — | — |
| P-34 | — | — | 30 | — | — | — | — | — | 70 |
| P-35 | — | — | 30 | — | — | — | — | — | 70 |
| P-36 | — | — | 50 | — | — | 50 | — | — | — |
| P-37 | 10 | — | 40 | — | — | 50 | — | — | — |
| P-38 | 30 | — | 30 | — | — | — | 40 | — | — |
| P-39 | 10 | — | 40 | — | — | — | 50 | — | — |
| P-40 | — | — | 50 | — | — | — | — | 50 | — |
| P-41 | — | — | 40 | — | — | 60 | — | — | — |
| P-42 | 10 | — | 50 | — | — | 40 | — | — | — |
| P-43 | — | — | 50 | — | — | — | — | — | 50 |
| P-44 | — | — | 50 | — | — | 50 | — | — | — |

Details of each monomer shown in Table 1 other than those described above are shown below.

PHS: 4-Hydroxystyrene

Ester 1: 1-Methylcyclopentyl methacrylate

Ester 2: t-Butyl methacrylate

Ester 4: 2-Methacryloyloxy-2-methyladamantane

Ester 5: 1-Phenylcyclohexyl methacrylate

<Preparation of PAG1 to PAG44>

A salt having an anion shown in Table 2 was reacted with a salt having a cation shown in Table 2, and PAG1 to PAG44 were prepared so that they had the molar ratios shown in Table 2, respectively.

TABLE 2

| | AN- | AN- | AN- | AN- | AN- | AN- | AN- | AN- | AN- | AN- | AN- | AN- | AN- | CA- | CA- | CA- | CA- | CA- | CA- |
|---|---|---|---|---|---|---|---|---|---|---|---|---|---|---|---|---|---|---|---|
| | 1 | 2 | 3 | 4 | 5 | 6 | 7 | 8 | 9 | 10 | 11 | 12 | 13 | 1 | 2 | 3 | 4 | 5 | 6 |
| PAG1 | — | — | — | 0.30 | — | — | 0.10 | — | — | — | — | — | — | 0.40 | — | — | — | — | — |
| PAG2 | — | 0.30 | — | — | — | — | 0.10 | — | — | — | — | — | — | 0.40 | — | — | — | — | — |
| PAG3 | — | — | — | — | — | 0.30 | 0.10 | — | — | — | — | — | — | 0.40 | — | — | — | — | — |
| PAG4 | — | — | — | — | — | 0.30 | 0.10 | — | — | — | — | — | — | 0.40 | — | — | — | — | — |
| PAG5 | — | — | — | — | — | 0.30 | 0.10 | — | — | — | — | — | — | 0.40 | — | — | — | — | — |
| PAG6 | — | — | — | — | — | 0.30 | 0.10 | — | — | — | — | — | — | 0.40 | — | — | — | — | — |
| PAG7 | — | — | — | — | — | 0.20 | — | — | — | — | — | — | — | 0.20 | — | — | — | — | — |
| PAG8 | — | — | 0.20 | — | — | — | 0.15 | — | — | — | — | — | — | 0.35 | — | — | — | — | — |
| PAG9 | — | — | — | — | 0.30 | — | 0.10 | — | — | — | — | — | — | 0.40 | — | — | — | — | — |
| PAG10 | — | — | — | — | 0.30 | — | 0.10 | — | — | — | — | — | — | 0.40 | — | — | — | — | — |
| PAG11 | — | — | — | — | 0.30 | — | 0.10 | — | — | — | — | — | — | 0.40 | — | — | — | — | — |
| PAG12 | — | — | — | — | 0.20 | — | 0.10 | — | — | — | — | — | — | 0.30 | — | — | — | — | — |
| PAG13 | — | — | 0.20 | — | 0.20 | — | — | — | — | — | — | — | — | 0.40 | — | — | — | — | — |
| PAG14 | — | — | 0.20 | — | 0.20 | — | — | — | — | — | — | — | — | 0.40 | — | — | — | — | — |
| PAG15 | — | — | 0.20 | — | 0.20 | — | — | — | — | — | — | — | — | 0.40 | — | — | — | — | — |
| PAG16 | — | — | — | — | — | — | — | — | — | — | 0.30 | — | — | — | 0.30 | — | — | — | — |
| PAG17 | — | — | — | — | — | — | — | — | 0.30 | — | — | — | — | 0.30 | — | — | — | — | — |
| PAG18 | — | — | — | — | — | — | — | — | 0.30 | — | — | — | — | 0.30 | — | — | — | — | — |
| PAG19 | — | — | — | — | — | — | — | 0.20 | — | — | — | — | — | 0.20 | — | — | — | — | — |
| PAG20 | — | — | — | — | 0.30 | — | — | — | — | — | — | — | — | 0.30 | — | — | — | — | — |
| PAG21 | — | — | — | — | 0.30 | — | — | — | — | — | — | — | — | 0.30 | — | — | — | — | — |
| PAG22 | — | — | — | — | — | — | — | — | — | — | 0.30 | — | — | — | — | 0.30 | — | — | — |
| PAG23 | — | — | — | — | — | — | — | — | — | — | — | 0.30 | — | 0.30 | — | — | — | — | — |
| PAG24 | — | — | — | — | — | — | — | — | 0.30 | — | — | — | — | 0.30 | — | — | — | — | — |
| PAG25 | — | — | — | — | — | — | 0.30 | — | — | — | — | — | — | — | — | — | 0.30 | — | — |
| PAG26 | — | — | — | — | — | — | 0.30 | — | — | — | — | — | — | — | — | — | 0.30 | — | — |
| PAG27 | — | — | — | — | — | 0.10 | — | — | — | — | — | — | 0.30 | — | — | — | — | 0.40 | — |
| PAG28 | — | — | — | — | — | 0.10 | — | — | — | — | — | — | 0.30 | — | — | — | — | 0.40 | — |
| PAG29 | — | — | — | — | — | — | — | 0.20 | — | — | — | — | — | 0.20 | — | — | — | — | — |
| PAG30 | — | 0.20 | — | — | — | — | — | — | — | 0.20 | — | — | — | 0.40 | — | — | — | — | — |
| PAG31 | — | 0.20 | — | — | — | — | — | — | — | 0.20 | — | — | — | 0.40 | — | — | — | — | — |
| PAG32 | — | — | — | — | — | — | 0.30 | — | — | — | — | — | — | 0.30 | — | — | — | — | — |
| PAG33 | — | — | — | — | 0.20 | — | 0.10 | — | — | — | — | — | — | 0.30 | — | — | — | — | — |
| PAG34 | — | — | — | — | — | 0.10 | — | — | — | — | — | — | 0.30 | — | — | — | — | 0.40 | — |
| PAG35 | — | — | — | — | — | 0.10 | — | — | — | — | — | — | 0.30 | — | — | — | — | 0.40 | — |
| PAG36 | 0.20 | — | — | — | — | — | 0.10 | — | — | — | — | — | — | — | — | — | — | — | 0.30 |
| PAG37 | — | — | 0.20 | — | — | 0.20 | — | — | — | — | — | — | — | 0.40 | — | — | — | — | — |
| PAG38 | — | 0.10 | — | — | — | — | — | 0.30 | — | — | — | — | — | 0.40 | — | — | — | — | — |
| PAG39 | — | — | — | — | — | — | — | — | — | 0.30 | — | — | — | 0.30 | — | — | — | — | — |
| PAG40 | — | 0.20 | — | — | — | — | 0.20 | — | — | — | — | — | — | 0.40 | — | — | — | — | — |
| PAG41 | — | — | 0.20 | — | 0.20 | — | — | — | — | — | — | — | — | 0.40 | — | — | — | — | — |
| PAG42 | — | — | 0.20 | — | 0.20 | — | — | — | — | — | — | — | — | 0.40 | — | — | — | — | — |
| PAG43 | — | — | — | — | — | 0.30 | — | — | — | — | — | — | — | 0.30 | — | — | — | — | — |
| PAG44 | — | — | 0.30 | — | — | — | — | — | — | — | — | — | — | 0.30 | — | — | — | — | — |

Details of anions (AN-1 to AN-13) and cations (CA-1 to CA-6) shown in Table 2 are shown below.

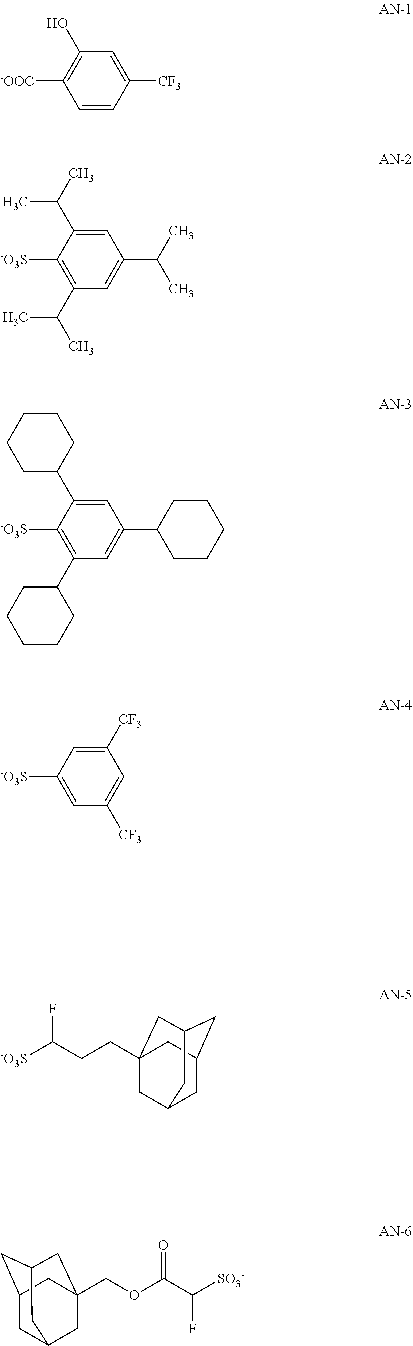

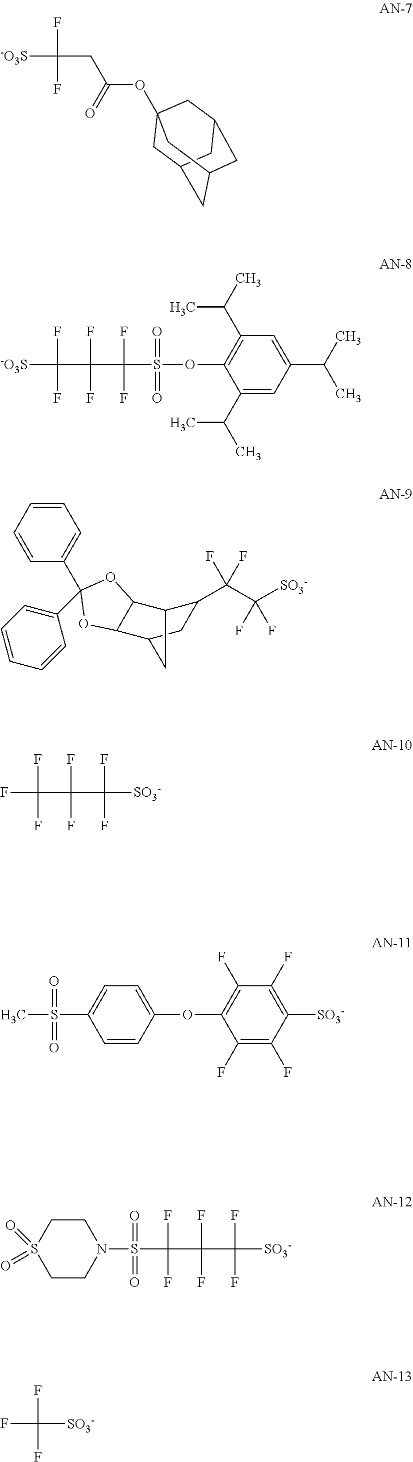

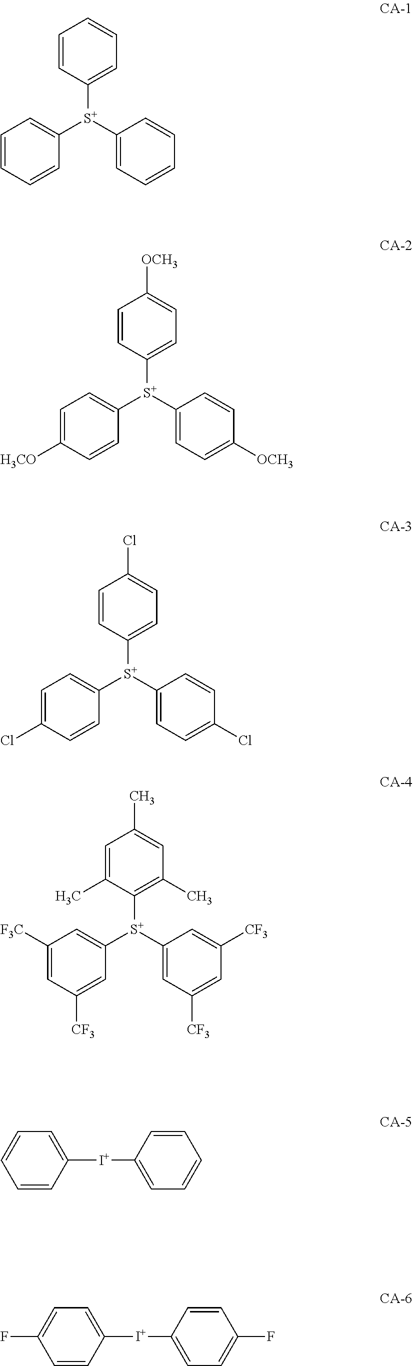 [SMILES: c1ccc([S+](c2ccccc2)c2ccccc2)cc1 ; COc1ccc([S+](c2ccc(OC)cc2)c2ccc(OC)cc2)cc1 ; Clc1ccc([S+](c2ccc(Cl)cc2)c2ccc(Cl)cc2)cc1 ; Cc1cc(C)c([S+](c2cc(C(F)(F)F)cc(C(F)(F)F)c2)c2cc(C(F)(F)F)cc(C(F)(F)F)c2)c(C)c1 ; c1ccc([I+]c2ccccc2)cc1 ; Fc1ccc([I+]c2ccc(F)cc2)cc1]

In addition, the amine compounds used in Examples or Comparative Examples are shown below.

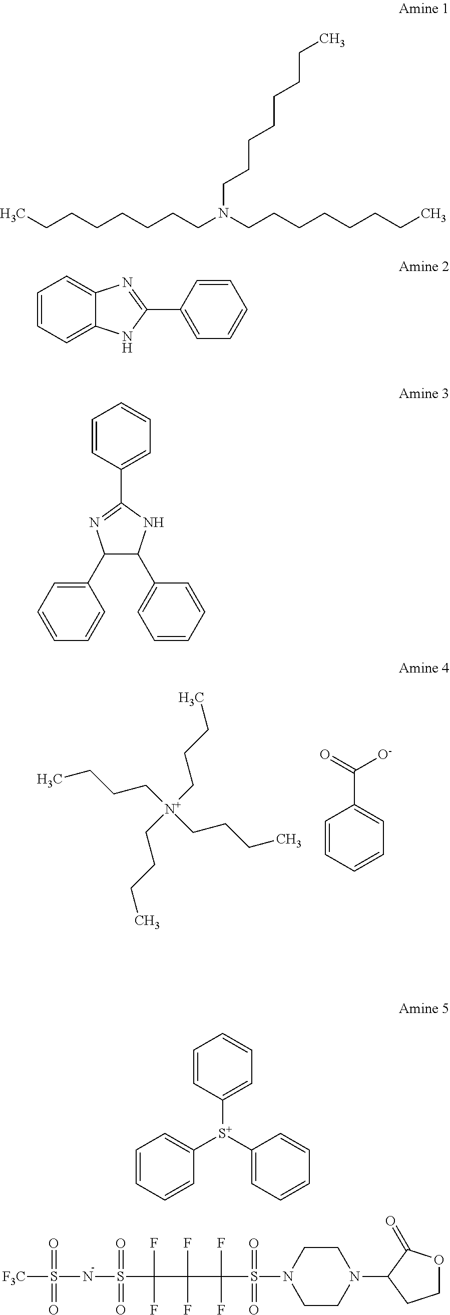

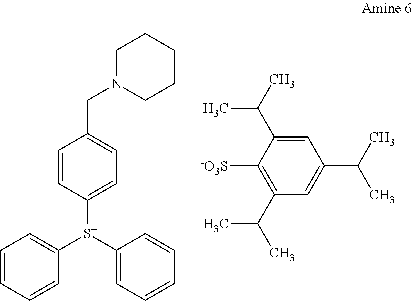

In addition, other polymers used in Examples or Comparative Examples are shown below.

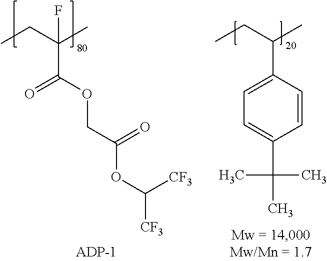

Coating liquids 1 to 5 for forming an inorganic base layer (bases 1 to 5): Any of these coating liquids are coating liquids including a silane compound, and an inorganic base layer including a silicon atom, exhibiting a surface energy shown in Table 4, was formed in each of Examples and Comparative Examples by a method which will be described later.

### Examples 1 to 35, and Comparative Examples 1 to 9

<Preparation of Resist Composition>

Components shown in Table 3 below were dissolved in a solvent with the composition shown in Table 3 below, a solution having a concentration of solid contents shown in Table 3 was prepared for each, and the solution was filtered through a polyethylene filter having a pore size of 0.03 μm to obtain a resist composition.

<Preparation of Laminate>

A coating liquid for forming an inorganic base layer shown in Table 3 was applied onto a silicon wafer and baked at 205° C. for 60 seconds to form an inorganic base layer having a thickness shown in Table 3, a resist composition shown in Table 3 was applied thereonto and baked at 120° C. for 60 seconds to form a resist layer having a thickness shown in Table 3, thereby obtaining a laminate.

<Method for Measuring Film Thickness>

The film thicknesses of the inorganic base layer and the resist layer in the obtained laminate were measured using a light interferometric film thickness meter (LAMBDA ACE VM-3100, manufactured by Dainippon Screen Mfg. Co., Ltd.). The film thickness is an average value of values measured at 25 points on the wafer surface.

<Method for Measuring Surface Energy>

The obtained laminate was irradiated with ultraviolet rays having a wavelength of 13.5 nm from the resist layer side at an integrated light quantity of 40 mJ/cm² and heated at 110° C. for 60 seconds.

The contact angle of pure water with respect to the surface of a sample cut out from the laminate after heating and the contact angle of diiodomethane with respect to the surface are each measured at 25° C. These contact angles were measured using a solid-liquid interface analyzer “Drop Master 700” manufactured by Kyowa Interface Science Co., Ltd. As the contact angle, a value after 6 seconds from the dropwise addition was used. Based on these contact angles, the surface energies γ_{A} and γ_{B} were derived by the Owens-Wendt method described above.

<EUV Exposure>

The wafer was subjected to patternwise exposure with an exposure mask (mask with line/space=1/5) using an EUV exposure apparatus (manufactured by Exitech Ltd., Micro Exposure Tool, NA 0.33, Quadrupole, outer sigma: 0.848, and inner sigma: 0.307). After performing the patternwise exposure, baking (PEB) was performed on a hot plate at 110° C. for 60 seconds, and a developer (butyl acetate) was puddled for 30 seconds. Next, after rotating the wafer at a rotation speed of 2,000 rpm for 30 seconds, a 1:5 isolated line pattern having a line width of 15 nm to 30 nm was obtained.

<Evaluation>

—Evaluation of Resolution (Pattern Collapse)—

The line width of the obtained isolated line pattern was measured. At this time, a minimum line width in which the pattern was resolved without a collapse over 5 μm square was defined as a collapsed line width, and the pattern collapse suppressing property was evaluated. A smaller value thereof indicates that a margin of pattern collapse is wider and the pattern collapse suppressing property is better.

The pattern collapse suppressing property determined above was evaluated as follows.

8: The collapsed pattern line width is 15.5 nm or less.

7: The collapsed pattern line width is more than 15.5 nm and 16.5 nm or less.

6: The collapsed pattern line width is more than 16.5 nm and 17.5 nm or less.

5: The collapsed pattern line width is more than 17.5 nm and 18.5 nm or less.

4: The collapsed pattern line width is more than 18.5 nm and 19.5 nm or less.

3: The collapsed pattern line width is more than 19.5 nm and 20.5 nm or less.

2: The collapsed pattern line width is more than 20.5 nm and 21.5 nm or less.

1: The collapsed pattern line width is more than 21.5 nm

—Evaluation of Etching Resistance—

The obtained resist pattern was etched using a plasma etching apparatus (device name: Hitachi ECR Plasma Etching Device U-621, manufactured by Hitachi Ltd. Ltd., plasma conditions: Ar 500 ml/min, N₂ 500 ml/min, and O₂ 10 ml/min) while changing the time, and the residual film of the resist pattern was observed with a scanning electron microscope (S4800 manufactured by Hitachi, Ltd.) to determine the shortest time required for the pattern to disappear.

The inorganic underlayer film was also subjected to a similar experiment to determine the shortest time required for the film to disappear.

(Selectivity in etching time)=(Pattern disappearance time)/(Inorganic underlayer film disappearance time)

The etching time selectivity obtained above was evaluated as follows.

5: The value of the selectivity in the etching time is 3.5 or more.

4: The value of the selectivity in the etching time is 3.0 or more and less than 3.5.

3: The value of the selectivity in the etching time is 2.5 or more and less than 3.0.

2: The value of the selectivity in the etching time is 2.0 or more and less than 2.5.

1: The value of the selectivity in the etching time is 1.5 or more and less than 2.0.

0: The value of the selectivity in the etching time is less than 1.5.

TABLE 3

| | | | | | | | | | Inorganic base layer | | |
|---|---|---|---|---|---|---|---|---|---|---|---|
| | | | | | | | | | Coating liquid for | | |
| | Resist layer | | | | | | | | forming inorganic | | |
| | | | Polymerization | | | | | | base layer | | |
| | Polymer | | initiator | | Amine compound | | ADP-1 | | | Concentration | |
| | | Content | | Content | | Content | content | | | (% by mass) | |
| | | (% by | | (% by | | (% by | (% by | Thickness | | of solid | Thickness |
| | Type | mass) | Type | mass) | Type | mass) | mass) | (nm) | Type | contents | (nm) |
| Example 1 | P-1 | 77.4 | PAG1 | 22.6 | Amine 3 | 4.7 | 0.0 | 58 | Primer 4 | 2.1 | 15 |
| Example 2 | P-2 | 77.7 | PAG2 | 22.3 | Amine 3 | 4.7 | 0.0 | 48 | Primer 4 | 1.8 | 15 |
| Example 3 | P-3 | 77.1 | PAG3 | 22.9 | Amine 3 | 4.7 | 0.0 | 47 | Primer 4 | 1.8 | 15 |
| Example 4 | P-4 | 77.1 | PAG4 | 22.9 | Amine 3 | 4.7 | 0.0 | 46 | Primer 5 | 1.7 | 15 |
| Example 5 | P-5 | 77.1 | PAG5 | 22.9 | Amine 3 | 4.7 | 0.0 | 56 | Primer 4 | 2.1 | 15 |
| Example 6 | P-6 | 77.1 | PAG6 | 22.9 | Amine 3 | 4.7 | 0.0 | 45 | Primer 4 | 1.7 | 15 |
| Example 7 | P-7 | 88.6 | PAG7 | 11.4 | Amine 3 | 2.4 | 0.0 | 48 | Primer 4 | 1.8 | 15 |
| Example 8 | P-8 | 77.9 | PAG8 | 22.1 | Amine 3 | 4.1 | 0.0 | 47 | Primer 4 | 1.8 | 15 |
| Example 9 | P-9 | 78.0 | PAG9 | 22.0 | Amine 3 | 4.7 | 0.0 | 52 | Primer 5 | 1.9 | 15 |
| Example 10 | P-10 | 78.0 | PAG10 | 22.0 | Amine 3 | 4.7 | 0.0 | 48 | Primer 5 | 1.8 | 15 |
| Example 11 | p-11 | 78.0 | PAG11 | 22.0 | Amine 3 | 4.7 | 0.0 | 53 | Primer 4 | 2.0 | 15 |
| Example 12 | P-12 | 83.4 | PAG12 | 16.6 | Amine 5 | 10.3 | 2.0 | 52 | Primer 4 | 1.9 | 15 |
| Example 13 | P-13 | 75.9 | PAG13 | 24.1 | Amine 6 | 10.3 | 0.0 | 50 | Primer 4 | 1.9 | 15 |
| Example 14 | P-14 | 75.9 | PAG14 | 24.1 | Amine 6 | 10.3 | 0.0 | 57 | Primer 5 | 2.1 | 15 |
| Example 15 | P-15 | 75.9 | PAG15 | 24.1 | Amine 6 | 10.3 | 0.0 | 59 | Primer 4 | 2.2 | 15 |
| Example 16 | P-16 | 77.4 | PAG16 | 22.6 | Amine 5 | 10.3 | 0.0 | 64 | Primer 4 | 2.3 | 15 |
| Example 17 | P-17 | 78.0 | PAG17 | 22.0 | Amine 3 | 3.6 | 0.0 | 52 | Primer 4 | 1.9 | 15 |
| Example 18 | P-18 | 78.0 | PAG18 | 22.0 | Amine 3 | 3.6 | 0.0 | 52 | Primer 4 | 1.9 | 15 |
| Example 19 | P-19 | 85.3 | PAG19 | 14.7 | Amine 1 | 2.8 | 0.0 | 58 | Primer 4 | 2.1 | 15 |
| Example 20 | P-20 | 83.8 | PAG20 | 16.2 | Amine 3 | 3.6 | 0.0 | 57 | Primer 4 | 2.1 | 15 |
| Example 21 | P-21 | 83.8 | PAG21 | 16.2 | Amine 3 | 3.6 | 0.0 | 49 | Primer 4 | 1.8 | 15 |
| Example 22 | P-22 | 77.0 | PAG22 | 23.0 | Amine 2 | 2.3 | 0.0 | 53 | Primer 5 | 2.0 | 15 |
| Example 23 | P-23 | 79.2 | PAG23 | 20.8 | Amine 3 | 3.6 | 3.0 | 56 | Primer 4 | 2.1 | 15 |
| Example 24 | P-24 | 78.0 | PAG24 | 22.0 | Amine 4 | 4.4 | 0.0 | 47 | Primer 4 | 1.8 | 15 |
| Example 25 | P-25 | 73.0 | PAG25 | 27.0 | Amine 2 | 2.3 | 0.0 | 59 | Primer 4 | 2.2 | 15 |
| Example 26 | P-26 | 73.0 | PAG26 | 27.0 | Amine 2 | 2.3 | 0.0 | 55 | Primer 4 | 2.0 | 15 |
| Example 27 | P-27 | 81.2 | PAG27 | 18.8 | Amine 4 | 5.8 | 0.0 | 48 | Primer 4 | 1.8 | 15 |
| Example 28 | P-28 | 81.2 | PAG28 | 18.8 | Amine 4 | 5.8 | 0.0 | 59 | Primer 4 | 2.2 | 15 |
| Example 29 | P-29 | 85.3 | PAG29 | 14.7 | Amine 6 | 5.2 | 0.0 | 59 | Primer 4 | 2.2 | 15 |
| Example 30 | P-30 | 77.8 | PAG30 | 22.2 | Amine 3 | 4.7 | 0.0 | 51 | Primer 4 | 1.9 | 15 |
| Example 31 | P-31 | 77.8 | PAG31 | 22.2 | Amine 3 | 4.7 | 0.0 | 58 | Primer 4 | 2.1 | 15 |
| Example 32 | P-32 | 82.4 | PAG32 | 17.6 | Amine 3 | 3.6 | 0.0 | 56 | Primer 4 | 2.1 | 15 |
| Example 33 | P-33 | 83.4 | PAG33 | 16.6 | Amine 5 | 10.3 | 0.0 | 64 | Primer 4 | 2.3 | 15 |
| Example 34 | P-34 | 81.2 | PAG34 | 18.8 | Amine 4 | 5.8 | 0.0 | 59 | Primer 4 | 2.2 | 12 |
| Example 35 | P-35 | 81.2 | PAG35 | 18.8 | Amine 4 | 5.8 | 0.0 | 55 | Primer 4 | 2.0 | 10 |
| Comparative | P-36 | 83.2 | PAG36 | 16.8 | Amine 5 | 10.3 | 0.0 | 35 | Primer 4 | 1.4 | 15 |
| Example 1 | | | | | | | | | | | |
| Comparative | P-37 | 75.3 | PAG37 | 24.7 | Amine 4 | 5.8 | 0.0 | 32 | Primer 3 | 1.3 | 15 |
| Example 2 | | | | | | | | | | | |
| Comparative | P-38 | 72.5 | PAG38 | 27.5 | Amine 1 | 5.7 | 0.0 | 30 | Primer 2 | 1.2 | 15 |
| Example 3 | | | | | | | | | | | |
| Comparative | P-39 | 83.1 | PAG39 | 16.9 | Amine 3 | 3.6 | 0.0 | 30 | Primer 1 | 1.2 | 15 |
| Example 4 | | | | | | | | | | | |
| Comparative | P-40 | 77.3 | PAG40 | 22.7 | Amine 4 | 5.8 | 0.0 | 35 | Primer 2 | 1.4 | 15 |
| Example 5 | | | | | | | | | | | |
| Comparative | P-41 | 75.9 | PAG41 | 24.1 | Amine 6 | 10.3 | 0.0 | 38 | Primer 3 | 1.5 | 15 |
| Example 6 | | | | | | | | | | | |
| Comparative | P-42 | 75.9 | PAG42 | 24.1 | Amine 6 | 10.3 | 0.0 | 36 | Primer 2 | 1.4 | 15 |
| Example 7 | | | | | | | | | | | |
| Comparative | P-43 | 82.9 | PAG43 | 17.1 | Amine 5 | 10.3 | 0.0 | 40 | Primer 3 | 1.5 | 15 |
| Example 8 | | | | | | | | | | | |
| Comparative | P-44 | 80.0 | PAG44 | 20.0 | Amine 4 | 4.4 | 0.0 | 39 | Primer 1 | 1.5 | 15 |
| Example 9 | | | | | | | | | | | |

TABLE 4

| | | | | | Surface energy of | | | Surface energy of | | | | | |
|---|---|---|---|---|---|---|---|---|---|---|---|---|---|
| | Contact angle (°) | | Contact angle (°) | | resist layer | | | inorganic base layer | | | | | |
| | after exposure | | after exposure of | | Disper- | Hydrogen | γ_{A} | Disper- | Hydrogen | γ_{B} | γ_{AB} | Evaluation | |
| | of resist layer | | inorganic base layer | | sion | bonding | (mJ/ | sion | bonding | (mJ/ | (mJ/ | Resolu- | Etching |
| | Water | Diiodomethane | Water | Diiodomethane | item γ^{d} | item γ^{h} | m²) | item γ^{d} | item γ^{h} | m²) | m²) | tion | resistance |
| Example 1 | 48.5 | 32.7 | 37.0 | 38.0 | 42.6 | 17.7 | 60.3 | 30.9 | 30.6 | 61.5 | −1.2 | 8 | 5 |
| Example 2 | 48.0 | 31.3 | 37.0 | 38.0 | 42.5 | 18.0 | 60.5 | 30.9 | 30.6 | 61.5 | −1.0 | 7 | 5 |
| Example 3 | 45.1 | 35.7 | 37.0 | 38.0 | 42.1 | 19.8 | 61.9 | 30.9 | 30.6 | 61.5 | 0.4 | 7 | 5 |
| Example 4 | 45.1 | 35.7 | 34.0 | 35.0 | 42.1 | 19.8 | 61.9 | 32.0 | 31.6 | 63.6 | −1.7 | 7 | 5 |
| Example 5 | 43.1 | 34.5 | 37.0 | 38.0 | 41.8 | 21.1 | 62.9 | 30.9 | 30.6 | 61.5 | 1.4 | 7 | 5 |
| Example 6 | 45.6 | 33.8 | 37.0 | 38.0 | 42.1 | 19.6 | 61.7 | 30.9 | 30.6 | 61.5 | 0.2 | 8 | 3 |
| Example 7 | 48.5 | 39.1 | 37.0 | 38.0 | 42.7 | 17.7 | 60.3 | 30.9 | 30.6 | 61.5 | −1.2 | 8 | 5 |
| Example 8 | 45.8 | 38.0 | 37.0 | 38.0 | 42.2 | 19.4 | 61.6 | 30.9 | 30.6 | 61.5 | 0.1 | 8 | 4 |
| Example 9 | 43.7 | 36.3 | 34.0 | 35.0 | 41.9 | 20.7 | 62.6 | 32.0 | 31.6 | 63.6 | −1.1 | 8 | 4 |
| Example 10 | 43.7 | 36.3 | 34.0 | 35.0 | 41.9 | 20.7 | 62.6 | 32.0 | 31.6 | 63.6 | −1.1 | 8 | 3 |
| Example 11 | 41.6 | 34.6 | 37.0 | 38.0 | 41.5 | 22.0 | 63.6 | 30.9 | 30.6 | 61.5 | 2.1 | 6 | 4 |
| Example 12 | 39.5 | 32.9 | 37.0 | 38.0 | 41.2 | 23.3 | 64.6 | 30.9 | 30.6 | 61.5 | 3.1 | 6 | 3 |
| Example 13 | 43.1 | 34.5 | 37.0 | 38.0 | 41.8 | 21.1 | 62.9 | 30.9 | 30.6 | 61.5 | 1.4 | 7 | 4 |
| Example 14 | 41.2 | 33.2 | 34.0 | 35.0 | 41.5 | 22.3 | 63.8 | 32.0 | 31.6 | 63.6 | 0.2 | 7 | 4 |
| Example 15 | 41.2 | 33.2 | 37.0 | 38.0 | 41.5 | 22.3 | 63.8 | 30.9 | 30.6 | 61.5 | 2.3 | 5 | 4 |
| Example 16 | 39.2 | 32.0 | 37.0 | 38.0 | 41.2 | 23.5 | 64.7 | 30.9 | 30.6 | 61.5 | 3.2 | 5 | 3 |
| Example 17 | 44.4 | 32.2 | 34.0 | 35.0 | 42.0 | 20.3 | 62.2 | 32.0 | 31.6 | 63.6 | −1.4 | 7 | 5 |
| Example 18 | 44.4 | 32.2 | 34.0 | 35.0 | 42.0 | 20.3 | 62.2 | 32.0 | 31.6 | 63.6 | −1.4 | 7 | 5 |
| Example 19 | 44.4 | 32.2 | 37.0 | 38.0 | 42.0 | 20.3 | 62.2 | 30.9 | 30.6 | 61.5 | 0.7 | 7 | 5 |
| Example 20 | 48.1 | 32.6 | 37.0 | 38.0 | 42.5 | 17.9 | 60.5 | 30.9 | 30.6 | 61.5 | −1.0 | 8 | 5 |
| Example 21 | 47.0 | 35.3 | 37.0 | 38.0 | 42.4 | 18.7 | 61.0 | 30.9 | 30.6 | 61.5 | −0.5 | 8 | 4 |
| Example 22 | 44.9 | 33.6 | 34.0 | 35.0 | 42.0 | 20.0 | 62.0 | 32.0 | 31.6 | 63.6 | −1.6 | 8 | 4 |
| Example 23 | 45.2 | 33.7 | 37.0 | 38.0 | 42.1 | 19.8 | 61.9 | 30.9 | 30.6 | 61.5 | 0.3 | 8 | 4 |
| Example 24 | 48.3 | 25.5 | 37.0 | 38.0 | 42.5 | 17.8 | 60.4 | 30.9 | 30.6 | 61.5 | −1.1 | 7 | 3 |
| Example 25 | 48.3 | 25.5 | 37.0 | 38.0 | 42.5 | 17.8 | 60.4 | 30.9 | 30.6 | 61.5 | −1.1 | 7 | 4 |
| Example 26 | 48.3 | 25.5 | 34.0 | 35.0 | 42.5 | 17.8 | 60.4 | 32.0 | 31.6 | 63.6 | −3.3 | 7 | 4 |
| Example 27 | 41.2 | 33.2 | 37.0 | 38.0 | 41.5 | 22.3 | 63.8 | 30.9 | 30.6 | 61.5 | 2.3 | 5 | 3 |
| Example 28 | 45.1 | 26.5 | 37.0 | 38.0 | 42.0 | 19.9 | 61.9 | 30.9 | 30.6 | 61.5 | 0.4 | 7 | 3 |
| Example 29 | 48.3 | 25.5 | 37.0 | 38.0 | 42.5 | 17.8 | 60.4 | 30.9 | 30.6 | 61.5 | −1.1 | 7 | 3 |
| Example 30 | 46.2 | 38.1 | 37.0 | 38.0 | 42.2 | 19.2 | 61.4 | 30.9 | 30.6 | 61.5 | −0.1 | 7 | 4 |
| Example 31 | 48.3 | 25.5 | 37.0 | 38.0 | 42.5 | 17.8 | 60.4 | 30.9 | 30.6 | 61.5 | −1.1 | 8 | 5 |
| Example 32 | 48.3 | 25.5 | 37.0 | 38.0 | 42.5 | 17.8 | 60.4 | 30.9 | 30.6 | 61.5 | −1.1 | 7 | 4 |
| Example 33 | 39.5 | 32.9 | 37.0 | 38.0 | 41.2 | 23.3 | 64.6 | 30.9 | 30.6 | 61.5 | 3.1 | 7 | 4 |
| Example 34 | 45.1 | 26.5 | 37.0 | 38.0 | 42.0 | 19.9 | 61.9 | 30.9 | 30.6 | 61.5 | 0.4 | 6 | 3 |
| Example 35 | 45.1 | 26.5 | 37.0 | 38.0 | 42.0 | 19.9 | 61.9 | 30.9 | 30.6 | 61.5 | 0.4 | 6 | 3 |
| Comparative | 51.6 | 24.4 | 37.0 | 38.0 | 43.1 | 15.8 | 58.9 | 30.9 | 30.6 | 61.5 | −2.6 | 5 | 0 |
| Example 1 | | | | | | | | | | | | | |
| Comparative | 50.3 | 26.7 | 56.0 | 40.0 | 42.9 | 16.6 | 59.5 | 32.4 | 17.9 | 50.2 | 9.2 | 1 | 1 |
| Example 2 | | | | | | | | | | | | | |
| Comparative | 50.9 | 30.2 | 70.0 | 52.0 | 43.0 | 16.2 | 59.2 | 27.9 | 11.5 | 39.4 | 19.8 | 1 | 2 |
| Example 3 | | | | | | | | | | | | | |
| Comparative | 50.3 | 26.7 | 79.0 | 53.0 | 42.9 | 16.6 | 59.5 | 28.8 | 6.6 | 35.4 | 24.1 | 1 | 1 |
| Example 4 | | | | | | | | | | | | | |
| Comparative | 51.6 | 24.4 | 70.0 | 52.0 | 43.1 | 15.8 | 58.9 | 27.9 | 11.5 | 39.4 | 19.5 | 1 | 0 |
| Example 5 | | | | | | | | | | | | | |
| Comparative | 48.3 | 25.5 | 56.0 | 40.0 | 42.5 | 17.8 | 60.4 | 32.4 | 17.9 | 50.2 | 10.1 | 1 | 0 |
| Example 6 | | | | | | | | | | | | | |
| Comparative | 53.5 | 25.7 | 70.0 | 52.0 | 43.4 | 14.6 | 58.0 | 27.9 | 11.5 | 39.4 | 18.6 | 1 | 1 |
| Example 7 | | | | | | | | | | | | | |
| Comparative | 51.6 | 24.4 | 56.0 | 40.0 | 43.1 | 15.8 | 58.9 | 32.4 | 17.9 | 50.2 | 8.6 | 1 | 0 |
| Example 8 | | | | | | | | | | | | | |
| Comparative | 51.6 | 24.4 | 79.0 | 53.0 | 43.1 | 15.8 | 58.9 | 28.8 | 6.6 | 35.4 | 23.5 | 1 | 0 |
| Example 9 | | | | | | | | | | | | | |

As shown in Tables 3 and 4, the pattern forming methods and the resist laminates for organic solvent development of Examples 1 to 35 make it possible to obtain a pattern having excellent etching resistance and enable excellent resolution, as compared with the pattern forming methods and the resist laminates for organic solvent development of Comparative Examples 1 to 9.

The disclosure of Japanese Patent Application No. 2018-182231 filed on Sep. 27, 2018 is incorporated herein by reference in its entirety.

All publications, patent applications and technical standards described herein are incorporated herein by reference to the same extent that as if each individual publication, patent application and technical standard was specifically and individually indicated to be incorporated by reference.

What is claimed is:

1. A pattern forming method, comprising:
preparing a laminate having a substrate, an inorganic base layer on the substrate, and a resist layer provided on the inorganic base layer in such a manner that the resist layer contacts the inorganic base layer;
exposing the resist layer; and
developing the laminate using a developer comprising an organic solvent to form a negative tone pattern,
wherein a surface energy γ_{A} of the resist layer after irradiation of the laminate with ultraviolet rays having a wavelength of 13.5 nm from the resist layer side with an integrated light quantity of 40 mJ/cm², followed by heating of the laminate at 110° C. for 60 seconds is 60 mJ/m² or more,
wherein a surface energy γ_{B} of the inorganic base layer after irradiation of the laminate with ultraviolet rays having a wavelength of 13.5 nm from the resist layer side with an integrated light quantity of 40 mJ/cm², followed by heating of the laminate at 110° C. for 60 seconds is 55 mJ/m² or more, and
wherein a difference γ_{AB} in surface energies that is defined by Formula (A) is 5.0 mJ/m² or less:
γ_{AB}=γ_{A}−γ_{B} Formula (A).

2. The pattern forming method according to claim 1,
wherein the surface energy γ_{A} is 62 mJ/m² or more.

3. The pattern forming method according to claim 1,
wherein the surface energy γ_{B} is 60 mJ/m² or more.

4. The pattern forming method according to claim 1,
wherein the exposure is performed with ultraviolet rays having a wavelength of 5 nm to 20 nm.

5. The pattern forming method according to claim 1,
wherein the inorganic base layer is a layer comprising a silicon atom.

6. The pattern forming method according to claim 1,
wherein the resist layer prior to the exposure comprises:
a resin having a constitutional unit having two or more phenolic hydroxyl groups and a constitutional unit having a polar group protected by an acid-decomposable group; and
a photoacid generator.

7. The pattern forming method according to claim 6,
wherein the constitutional unit having two or more phenolic hydroxyl groups is a constitutional unit represented by Formula (I-1): 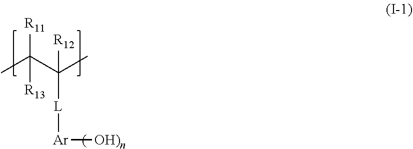
wherein, in Formula (I-1), R₁₁ and R₁₂ each independently represent a hydrogen atom or an alkyl group; R₁₃ represents a hydrogen atom or an alkyl group, or represents a single bond or an alkylene group, and is bonded to L or Ar to form a ring, wherein L represents a single bond or a divalent linking group and Ar represents an aromatic ring, and n represents an integer of 2 or more.

8. The pattern forming method according to claim 1,
wherein a value of a pattern height/a pattern width in at least a part of an obtained pattern is 1.5 to 1.8.

9. A resist laminate for organic solvent development, the resist laminate comprising:
a substrate;
an inorganic base layer on the substrate; and
a resist layer provided on the inorganic base layer in such a manner that the resist layer contacts the inorganic base layer,
wherein a surface energy γA of the resist layer after irradiation of the laminate with ultraviolet rays having a wavelength of 13.5 nm from the resist layer side with an integrated light quantity of 40 mJ/cm², followed by heating of the laminate at 110° C. for 60 seconds is 60 mJ/m² or more,
a surface energy γB of the base layer after irradiation of the laminate with ultraviolet rays having a wavelength of 13.5 nm from the resist layer side with an integrated light quantity of 40 mJ/cm², followed by heating the laminate at 110° C. for 60 seconds is 50 mJ/m² or more, and
a difference γ_{AB} in surface energies that is defined by Formula (A) is 5.0 mJ/m² or less:
γ_{AB}=γ_{A}−γ_{B} Formula (A).

10. The resist laminate for organic solvent development according to claim 9,
wherein the surface energy γ_{A} is 62 mJ/m² or more.

11. The resist laminate for organic solvent development according to claim 9,
wherein the surface energy γ_{B} is 60 mJ/m² or more.

12. The resist laminate for organic solvent development according to claim 9,
wherein the inorganic base layer is a layer comprising a silicon atom.

13. The resist laminate for organic solvent development according to claim 9,
wherein the resist layer comprises:
a resin having a constitutional unit having two or more phenolic hydroxyl groups and
a constitutional unit having a polar group protected by an acid-decomposable group; and
a photoacid generator.

14. The resist laminate for organic solvent development according to claim 13,
wherein the constitutional unit having two or more phenolic hydroxyl groups is a constitutional unit represented by Formula (I-1): 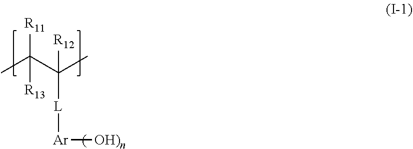
wherein, in Formula (I-1), R₁₁ and R₁₂ each independently represent a hydrogen atom or an alkyl group; R₁₃ represents a hydrogen atom or an alkyl group, or represents a single bond or an alkylene group, and is bonded to L or Ar to form a ring, where L represents a single bond or a divalent linking group and Ar represents an aromatic ring, and n represents an integer of 2 or more.
